(19) United States
(12) Patent Application Publication
(10) Pub. No.: US 2024/0341100 A1
(43) Pub. Date: Oct. 10, 2024

(54) VERTICAL MEMORY DEVICES INCLUDING DIVISION PATTERNS

(71) Applicant: SAMSUNG ELECTRONICS CO., LTD., Suwon-si (KR)

(72) Inventors: Jimin LEE, Suwon-si (KR); Jungtae SUNG, Suwon-si (KR); Sunil SHIM, Suwon-si (KR); Yunsun JANG, Suwon-si (KR); Wonseok CHO, Suwon-si (KR); Moorym CHOI, Suwon-si (KR); Chulmin CHOI, Suwon-si (KR)

(73) Assignee: SAMSUNG ELECTRONICS CO., LTD., Suwon-si (KR)

(21) Appl. No.: 18/386,429

(22) Filed: Nov. 2, 2023

(30) Foreign Application Priority Data
Apr. 5, 2023 (KR) 10-2023-0044589

(51) Int. Cl. H10B 43/50; H10B 43/27; H10B 43/40

(52) U.S. Cl. CPC H10B 43/50; H10B 43/27; H10B 43/40

(57) ABSTRACT

A semiconductor device includes gate electrode structures, a first division pattern, a second division pattern, and a memory channel structure. Each gate electrode structure includes gate electrodes spaced apart from each other on a substrate in a first direction substantially perpendicular to an upper surface of the substrate. Each gate electrode extends in a second direction substantially parallel to the upper surface of the substrate. The gate electrode structures are spaced apart from each other in a third direction substantially parallel to the upper surface and crossing the second direction. The first division pattern extends in the second direction between the gate electrode structures on the substrate. The second division pattern extends in the third direction on the substrate, and is on sidewalls of end portions in the second direction of the gate electrode structures. The memory channel structure extends in the first direction through each gate electrode structure.

### CROSS-REFERENCE TO RELATED APPLICATIONS

This application claims benefit of priority under 35 U.S.C. § 119 to Korean Patent Application No. 10-2023-0044589, filed on Apr. 5, 2023, in the Korean Intellectual Property Office, the disclosure of which is incorporated by reference in its entirety.

### BACKGROUND

### 1. Field

The present disclosure to semiconductor devices, and more particularly, to a vertical memory device including division patterns.

### 2. Description of Related Art

In an electronic system requiring data storage, a high capacity semiconductor device that may store high capacity data may be desirable. Thus, for at least such a reason, methods of potentially increasing the data storage capacity of semiconductor devices have been studied. For example, semiconductor devices including memory cells that may be 3-dimensionally (3D) stacked have been suggested.

As the number of 3D stacked memory cells in semiconductor devices increases, the height of the upper surface of the gate electrode structure constituting the memory cells may also increase. Consequently, it may be necessary to secure a margin for forming a division pattern that may penetrate and/or separate the gate electrode structure by an etching process.

### SUMMARY

Aspects of the present disclosure provide for a semiconductor device having improved electrical characteristics when compared to related semiconductor devices.

According to an aspect of the present disclosure, a semiconductor device is provided. The semiconductor device includes a plurality of gate electrode structures. Each gate electrode structure of the plurality of gate electrode structures includes a plurality of gate electrodes spaced apart from each other on a substrate in a first direction substantially perpendicular to an upper surface of the substrate. Each gate electrode of the plurality of gate electrodes extends in a second direction substantially parallel to the upper surface of the substrate. The plurality of gate electrode structures are spaced apart from each other in a third direction substantially parallel to the upper surface of the substrate and crossing the second direction. The semiconductor device further includes a first division pattern extending in the second direction between the plurality of gate electrode structures on the substrate, and a second division pattern extending in the third direction on the substrate. The second division pattern is on sidewalls of end portions in the second direction of the plurality of gate electrode structures. The semiconductor device further includes a memory channel structure extending in the first direction through each gate electrode structure of the plurality of gate electrode structures. The first division pattern and the second division pattern contact each other. The first division pattern and the second division pattern are coupled to each other. A first maximum width in the second direction of a first portion of the second division pattern contacting the first division pattern is narrower than a second maximum width in the second direction of other portions of the second division pattern.

According to an aspect of the present disclosure, a semiconductor device is provided. The semiconductor device includes a gate electrode structure including a plurality of gate electrodes spaced apart from each other on a substrate in a first direction substantially perpendicular to an upper surface of the substrate. Each gate electrode of the plurality of gate electrodes extends in a second direction substantially parallel to the upper surface of the substrate. The semiconductor device further includes a plurality of first division patterns on respective opposite sidewalls of the gate electrode structure in a third direction substantially parallel to the upper surface of the substrate and crossing the second direction. Each pattern of the plurality of first division patterns extends in the second direction on the substrate. The semiconductor device includes a plurality of second division patterns spaced apart from each other in the second direction between the plurality of first division patterns on the substrate, each pattern of the plurality of second division patterns extending partially through the gate electrode structure, and a memory channel structure extending in the first direction through the gate electrode structure. For each pattern of the plurality of second division patterns, a first maximum width in the third direction of an end portion in the second direction of that pattern is narrower than a second maximum width in the third direction of other portions of that pattern.

According to an aspect of the present disclosure, a semiconductor device is provided. The semiconductor device includes a lower circuit pattern on a substrate, a common electrode plate (CSP) on the lower circuit pattern, and a plurality of gate electrode structures. Each gate electrode structure of the plurality of gate electrode structures includes a plurality of gate electrodes spaced apart from each other on the CSP in a first direction substantially perpendicular to an upper surface of the substrate. Each gate electrode of the plurality of gate electrodes extends in a second direction substantially parallel to the upper surface of the substrate. The plurality of gate electrode structures are spaced apart from each other in a third direction substantially parallel to the upper surface of the substrate and crossing the second direction. The semiconductor device further includes a first division pattern extending in the second direction between the plurality of gate electrode structures on the CSP, and a second division pattern extending in the third direction on the CSP. The second division pattern is on sidewalls of end portions in the second direction of the plurality of gate electrode structures. The semiconductor device further includes a memory channel structure extending in the first direction through each gate electrode structure of the plurality of gate electrode structures on the CSP, a support structure extending in the first direction through each gate electrode structure of the plurality of gate electrode structures on the CSP, and a contact plug extending through each of the plurality of gate electrode structures, the contact plug being electrically coupled to the lower circuit pattern. The first division pattern and the second division pattern contact each other. The first division pattern and the second division pattern are coupled to each other. A first maximum width in the second direction of a first portion of the second division pattern contacting the first division pattern is narrower than a second maximum width in the second direction of other portions of the second division pattern.

In a semiconductor device in accordance with example embodiments, a portion of each of the division patterns, which may respectively extend in intersecting directions through the gate electrode structure and contact other division patterns, may have a smaller width than those of other portions thereof. Thus, the semiconductor device including the division patterns may have an improved degree of integration when compared to related semiconductor devices.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIGS. 1 to 8 are plan views and cross-sectional views illustrating a semiconductor device, in accordance with example embodiments;

FIGS. 9 to 62 are plan views and cross-sectional views illustrating a method of manufacturing a vertical memory device, in accordance with example embodiments;

FIGS. 63A and 64A are plan views illustrating a semiconductor device, in accordance with example embodiments;

FIGS. 63B and 64B are enlarged cross-sectional views about region P of FIGS. 63A and 64A, respectively, in accordance with example embodiments;

FIGS. 65 and 66 are plan views illustrating a semiconductor device, in accordance with example embodiments;

FIG. 67 is a plan view illustrating a semiconductor device, in accordance with example embodiments; and

FIG. 68 is a plan view illustrating a semiconductor device, in accordance with example embodiments.

### DETAILED DESCRIPTION

The above and other aspects and features of the capacitor structures and the methods of manufacturing the same, the semiconductor devices including the capacitor structures and the methods of manufacturing the same in accordance with example embodiments may become readily understood from detail descriptions that follow, with reference to the accompanying drawings. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include possible combinations of the items enumerated together in a corresponding one of the phrases.

As used herein, such terms as “1st” and “2nd,” or “first” and “second” may be used to simply distinguish a corresponding component from another, and does not limit the components in other aspect (e.g., importance or order). For example, it may be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment.

The embodiments herein may be described and illustrated in terms of blocks, as shown in the drawings, which carry out a described function or functions. These blocks, which may be referred to herein as units or modules or the like, or by names such as device, logic, circuit, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

As used herein, each of the terms “Al₂O₃”, “GaAs”, “GaP”, “GaSb”, “H₂SO₄”, “H₃PO₄”, “HF”, “HfO”, “SiGe”, “SiN”, “SiO”, “TaN”, “TiN”, “WSi”, and the like may refer to a material made of elements included in each of the terms and is not a chemical formula representing a stoichiometric relationship.

Hereinafter, various embodiments of the present disclosure are described with reference to the accompanying drawings.

As used herein, a vertical direction substantially perpendicular to an upper surface of a substrate may be referred to as a first direction D1, and two directions crossing each other among horizontal directions substantially parallel to the upper surface of the substrate may be referred to as second direction D2 and third direction D3, respectively. In example embodiments, the second and third directions D2 and D3 may be substantially perpendicular to each other.

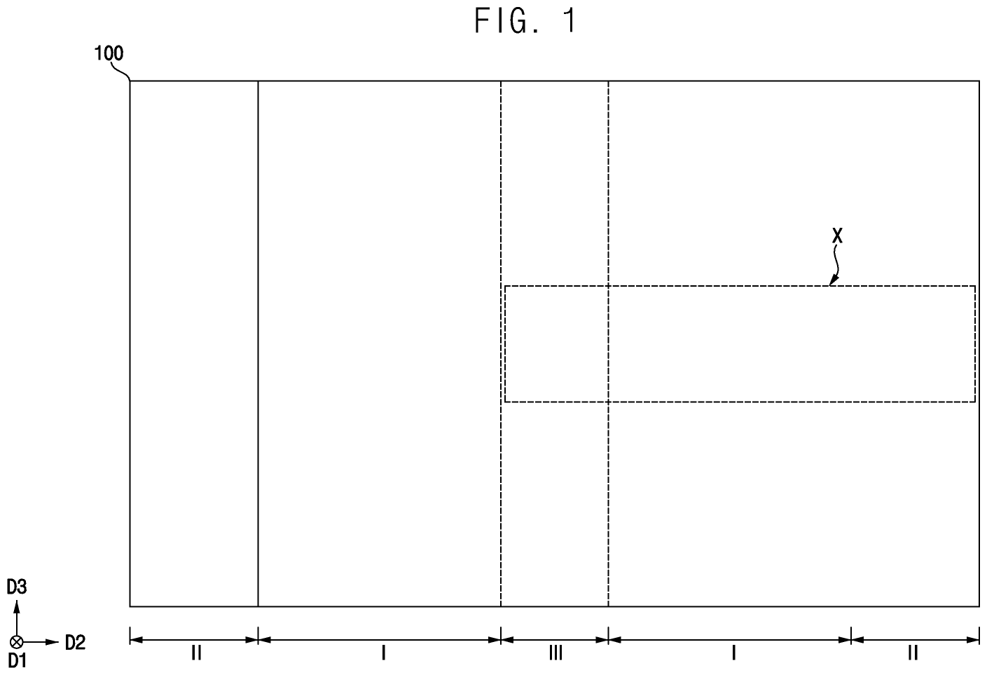

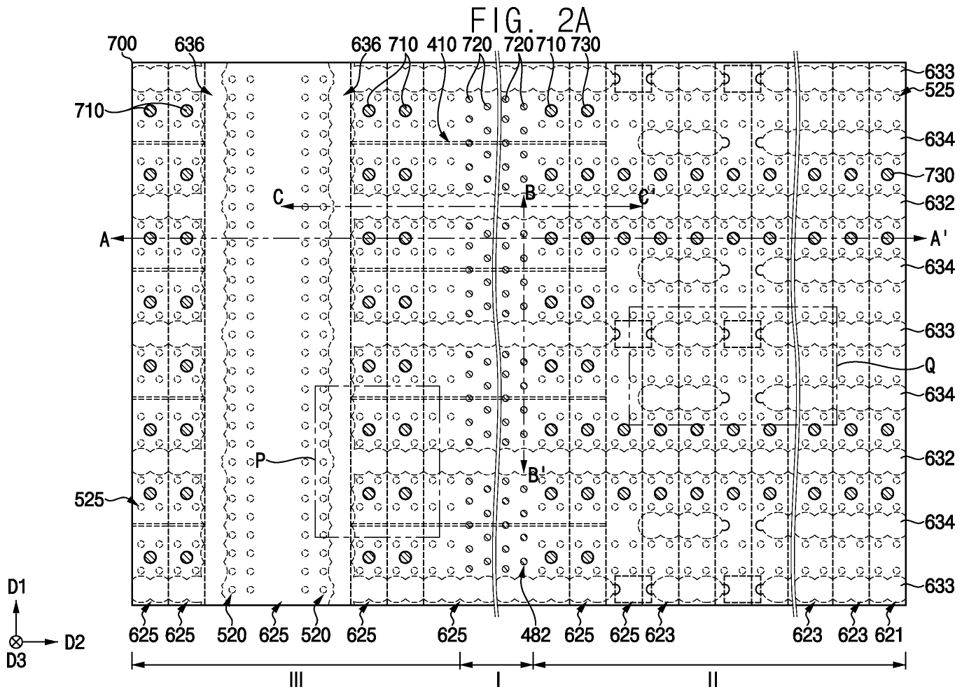

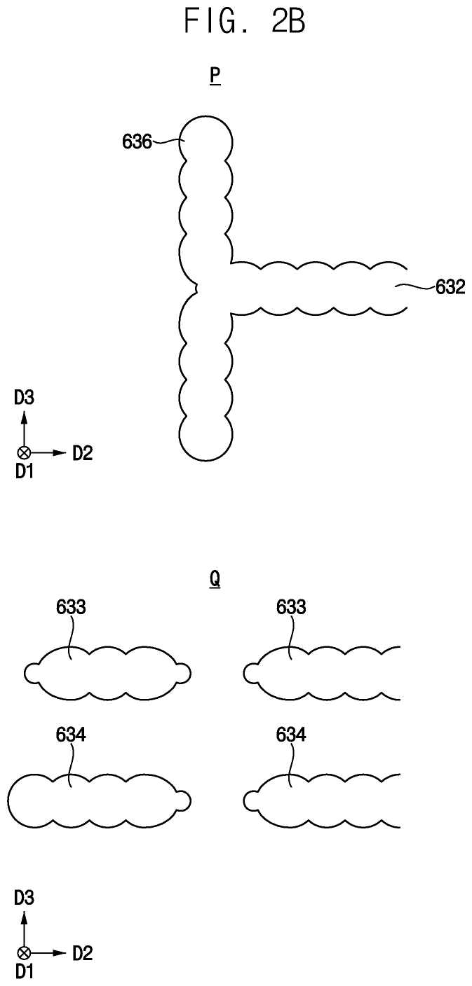

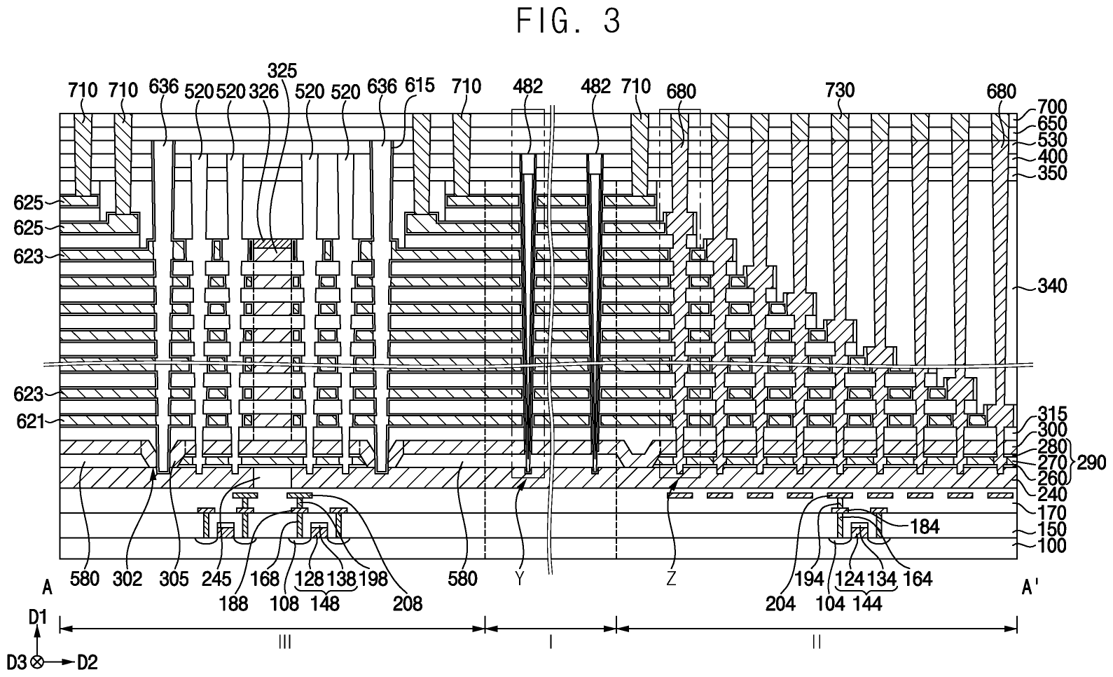

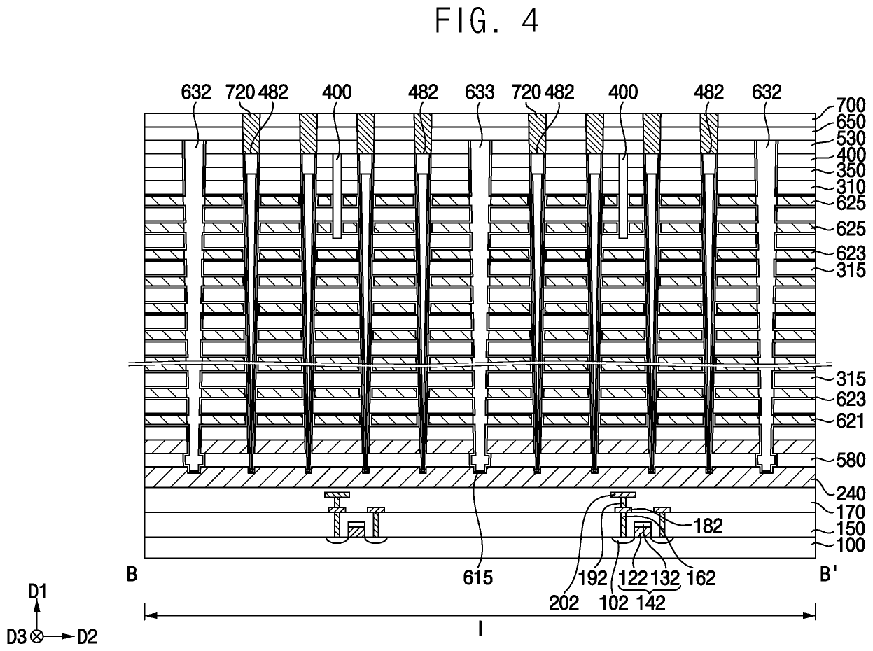

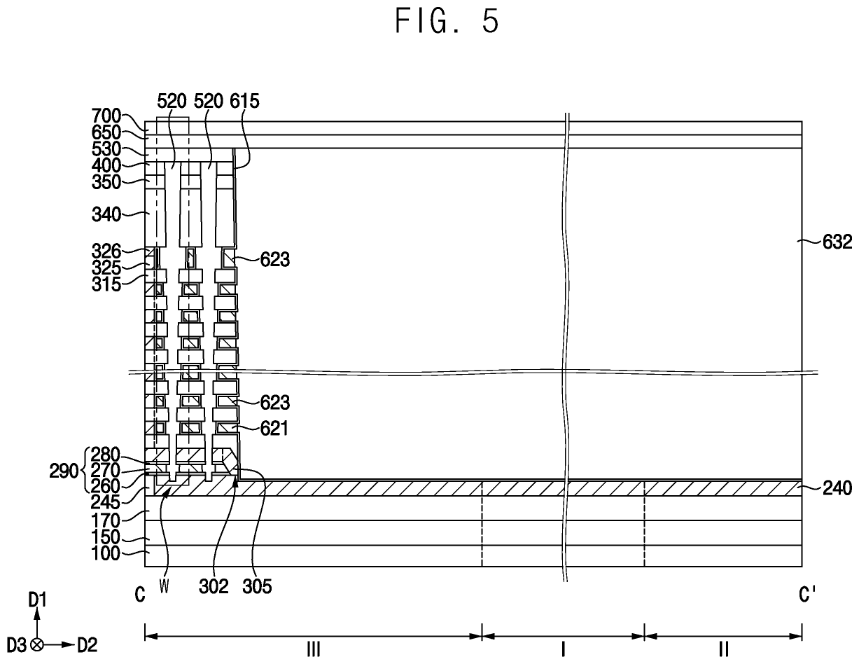

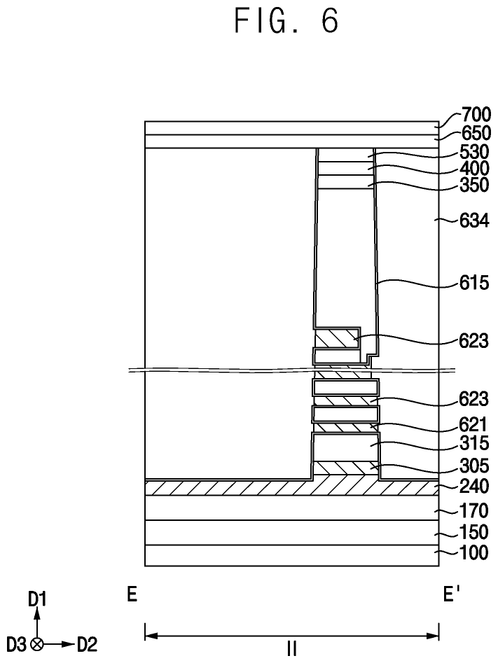

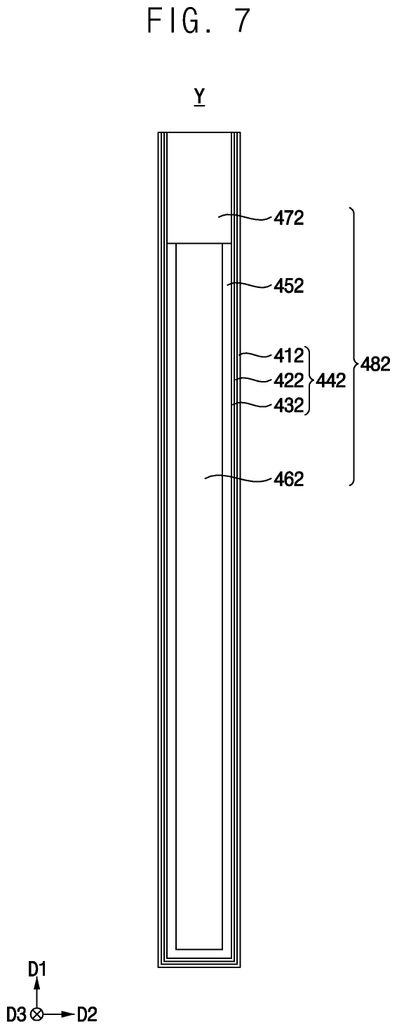

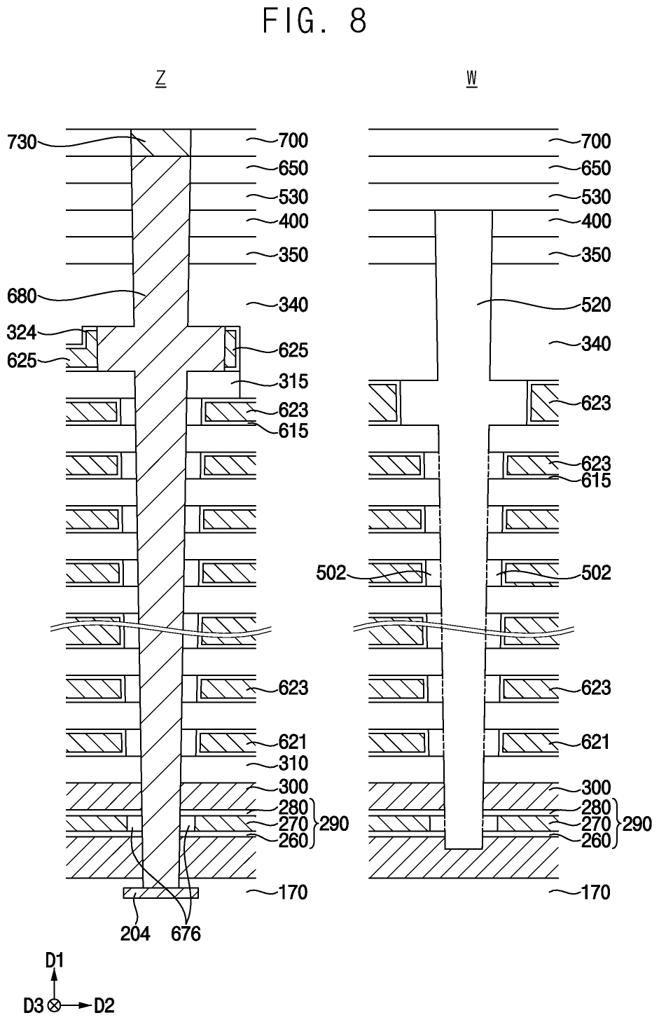

FIGS. 1 to 8 are plan views and cross-sectional views illustrating a semiconductor device, in accordance with example embodiments. Specifically, FIGS. 1, 2A and 2B are a plan view, FIG. 3 is a cross-sectional view taken along line A-A′ of FIG. 2, FIG. 4 is a cross-sectional view taken along line B-B′ of FIG. 2, FIG. 5 is a cross-sectional view taken along line C-C′ of FIG. 2, FIG. 6 is a cross-sectional view taken along line E-E′ of FIG. 2, FIG. 7 is an enlarged cross-sectional view of region Y of FIG. 3, and FIG. 8 includes enlarged cross-sectional views of regions Z and W of FIGS. 3 and 5, respectively.

FIG. 2B includes enlarged plan views of region P and region Q of FIG. 2A. However, only division patterns are shown in FIG. 2B in order to avoid complexity of the drawing. FIGS. 2 to 8 are drawings about region X of FIG. 1.

Referring to FIGS. 1 to 7, the semiconductor device may include a lower circuit pattern, a common source plate (CSP) 240, a gate electrode structure, a plurality of division patterns (e.g., first division pattern 330, second division pattern 410, third division pattern 632, fourth division pattern 633, fifth division pattern 634, and sixth division pattern 636), a memory channel structure 482, support structures (e.g., first support structure 520 and second support structure 525), upper contact plugs (e.g., first upper contact plug 680, second upper contact plug 710, and third upper contact plug 720), and an upper via 730 on a substrate 100.

The semiconductor device may further include a CSP division layer 245, a support layer 300, a support pattern 305, a sacrificial layer structure 290, a fourth sacrificial pattern 325, a third insulation pad 326, a channel connection pattern 580, a second blocking pattern 615, insulation patterns (e.g., first insulation pattern 315, fourth insulation pattern 674, and fifth insulation pattern 676), and insulating interlayers (e.g., first insulating interlayer 150, second insulating interlayer 170, third insulating interlayer 340, fourth insulating interlayer 350, fifth insulating interlayer 400, sixth insulating interlayer 530, seventh insulating interlayer 650, and eighth insulating interlayer 700).

The substrate 100 may include, but not be limited to, a semiconductor material (e.g., silicon (Si), germanium (Ge), silicon-germanium (SiGe), and the like), and a III-V group compound semiconductor (e.g., gallium phosphide (GaP), gallium arsenide (GaAs), gallium antimonide (GaSb), and the like). In some example embodiments, the substrate 100 may be and/or may include a silicon-on-insulator (SOI) substrate or a germanium-on-insulator (GOI) substrate.

In example embodiments, the substrate 100 may include a third region III, a first region I at each of opposite sides in the second direction D2 of the third region III, and a second region II at a side in the second direction D2 of the first region I. The first region I may be and/or may include a cell region where memory cells may be formed. The second region II may be and/or may include a pad region and/or an extension region where upper contact plugs for transferring electrical signals to the memory cells may be formed. The third region III may be and/or may include a connection region connecting the first regions I to each other, which may be spaced apart from each other in the second direction D2.

In example embodiments, the semiconductor device may have a cell over periphery (COP) structure. That is, the lower circuit pattern may be disposed on the substrate 100, and the memory cells, the upper contact plugs and the upper circuit pattern may be disposed over the lower circuit pattern. The lower circuit pattern may include circuitry elements such as, but not limited to, transistors, lower contact plugs, lower wirings, lower vias, and the like.

For example, a first transistor, a second transistor, and a third transistor may be disposed on the first, second, and third regions I, II, and III, respectively, of the substrate 100.

The first transistor may include a first lower gate structure 142 on the substrate 100 and first impurity regions 102 at upper portions of the substrate 100 adjacent to the first lower gate structure 142, which may serve as source/drains, respectively. The second transistor may include a second lower gate structure 144 on the substrate 100 and second impurity regions 104 at upper portions of the substrate 100 adjacent to the second lower gate structure 144, which may serve as source/drains, respectively. The third transistor may include a third lower gate structure 148 on the substrate 100, and third impurity regions 108 at upper portions of the substrate 100 adjacent to the third lower gate structure 148, which may serve as source/drains, respectively.

In example embodiments, each of the first to third transistors may be a pass transistor.

The first lower gate structure 142 may include a first lower gate insulation pattern 122 and a first lower gate electrode 132 sequentially stacked on the substrate 100. The second lower gate structure 144 may include a second lower gate insulation pattern 124 and a second lower gate electrode 134 sequentially stacked on the substrate 100. The third lower gate structure 148 may include a second lower gate insulation pattern 128 and a third lower gate electrode 138 sequentially stacked on the substrate 100.

The first insulating interlayer 150 may be disposed on the substrate 100, and may at least partially cover the first to third transistors. In an embodiment, lower contact plugs (e.g., first lower contact plug 162, second lower contact plug 164, and third lower contact plug 168) may extend through the first insulating interlayer 150 to contact the first to third impurity regions 102 to 108, respectively.

In an embodiment, lower wirings (e.g., first lower wiring 182, second lower wiring 184, and third lower wiring 188) may be disposed on the first insulating interlayer 150, and may contact upper surfaces of the first to third lower contact plugs 162 to 168, respectively. A first lower via 192 and a fourth lower wiring 202 may be sequentially stacked on the first lower wiring 182. A second lower via 194 and a fifth lower wiring 204 may be sequentially stacked on the second lower wiring 184. A third lower via 198 and a sixth lower wiring 208 may be sequentially stacked on the third lower wiring 186.

The second insulating interlayer 170 may be disposed on the first insulating interlayer 150, and may at least partially cover the first to sixth lower wirings 182 to 208 and the first to third lower vias 192 to 198

Each of the first and second insulating interlayers 150 and 170 may include an oxide such as, but not limited to, silicon oxide (SiO).

The CSP 240 may be disposed on the second insulating interlayer 170, and may include a conductive material such as, but not limited to, a semiconductor material doped with impurities, a metal, a metal nitride, a metal silicide, and the like.

In an example embodiment, the CSP 240 may be and/or may include a single layer including a semiconductor material doped with n-type and/or p-type impurities. In another example embodiment, the CSP 240 may have and/or may include a multi-layered structure, in which a first layer including a metal silicide (e.g., tungsten silicide (WSi)) and a second layer including a semiconductor material doped with impurities are stacked in the first direction D1. However, the present disclosure may not be limited thereto. For example, the CSP 240 may have a multi-layered structure including three or more layers sequentially stacked in the first direction D1.

In example embodiments, the CSP division layer 245 may extend in the third direction D3 on a central portion in the second direction D2 of the third region III of the substrate 100. The CSP division layer 245 may include, but not limited to, an insulating material (e.g., an oxide, a nitride, and the like).

In an embodiment, the sacrificial layer structure 290, the channel connection pattern 580, the support layer 300, and the support pattern 305 may be disposed on the CSP 240.

The channel connection pattern 580 may be disposed on the first region I of the substrate 100 and a portion of the third region III of the substrate 100 neighboring the first region I. In some embodiments, the channel connection pattern 580 may include an air gap therein.

In an embodiment, the sacrificial layer structure 290 may be disposed on the second region II of the substrate 100, and a remaining portion of the third region III of the substrate 100 except for the portion neighboring the first region I.

The support layer 300 may be disposed on the channel connection pattern 580 and the sacrificial layer structure 290. Alternatively or additionally, the support layer 300 may be disposed in a first opening 302 extending through the channel connection pattern 580 and the sacrificial layer structure 290 and exposing an upper surface of the CSP 240. In an embodiment, a portion of the support layer 300 in the first opening 302 may be referred to as a support pattern 305.

The support pattern 305 may be disposed in various layouts in a plan view. For example, a plurality of support patterns 305 may be spaced apart from each other in the second and third directions D2 and D3 on the first region I of the substrate 100. Alternatively or additionally, the support pattern 305 may extend in the third direction D3 on a portion of the second region II adjacent to the first region I of the substrate 100. In an embodiment, a plurality of support patterns 305, each of which may extend in the second direction D2, may be spaced apart from each other in the third direction D3 on the second region II of the substrate 100. In an embodiment, a plurality of support patterns 305, each of which may extend in the third direction D3, may be spaced apart from each other in the second direction D2 on the third region III of the substrate 100.

The channel connection pattern 580 may include, but not be limited to, polysilicon doped with n-type impurities or undoped polysilicon. The sacrificial layer structure 290 may include sacrificial layers (e.g., first sacrificial layer 260, second sacrificial layer 270, and third sacrificial layer 280) sequentially stacked in the first direction D1. Each of the first and third sacrificial layers 260 and 280 may include an oxide (e.g., silicon oxide (SiO)), and the second sacrificial layer 270 may include a nitride (e.g., silicon nitride (SiN)). The support layer 300 and the support pattern 305 may include a material having an etching selectivity with respect to the first to third sacrificial layers 260 to 280 such as, but not limited to, polysilicon doped with n-type impurities.

The gate electrode structure may include gate electrodes, which may be formed at a plurality of levels, respectively, spaced apart from each other in the first direction D1 on the support layer 300 and the support pattern 305. Each of the gate electrodes may extend in the second direction D2. The first insulation pattern 315 may be disposed between the gate electrodes, and between the gate electrode and the support layer 300 and/or the support pattern 305. The first insulation pattern 315 may include an oxide such as, but not limited to, silicon oxide (SiO).

In example embodiments, the gate electrode structure may include gate electrodes (e.g., first gate electrode 621, second gate electrode 623, and third gate electrode 625) sequentially stacked in the first direction D1. The first gate electrode 621 may be disposed at one or two levels, respectively. The second gate electrode 623 may be disposed at a plurality of levels, respectively. The third gate electrode 625 may be disposed at one or two levels, respectively. Although FIGS. 3 to 5 illustrate the first gate electrode 621 as being disposed at one level and the third gate electrode 625 being disposed at two levels, respectively, the present disclosure may not be limited thereto. For example, the first gate electrode 621, the second gate electrode 623, and the third gate electrode 625 may be disposed at other combinations of levels without deviating from the scope of the present disclosure.

In example embodiments, the first gate electrode 621 may serve as a ground selection line (GSL), the second gate electrode 623 may serve as a word line (WL), and the third gate electrode 625 may serve as a string selection line (SSL).

In an embodiment, the gate electrode structure may further include a gate electrode (hereinafter referred to as a gate induced drain leakage (GIDL) gate electrode) that may be configured to perform an erase operation for erasing data stored in the memory channel structure 482 by using a GIDL phenomenon. In an example embodiment, the GIDL gate electrode may be disposed at a level under the first gate electrode 621 and at a level over the third gate electrode 625. In another example embodiment, the GIDL gate electrode may be disposed at a level between the second gate electrode 623 and the third gate electrode 625, and at a level under the first gate electrode 621.

In example embodiments, the gate electrode structure may have a staircase shape in which a length in the second direction D2 decreases in a stepwise manner in the first direction D1 from a lowermost level toward an uppermost level, and may include steps arranged in the second direction D2 on the second region II of the substrate 100. The gate electrode structure may further include steps arranged in the third direction D3 on the second region II of the substrate 100.

Hereinafter, a portion of the gate electrodes corresponding to the step of the gate electrode structure, that is, an end portion of each of the gate electrodes that may not overlapped by upper ones of the gate electrodes, may be referred to as a pad. As such, the pad of each of the gate electrodes may be disposed on the second region II of the substrate 100.

The gate electrode structure may further include steps disposed in a second direction D2 at an upper level on an edge portion of the third region III adjacent to the first region I of the substrate 100 in the second direction D2. That is, the gate structure may have a staircase shape at levels where the third gate electrodes 625 serving as SSLs may be disposed on the edge portion of the third region III adjacent to the first region I of the substrate 100.

Thus, the third gate electrode 625 may include the pad disposed on the second region II of the substrate 100 and the pad disposed on the edge portion of the third region III of the substrate 100. For example, FIG. 3 illustrates that the gate structure has a staircase shape at upper two levels where the third gate electrodes 625 may be disposed.

Each of the first to third gate electrodes 621 to 625 may include a gate conductive pattern and a gate barrier pattern at least partially covering a surface of the gate conductive pattern. The gate conductive pattern may include a metal having a low resistance such as, but not limited to, tungsten (W), titanium (Ti), tantalum (Ta), platinum (Pt), and the like. The gate barrier pattern may include a metal nitride such as, but not limited to, titanium nitride (TiN), tantalum nitride (TaN), and the like.

In example embodiments, a plurality of gate electrode structures may be spaced apart from each other in the third direction D3 on the first and second regions I and II of the substrate 100 and the edge portion of third region III of the substrate 100 neighboring the first region I in the second direction D2.

The third division pattern 632, which may extend in the second direction D2 on the first and second regions I and II of the substrate 100 and on the edge portion of the third region III of the substrate 100 neighboring the first region I, may be disposed between the gate structures adjacent to each other in the third direction D3. The sixth division pattern 636, which may extend in the third direction D3, may be disposed at end portions in the second direction D2 of the gate structures on the edge portion of the third region III of the substrate 100. A plurality of third division patterns 632 may be spaced apart from each other in the third direction D3. A plurality of sixth division patterns 636 may be spaced apart from each other in the second direction D2. In an example embodiment, the sixth division pattern 636 may be disposed on each of opposite edge portions in the second direction D2 of the third region III of the substrate 100.

In each of the gate structures, the fourth division pattern 633 spaced apart from each other in the second direction D2 may be disposed between the third division patterns 632 adjacent to each other in the third direction D3 on the first and second regions I and II of the substrate 100 and the edge portion of the third region III adjacent to the first region I, and fifth division patterns 634 spaced apart from each other in the second direction D2 may be disposed between the third and fourth division patterns 632 and 633 adjacent to each other in the third direction D3 on the second region II of the substrate 100.

Each of the third to fifth division patterns 632 to 634 may extend through the third to sixth insulating interlayers 340 to 530, the gate electrode structure, the first insulation pattern 315, and the support pattern 305, and may contact an upper surface of the CSP. In some embodiments, the fifth division pattern 634 may extend through the third to sixth insulating interlayers 340 to 530, the gate electrode structure, the first insulation pattern 315, the support layer 300, and the channel connection pattern 580, and may contact the upper surface of the CSP.

In example embodiments, the fourth division pattern 633 may continuously extend in the second direction D2 on the first region I of the substrate 100 and portions of the second and third regions II and III of the substrate 100 adjacent to the first region I in the second direction D2. Alternatively or additionally, a plurality of fourth division pattern 633 may be spaced apart from each other in the second direction D2 on a remaining portion of the second region II. Thus, each of the gate structures on the second region II of the substrate 100 may not be completely divided by the fourth division pattern 633.

In example embodiments, a plurality of fifth division patterns 634 may be spaced apart from each other in the second direction D2 on the second region II of the substrate 100. Consequently, each of the gate structures on the second region II of the substrate 100 may not be completely divided by the fifth division pattern 634.

The first division pattern 330 may extend through the first gate electrode 621 on the second region II of the substrate 100, and a plurality of first division patterns 330 may be spaced apart from each other in the second and third directions D2 and D3, respectively. In example embodiments, the first division pattern 330 may contact an end portion of the fourth division pattern 633 in the second direction D2.

The second division pattern 410 may extend in the second direction D2 on the first region I of the substrate 100 and the portions of the second and third regions II and III of the substrate 100 adjacent to the first region I in the second direction D2. The second division pattern 410 may extend through upper portion of each of the gate structures, that is, upper two levels where the third gate electrode 625 may be formed. Thus, each of the third gate electrodes 625 may be additionally separated in the third direction D3 by the second division pattern 410.

In example embodiments, a plurality of memory blocks, each of which may include the gate electrode structure and the memory channel structures 482 in an area defined by ones of the third division patterns 632 adjacent to each other in the third direction D3 and the sixth division pattern 636, may be spaced apart from each other in the third direction D3 to form a memory block column. A plurality of memory block columns may be disposed at opposite sides, respectively, in the second direction D2 with respect to the third region III of the substrate 100.

In an example embodiment, each of the memory blocks may include two first gate electrodes 621 divided by the first division pattern 330, one second gate electrode 623, and four third gate electrodes 625 divided by the second and fourth division patterns 410 and 633 at each level, however the present disclosure may not be limited thereto. In another example embodiment, each of the memory blocks may include two first gate electrodes 621, one second gate electrode 623, and six third gate electrodes 625 at each level.

In example embodiments, a width of each of the third to fifth division patterns 632 to 634 in the third direction D3 may decrease from an uppermost level toward a lowermost level, and a width of the sixth division pattern 636 in the second direction D2 may decrease from an uppermost level toward a lowermost level. Thus, a sidewall of each of the third to fifth division patterns 632 to 634 in the third direction D3 and a sidewall of the sixth division pattern 636 in the second direction D2 may be inclined with respect to the upper surface of the substrate 100.

A sidewall of an end portion of the third division pattern 632 in the second direction D2 on the second region II of the substrate 100 may be inclined with respect to the upper surface of the substrate 100. Each of opposite sidewalls of the fourth and fifth division patterns 633 and 634 in the second direction D2 on the second region II of the substrate 100 may be inclined with respect to the upper surface of the substrate 100.

The end portion of each of the third and fourth division patterns 632 and 633 in the second direction D2 on the third region III of the substrate 100 may contact and/or may be connected (e.g., coupled) to the sixth division pattern 636. In example embodiments, a portion of the sixth division pattern 636 crossing the third and fourth division patterns 632 and 633 may have a width smaller (e.g., narrower) than those of other portions of the sixth division pattern 636. A portion of each of the third and fourth division patterns 632 and 633 crossing the sixth division pattern 636 may have a width smaller than those of other portions of each of the third and fourth division patterns 632 and 633.

For example, a width (e.g., a maximum width) in the second direction D2 of a portion of the sixth division pattern 636 contacting each of the third and fourth division patterns 632 and 633 may be smaller than widths (e.g., a maximum width) in the second direction D2 of other portions of the sixth division pattern 636. As another example, a width (e.g., a maximum width) in the third direction D3 of the end portion of each of the third and fourth division patterns 632 and 633 contacting the sixth division pattern 636 may be smaller than widths (e.g., a maximum width) in the third direction D3 of other portions of each of the third and fourth division patterns 632 and 633.

In example embodiments, the end portion in the second direction D2 of each of the fourth and fifth division patterns 633 and 634 on the second region II of the substrate 100 may have a width (e.g., a maximum width) in the third direction D3 smaller than widths of other portions thereof. Alternatively or additionally, a first end portion closer to the first region I of the substrate 100 among the opposite end portions in the second direction D2 of one of the fifth division patterns 634 that is closest to the first region I of the substrate 100 may have a width (e.g., a maximum width) in the third direction D3 substantially the same as widths (e.g., a maximum width) in the third direction D3 of other portions of the one of the fifth division patterns 634, as shown in FIG. 2B.

Each of the first to sixth division patterns 330 to 636 may include an oxide such as, but not limited to, silicon oxide (SiO).

The memory channel structure 482 may be disposed on the first region I of the substrate 100, and may contact the upper surface of the CSP 240. The memory channel structure 482 may extend through the channel connection pattern 580, the support layer 300, the gate electrode structure, the first insulation pattern 315, and the fourth and fifth insulating interlayers 350 and 400.

In example embodiments, the memory channel structure 482 may include a filling pattern 462 having a pillar shape extending in the first direction D1, a channel 452 on a sidewall of the filling pattern 462 having a cup shape, a capping pattern 472 contacting upper surfaces of the filling pattern 462 and the channel 452, and a charge storage structure 442 on an outer sidewall of the channel 452 and a sidewall of the capping pattern 472.

The charge storage structure 442 may include a tunnel insulation pattern 432, a charge storage pattern 422 and a first blocking pattern 412 sequentially stacked in the horizontal direction from an outer sidewall of the channel 452.

The channel 452 may include, but not be limited to, undoped polysilicon. The filling pattern 462 may include an oxide such as, but not limited to, silicon oxide (SiO). The capping pattern 472 may include, but not be limited, polysilicon doped with impurities.

The tunnel insulation pattern 432 may include an oxide such as, but not limited to, silicon oxide (SiO). The charge storage pattern 422 may include a nitride such as, but not limited to, silicon nitride (SiN). The first blocking pattern 412 may include a nitride such as, but not limited to, silicon nitride (SiN).

In example embodiments, a plurality of memory channel structures 482 may be spaced apart from each other in the second and third directions D2 and D3 on the first region I of the substrate 100 to form a memory channel structure array. The plurality of memory channel structures 482 included in the memory channel structure array may be connected to each other by the channel connection pattern 580. For example, the charge storage structure 442 may not be disposed on a portion of the outer sidewall of each of the channels 452. As another example, the channel connection pattern 580 may contact the outer sidewalls of the channels 452 so that the channels 452 may be electrically connected (e.g., coupled) to each other.

The first support structure 520 may be disposed on the third region III of the substrate 100, and may contact the upper surface of the CSP 240. The first support structure 520 may extend through the sacrificial layer structure 290, the support layer 300, the gate electrode structure, the first insulation pattern 315, and the third to fifth insulating interlayers 340 to 400.

In example embodiments, a plurality of first support structures 520 may be spaced apart from each other in the second and third directions D2 and D3 on the third region III of the substrate 100 to form a first support structure array. The first support structure array may include a plurality of first support structure columns each of which may include ones of the plurality of first support structures 520 disposed in the third direction D3.

In example embodiments, the first support structure 520 may be disposed on a portion of the third region III of the substrate 100 adjacent to each of the sixth division patterns 636. Although FIG. 2A shows two first support structure columns formed on the portion of third region III of the substrate 100 adjacent to each of the sixth division patterns 636, the present disclosure may not be limited thereto. For example, one or a plurality of first support structure columns spaced apart from each other in the second direction D2 may be formed on the portion of the third region III of the substrate 100 adjacent to each of the sixth division patterns 636.

The second support structure 525 may be disposed on the second region II of the substrate 100, and may contact the upper surface of the CSP 240. The second support structure 525 may extend through the sacrificial layer structure 290, the support layer 300, the gate electrode structure, the first insulation pattern 315, and the third to fifth insulating interlayers 340 to 400.

A plurality of second support structures 525 may be spaced apart from each other in the second and third directions D2 and D3 on the second region II of the substrate 100. In example embodiments, the second support structures 525 may extend through pads of the first to third gate electrodes 621 to 625 included in the gate electrode structure, and may be respectively disposed at vertices of a rectangle within each of the pads, in a plan view.

In example embodiments, each of the first and second support structures 520 and 525 may include a vertical extension portion having a pillar shape extending in the first direction D1, and protrusion portions respectively protruding in the horizontal direction from a sidewall of the vertical extension portion. The protrusion portions may be disposed on portions of a sidewall of the vertical extension portion facing the first to third gate electrodes 621 to 625 and/or the second sacrificial layer 270 included in the second sacrificial layer structure 290, respectively. Consequently, a plurality of protrusion portions may be spaced apart from each other in the first direction D1.

In example embodiments, a first protrusion portion at an uppermost level in each of the first and second support structures 520 and 525 may have a width greater than widths of second protrusion portions 502 at other levels, respectively, under the uppermost level. In an example embodiment, the vertical extension portion and the protrusion portion may include an oxide (e.g., silicon oxide (SiO), so that the vertical extension portion and the protrusion portion may be merged with each other. In another example embodiment, the vertical extension portion and the first protrusion portion among the protrusion portions may include a conductive material, and the second protrusion portions 502 among the protrusion portions may include an oxide such as, but not limited to, silicon oxide (SiO).

The fourth sacrificial pattern 325 may be disposed on a central portion of the third region III of the substrate 100 in the second direction D2, and may be interposed between the first insulation patterns 315 spaced apart from each other in the first direction D1, and on an uppermost one of first insulation patterns 315. The third insulation pad 326 may be disposed on the uppermost one of the fourth sacrificial patterns 325. Each of the fourth sacrificial pattern 325 and the third insulation pad 326 may include a nitride such as, but not limited to, silicon nitride (SiN).

The second blocking pattern 615 may cover upper and lower surfaces of each of the first to third gate electrodes 621 to 625, and sidewalls of each of the first to third gate electrodes 621 to 625 facing the memory channel structure 482, the first and second support structures 520 and 525, and the second division pattern 410. The second blocking pattern 615 may also contact sidewalls of the fourth sacrificial pattern 325 and the third insulation pad 326. The second blocking pattern 615 may include a metal oxide such as, but not limited to, aluminum oxide (Al₂O₃), hafnium oxide (HfO), and the like.

The third insulating interlayer 340 may be disposed on the CSP 240, and may at least partially cover sidewalls of the gate electrode structure and the first insulation pattern 315. The fourth and fifth insulating interlayers 350 and 400 may be stacked on the third insulating interlayer 340 and the first insulation pattern 315.

The sixth to eighth insulating interlayers 530 to 700 may be sequentially stacked on the fifth insulating interlayer 400, the memory channel structure 482, and the first and second support structures 520 and 525.

The first upper contact plug 680 may extend in the first direction D1 through the third to seventh insulating interlayers 340 to 650, the gate electrode structure, the first insulation pattern 315, the support layer 300, the sacrificial layer structure 290, the CSP 240, and an upper portion of the second insulating interlayer 170 on the second region II of the substrate 100. The first upper contact plug 680 may contact an upper surface of the sixth lower wiring 208. In example embodiments, each of the first upper contact plugs 680 may extend through a pad of a corresponding gate electrode included in the gate electrode structure, and may be disposed in an area surrounded by the second support structures 525 in a plan view.

In example embodiments, the first upper contact plug 680 may include a vertical extension portion having a pillar shape extending in the first direction D1, and a protrusion portion protruding in the horizontal direction from a sidewall of the vertical extension portion. The protrusion portion may be disposed on and contact a portion of a sidewall facing an uppermost one of the first to third gate electrodes 621 to 625 through which the first upper contact plug 680 extends. The fourth insulation pattern 674 may be disposed on portions of the sidewall facing other ones of the first to third gate electrodes 621 to 625 through which the first upper contact plug 680 extends. The fifth insulation pattern 676 may be disposed on a portion of the sidewall facing the second sacrificial layer 270 included in the sacrificial film structure 290.

Thus, the first upper contact plug 680 may be electrically connected only to the uppermost one of the first to third gate electrodes 621 to 625, and may be electrically insulated from the other ones of the first to third gate electrodes 621 to 625.

Each of the fourth and fifth insulation patterns 674 and 676 may include an oxide such as, but not limited to, silicon oxide (SiO).

The second upper contact plug 710 may extend through the third to eighth insulating interlayers 340 to 700, the first insulation pattern 315 and the second blocking pattern 615 on the third region III of the substrate 100. The second upper contact plug 710 may contact a pad of an uppermost one of the third gate electrodes 625. Alternatively or additionally, the second upper contact plug 710 may extend through the third to eighth insulating interlayers 340 to 700 and the second blocking pattern 615, and may contact a pad of a second one of the third gate electrodes 625 that is disposed at a second level from above. In an example embodiment, the second upper contact plug 710 may be disposed in an area surrounded by the second support structures 525 in a plan view.

The third upper contact plug 720 may extend through the sixth to eighth insulating interlayers 530 to 700, and may contact an upper surface of the capping pattern 472 included in the memory channel structure 482. The upper via 730 may extend through the eighth insulating interlayer 700, and may contact an upper surface of the first upper contact plug 680.

Each of the first to third upper contact plugs 680 to 720 and the upper via 730 may include a conductive material, such as, but not limited to, a metal, a metal nitride, a metal silicide, and the like.

Alternatively or additionally, upper wirings electrically connected to the second and third upper contact plugs 710 and 720 and the upper via 730 may be formed, and some of the upper wirings may serve as bit lines. Each of the bit lines may extend in the third direction D3, and the bit lines may be spaced apart from each other in the second direction D2.

As described above, the portion of the sixth division pattern 636, which may extend in the third direction D3 through the gate electrode structure, contacting the third and fourth division patterns 632 and 633, which may extend in the second direction D2 through the gate electrode structure, may have a smaller width than those of the other portions of the sixth division pattern 636. As a result, the semiconductor device including the sixth division pattern 636 may have an improved degree of integration when compared to related semiconductor devices.

Alternatively or additionally, each of the end portions in the second direction D2 of the fourth division pattern 633 or the fifth division pattern 634, which may extend in the second direction D2 to a given length, may have a width smaller than those of other portions of the fourth division pattern 633 or the fifth division pattern 634. Consequently, the semiconductor device including the fourth and fifth division patterns 633 and 634 may have an improved degree of integration when compared to related semiconductor devices.

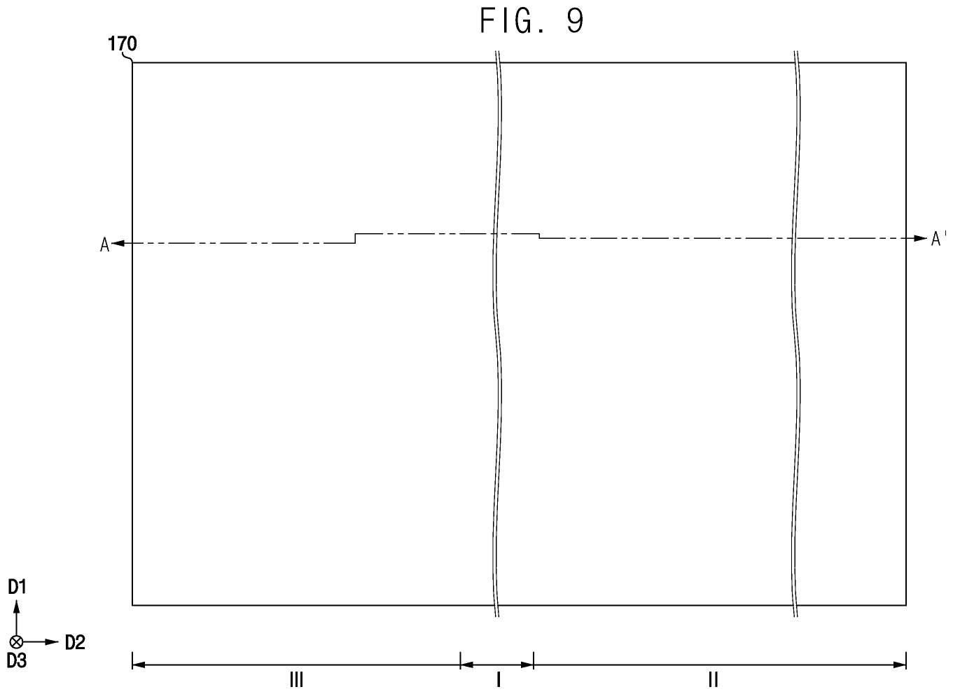

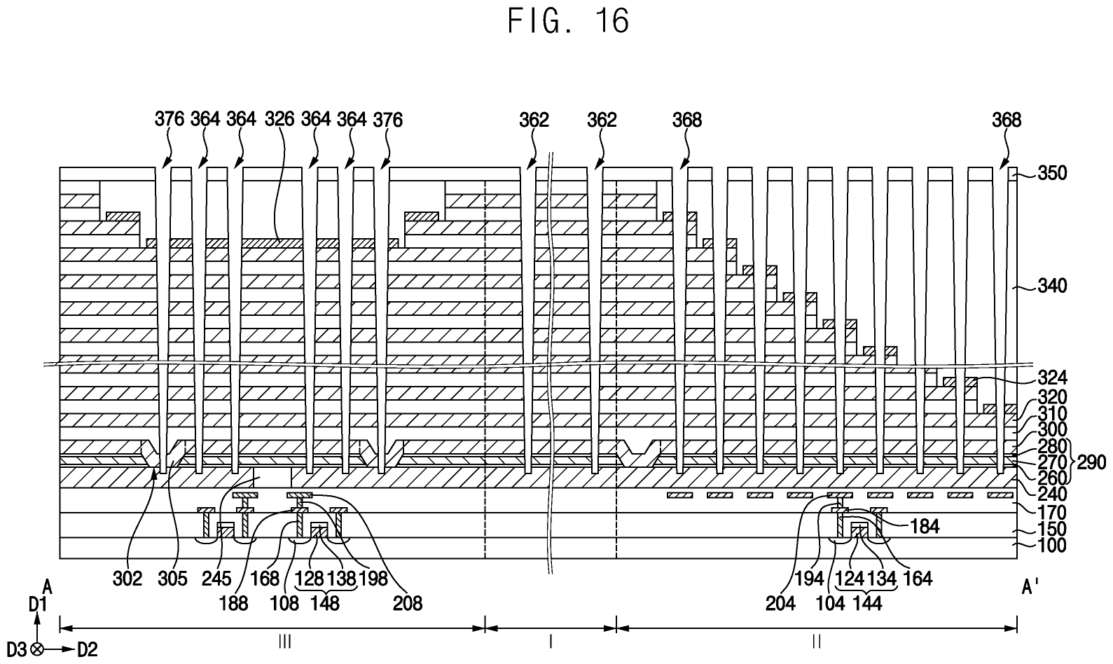

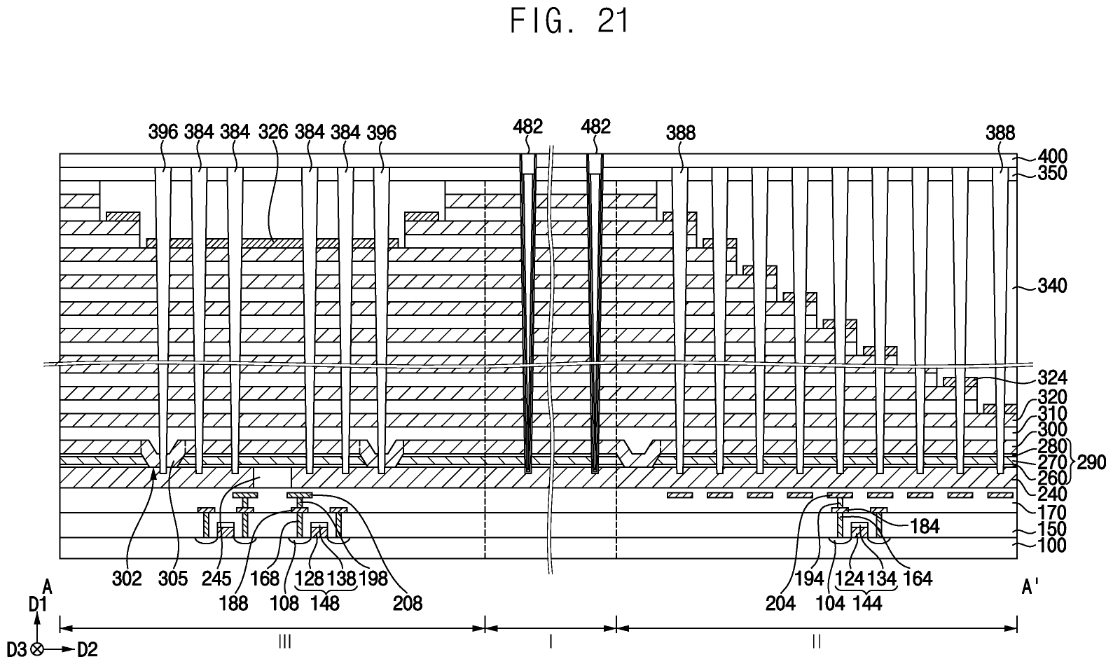

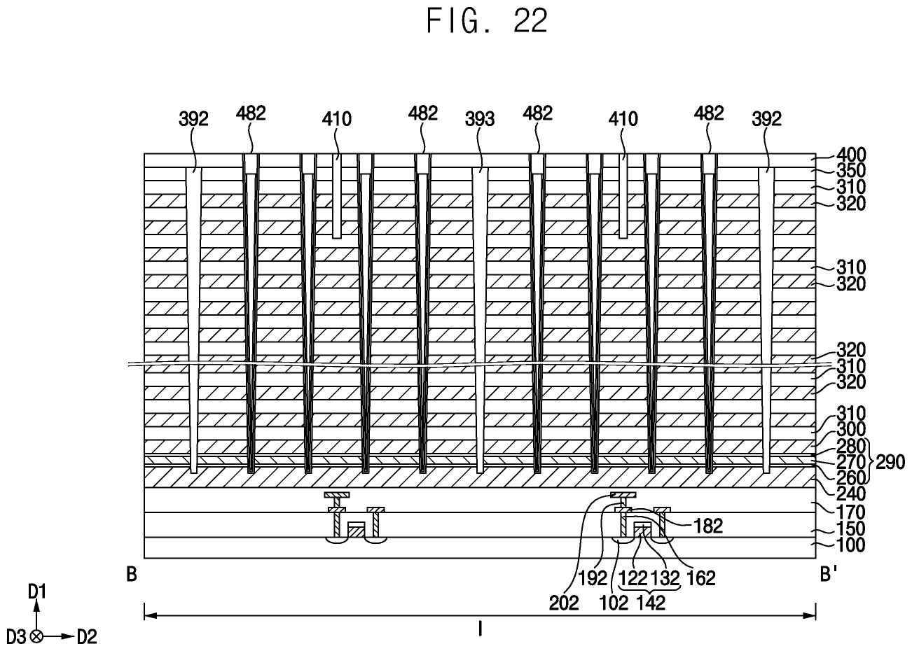

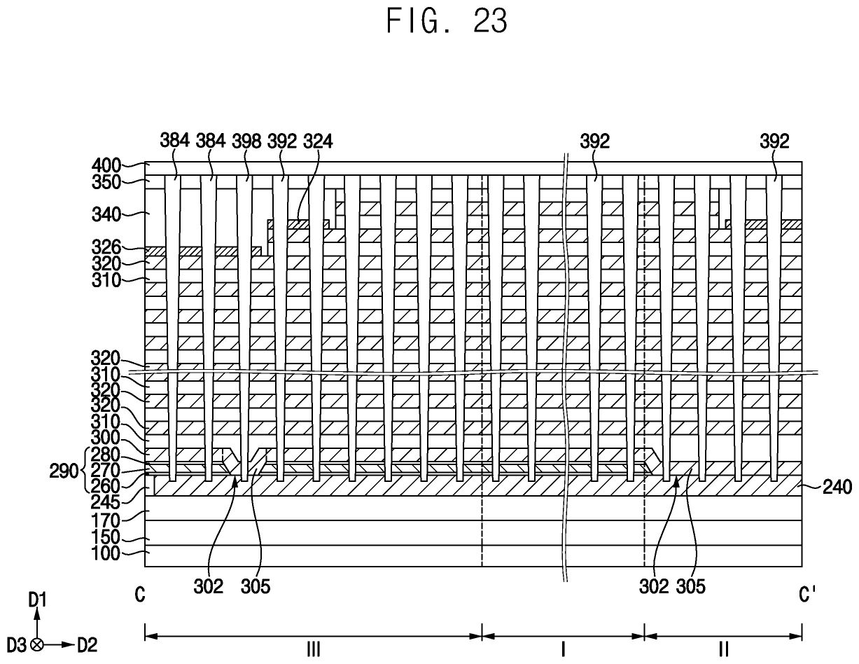

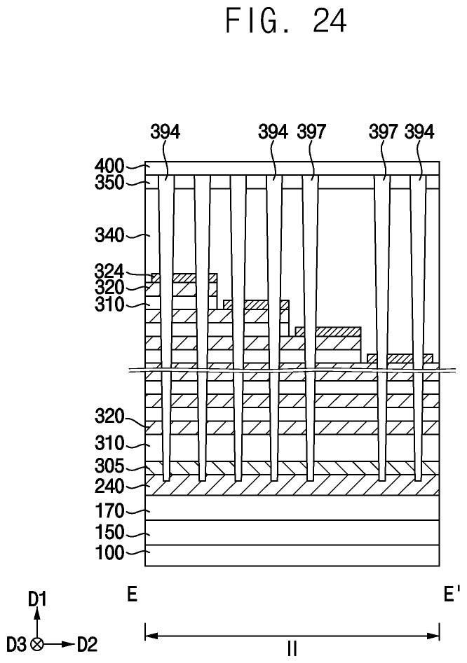

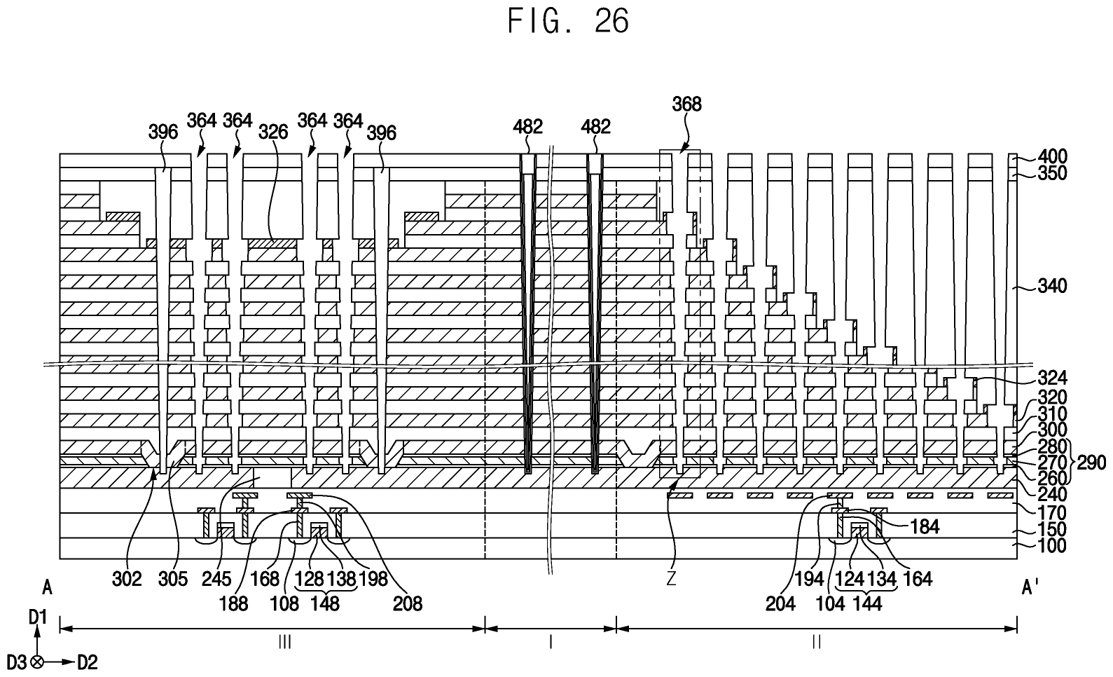

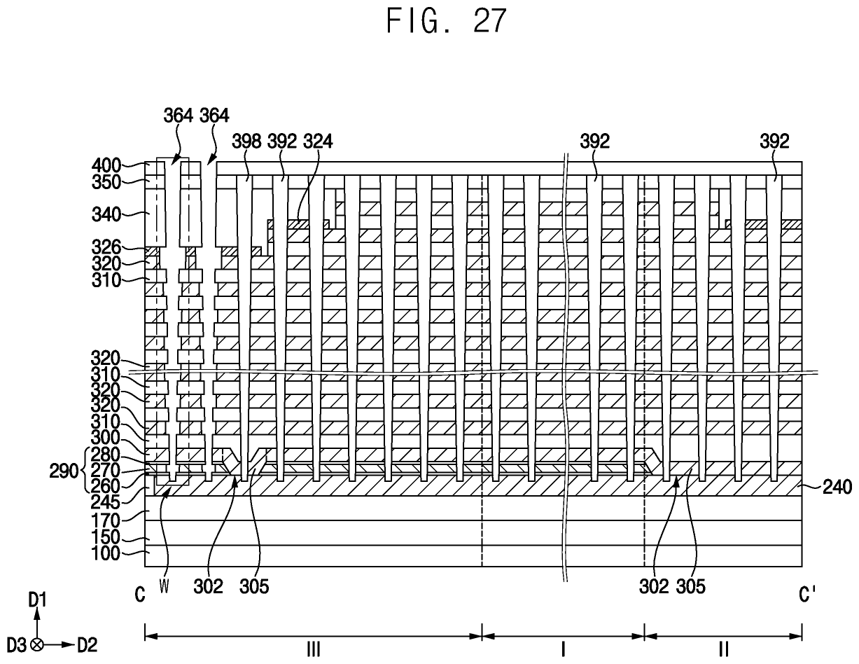

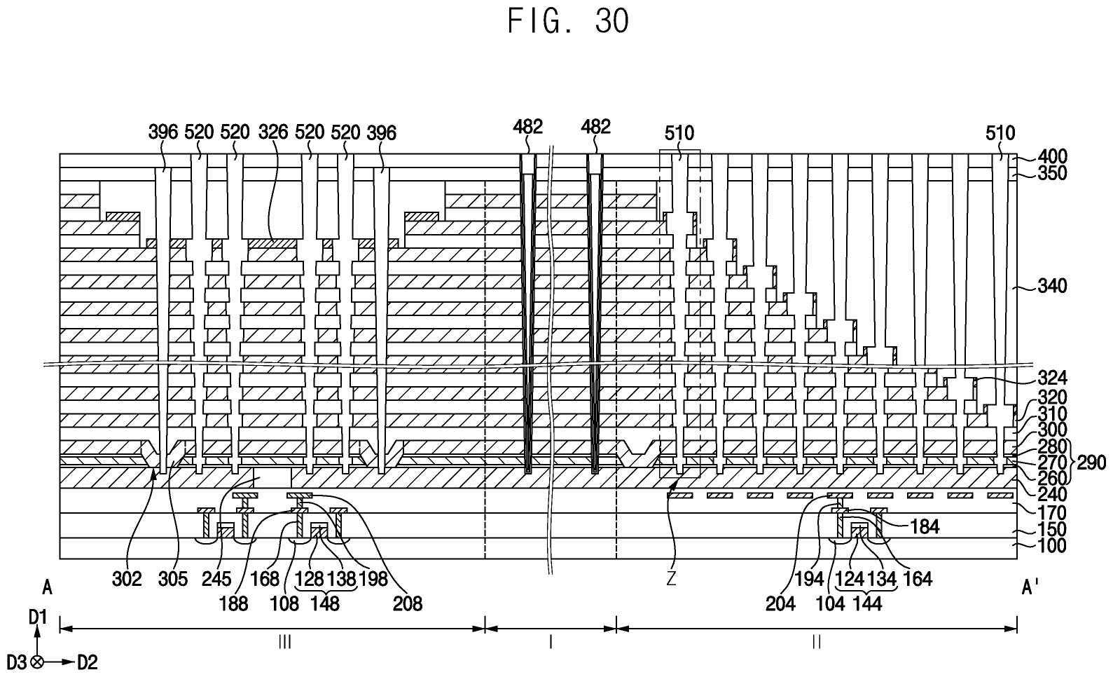

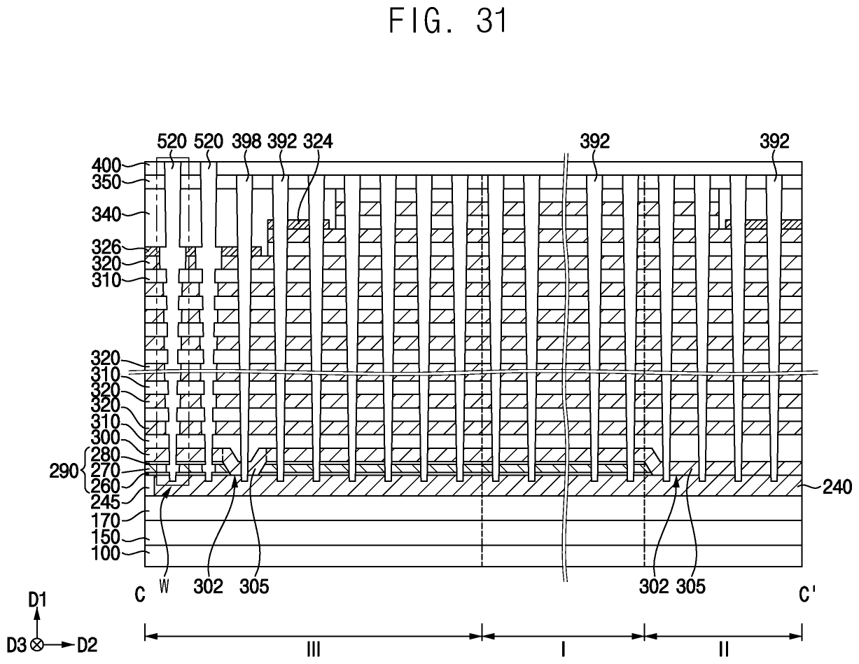

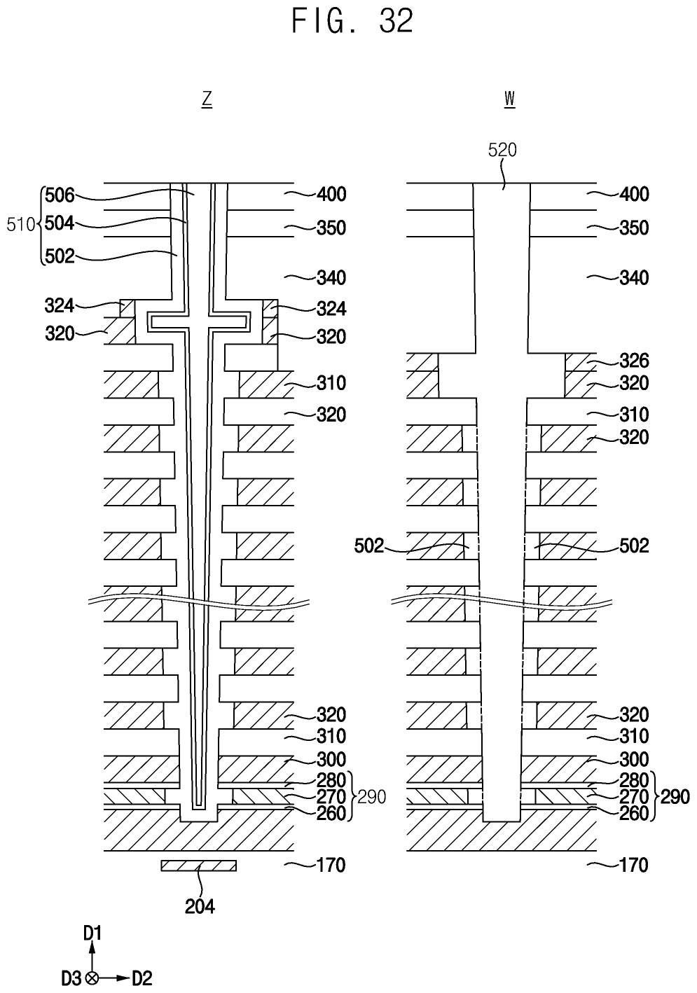

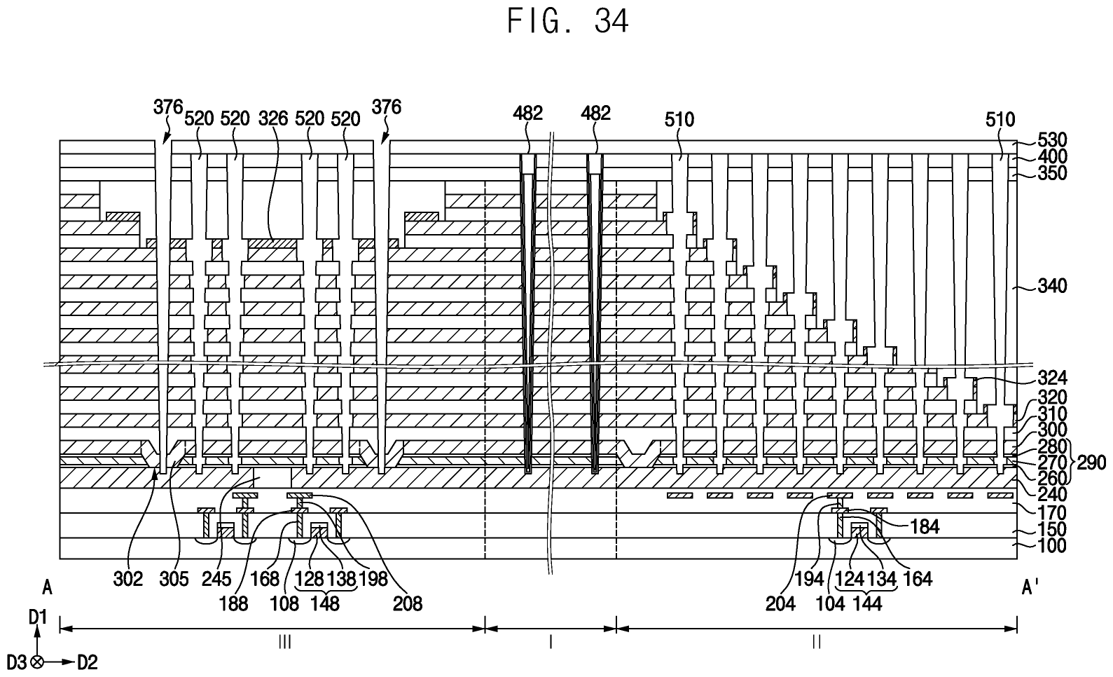

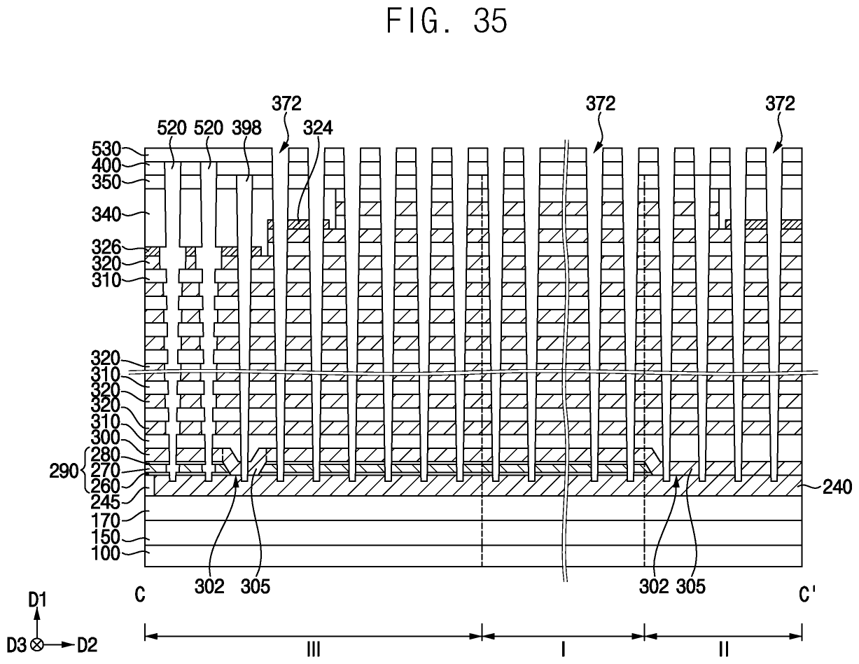

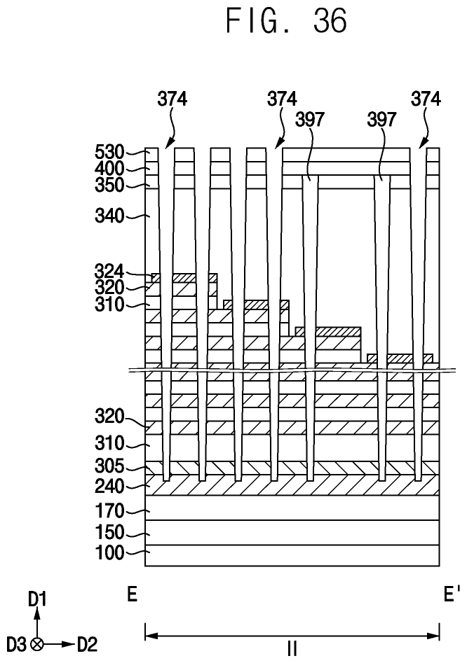

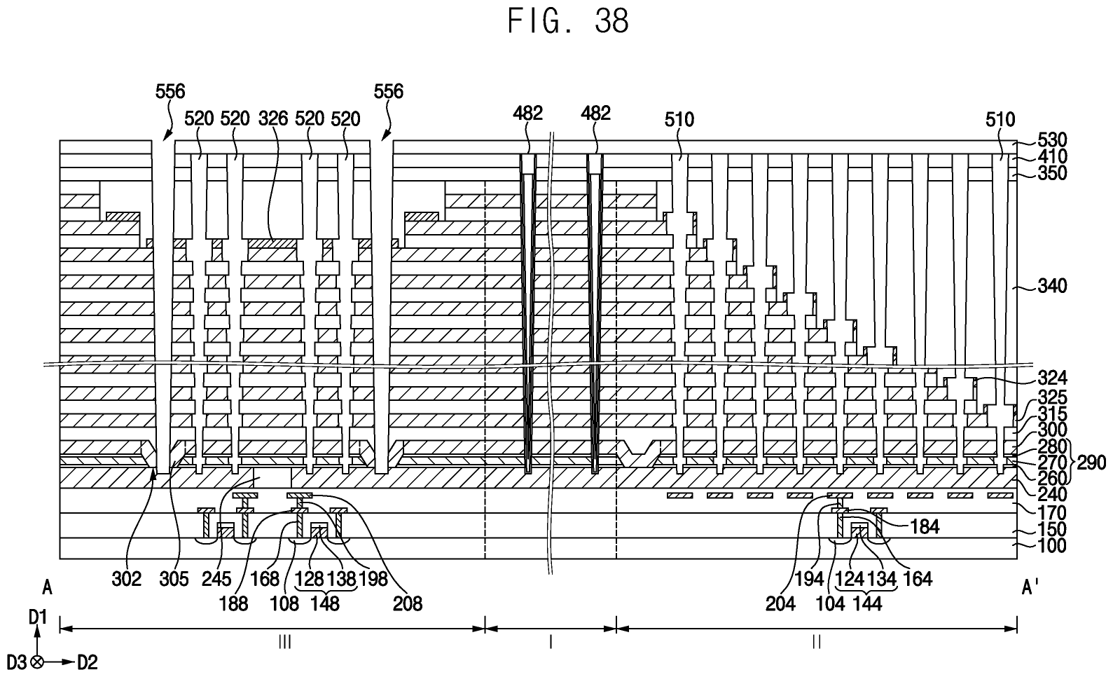

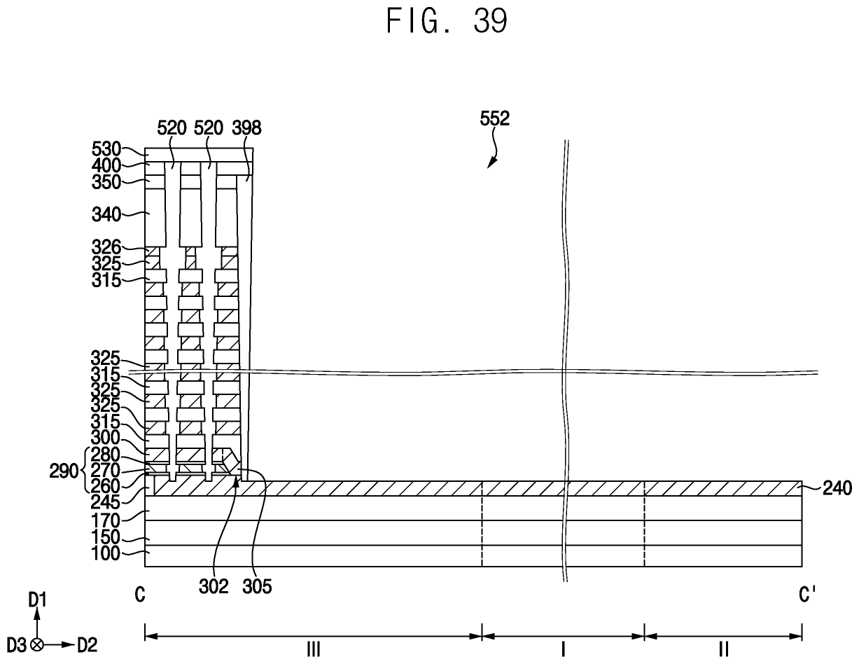

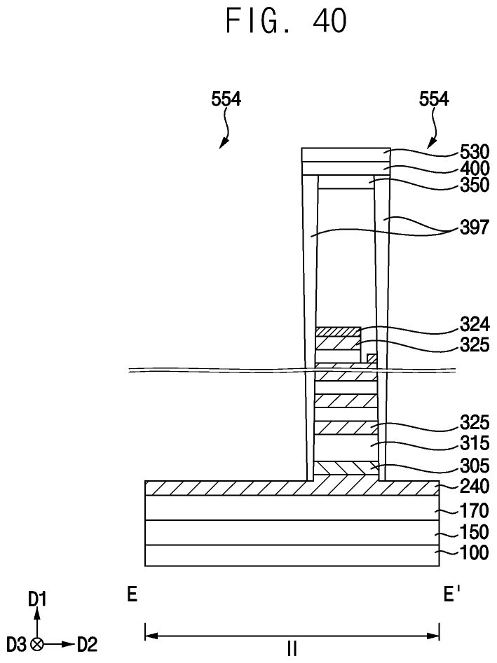

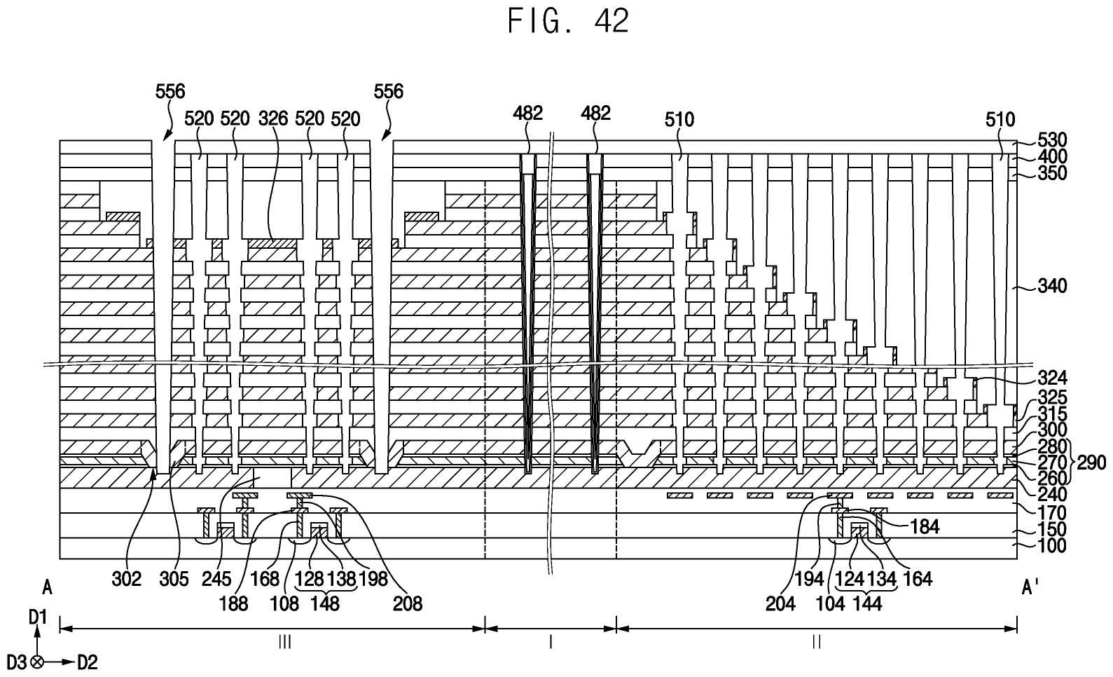

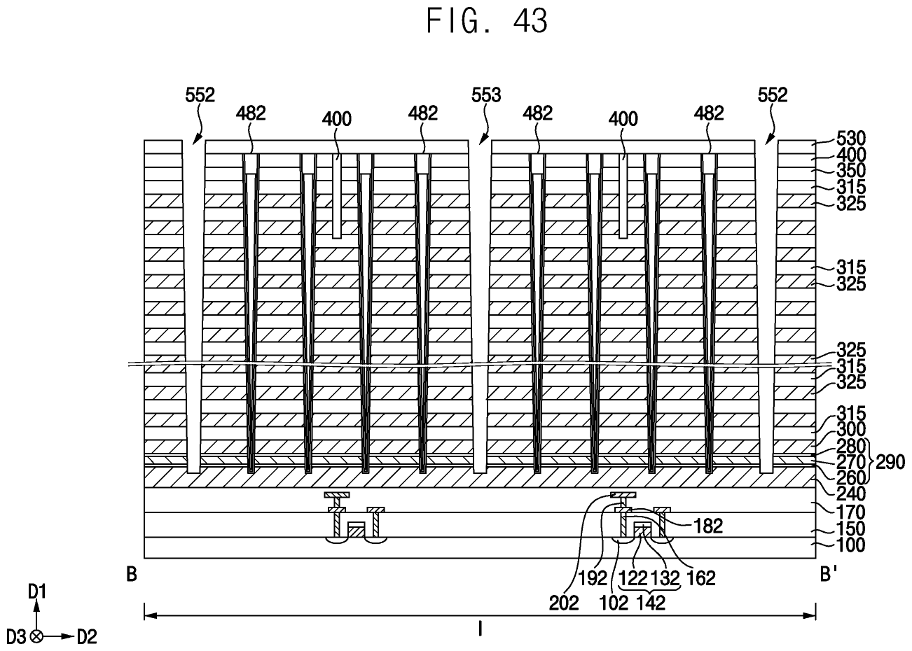

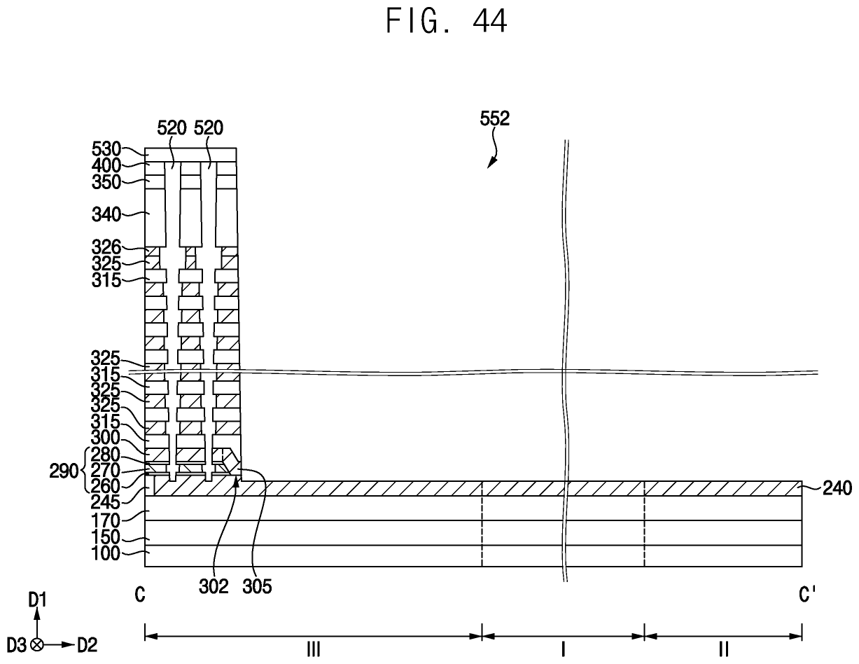

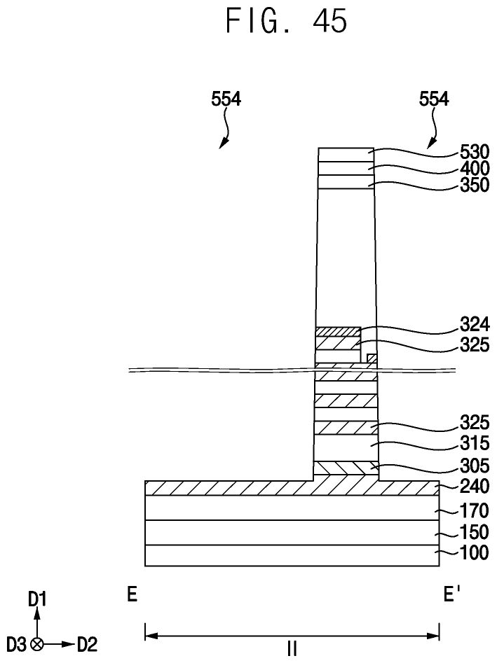

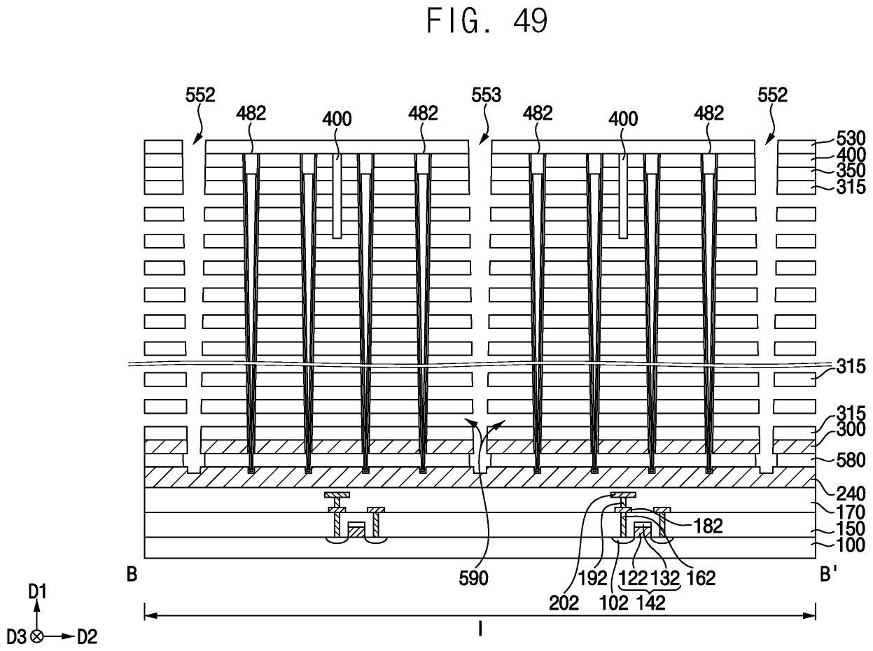

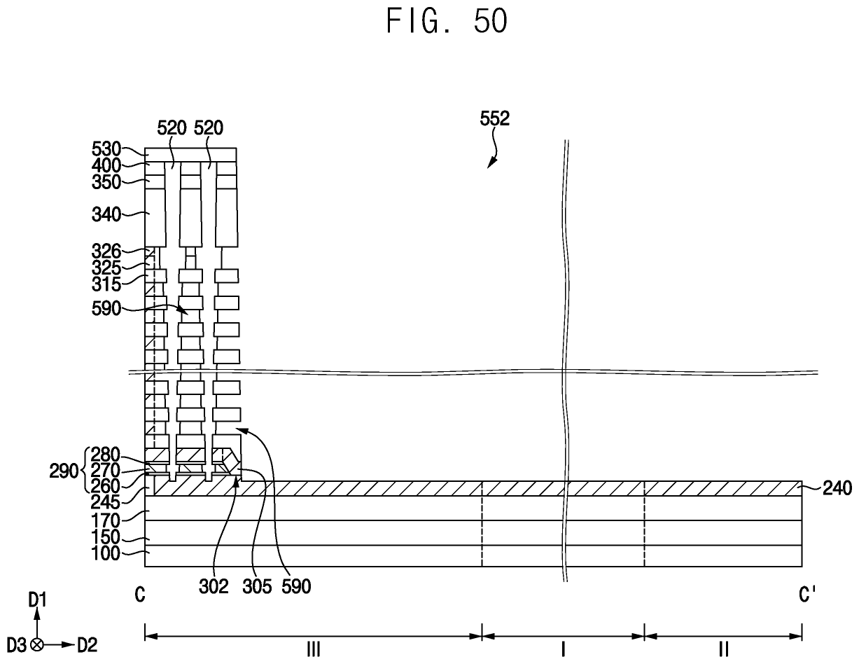

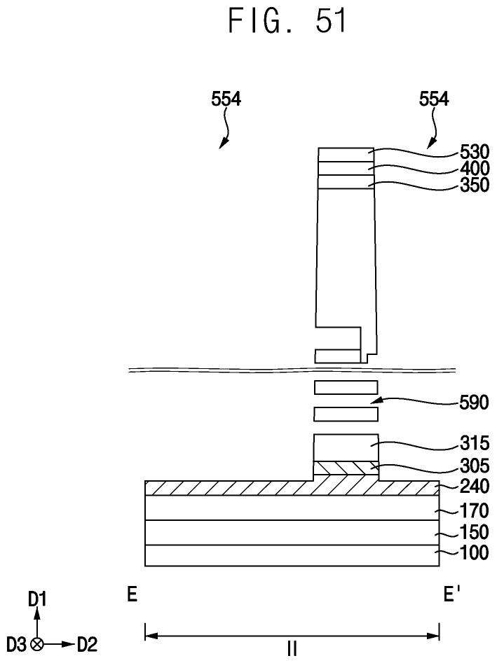

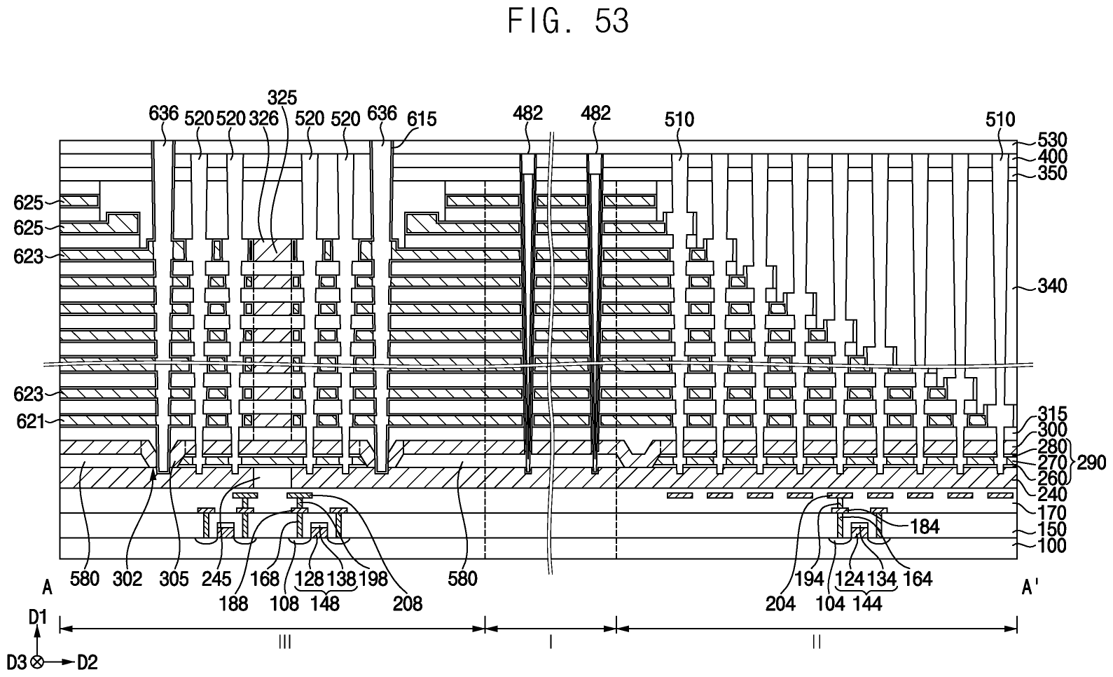

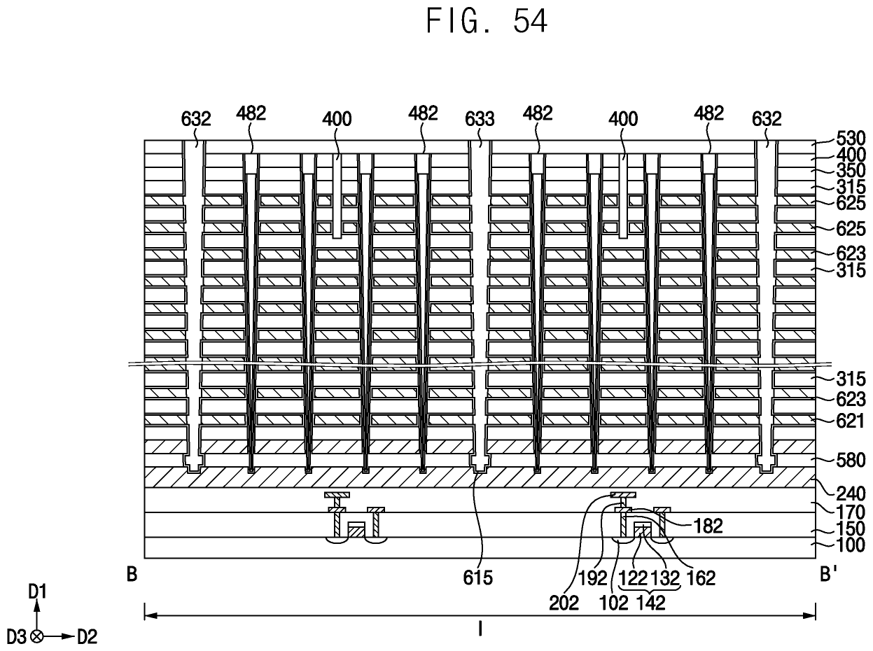

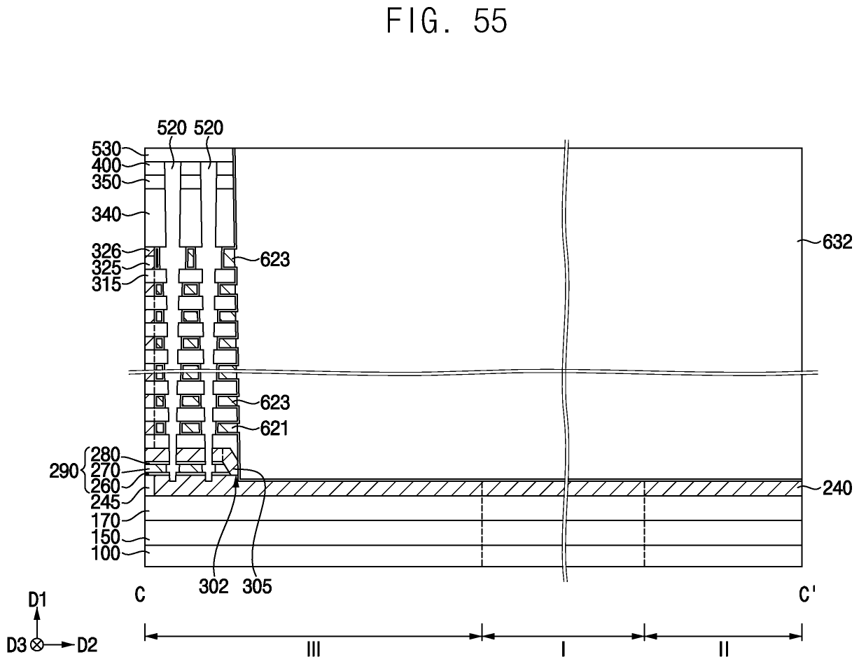

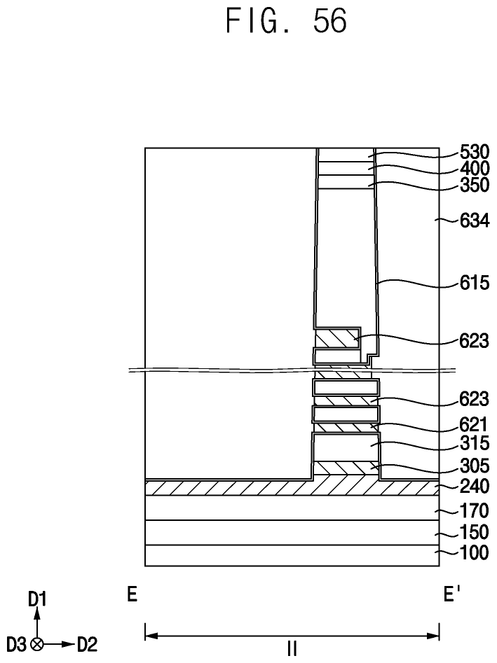

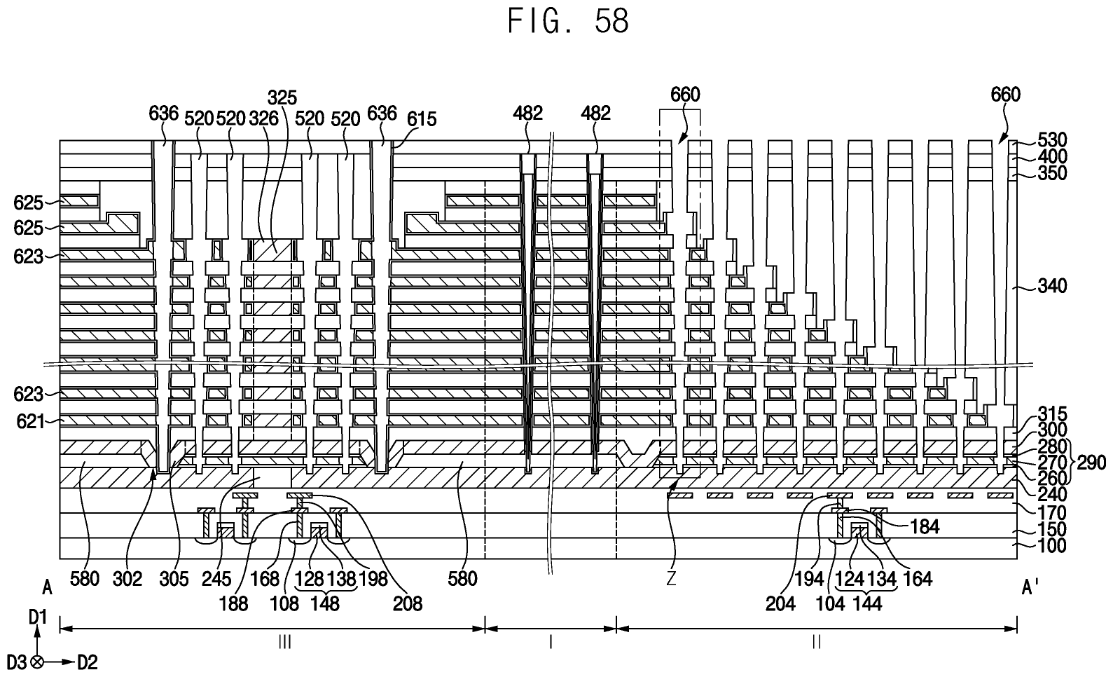

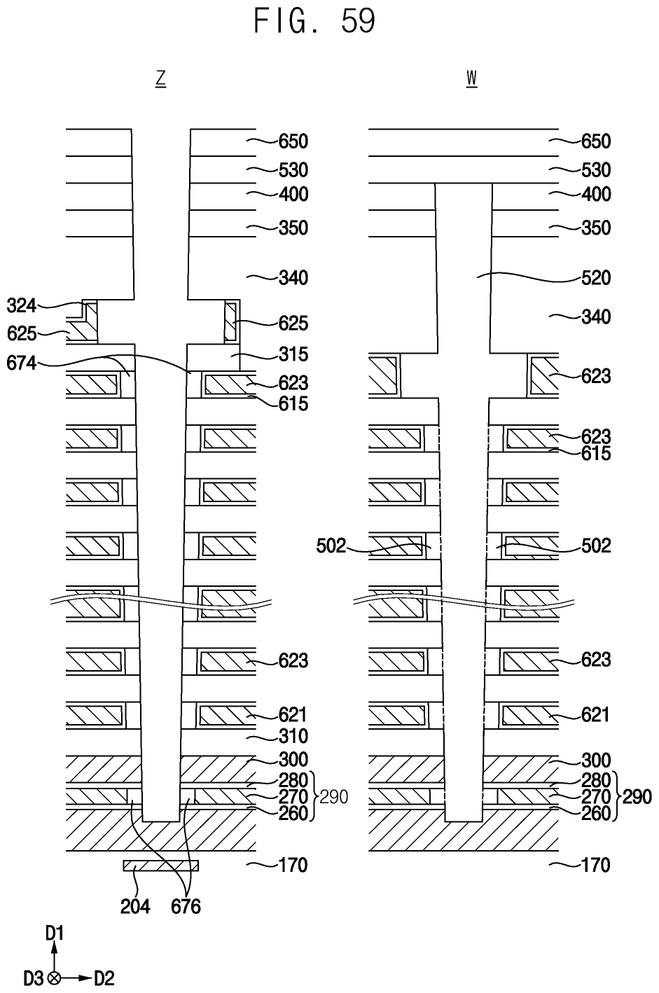

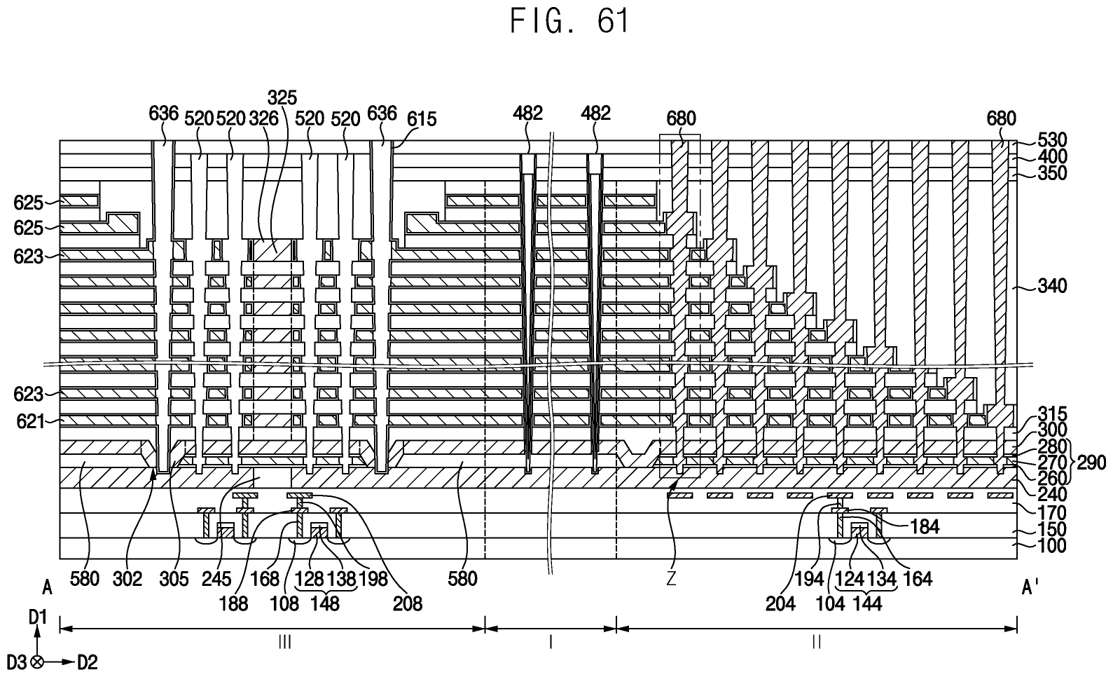

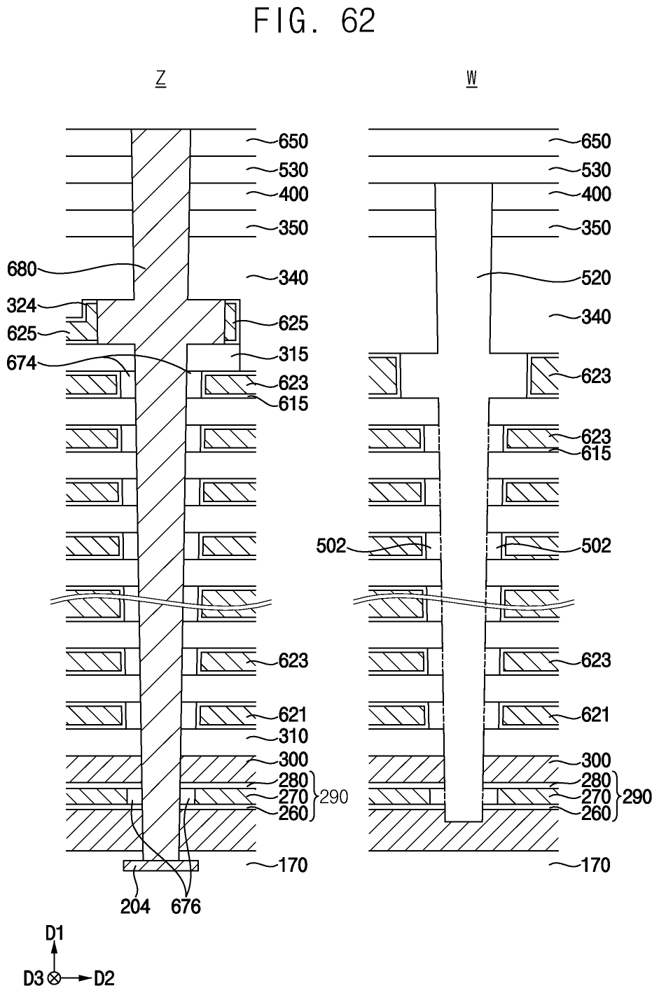

The characteristics of the semiconductor device having the improved degree of integration due to the shapes of the third to sixth division patterns 632 to 636 are described below with reference to FIGS. 9 to 62.

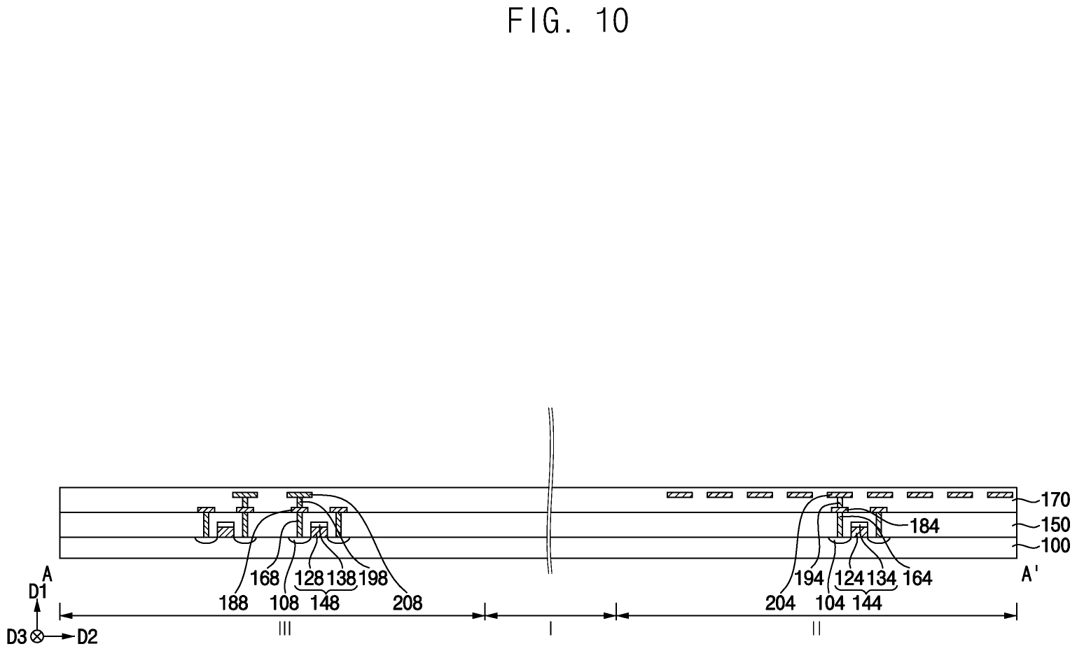

FIGS. 9 to 62 are plan views and cross-sectional views illustrating a method of manufacturing a semiconductor device. Particularly, FIGS. 9, 12, 15, 20, 25, 29, 33, 37, 41, 52, 57 and 60 are the plan views, and FIGS. 10, 11, 13, 14, 16-19, 21-24, 26-28, 30-32, 34-36, 38-40, 42-51, 53-56, 58, 59, 61, and 62 are the cross-sectional views.

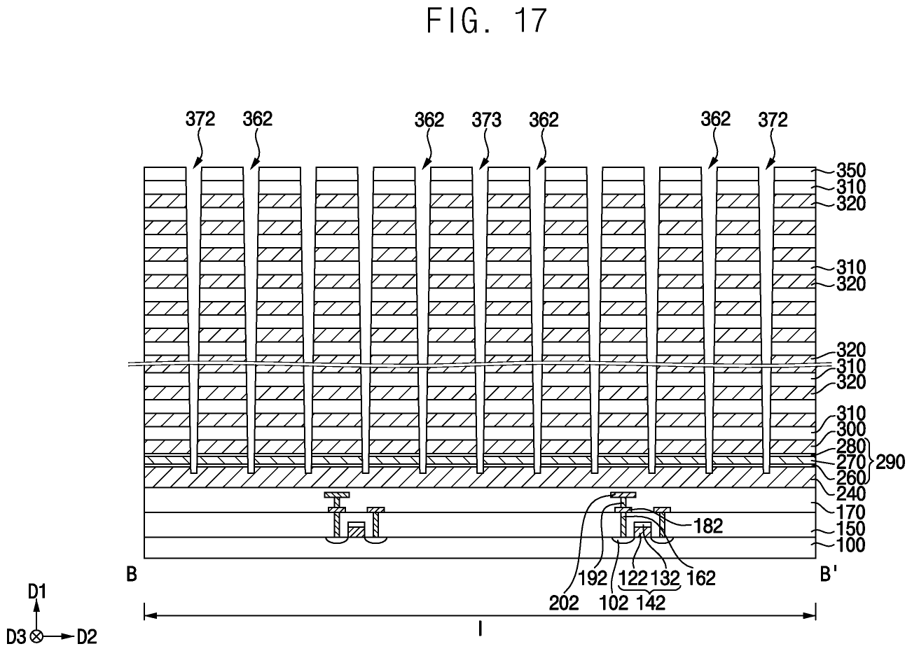

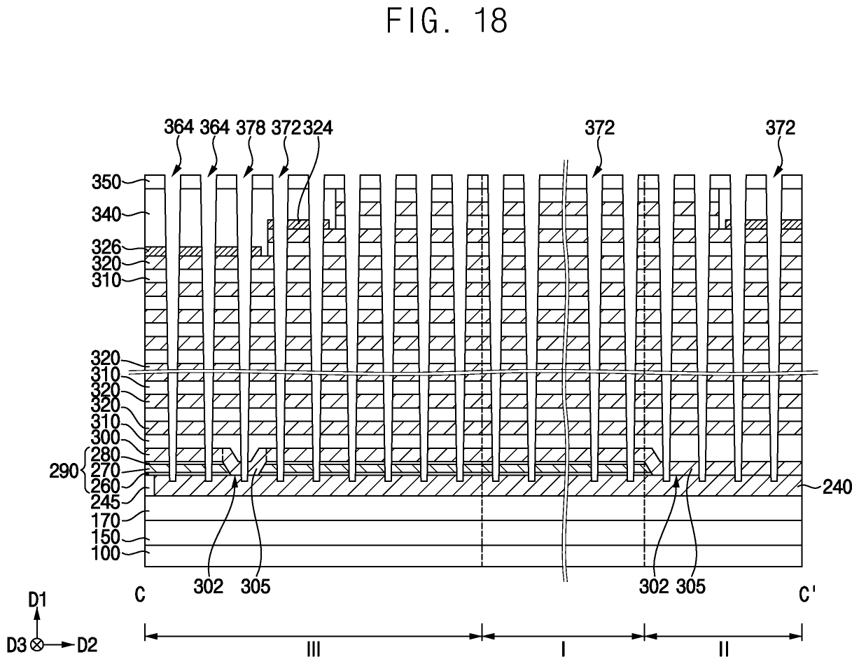

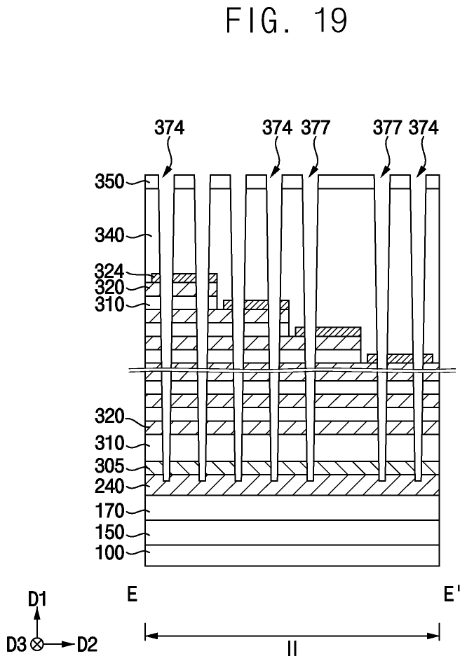

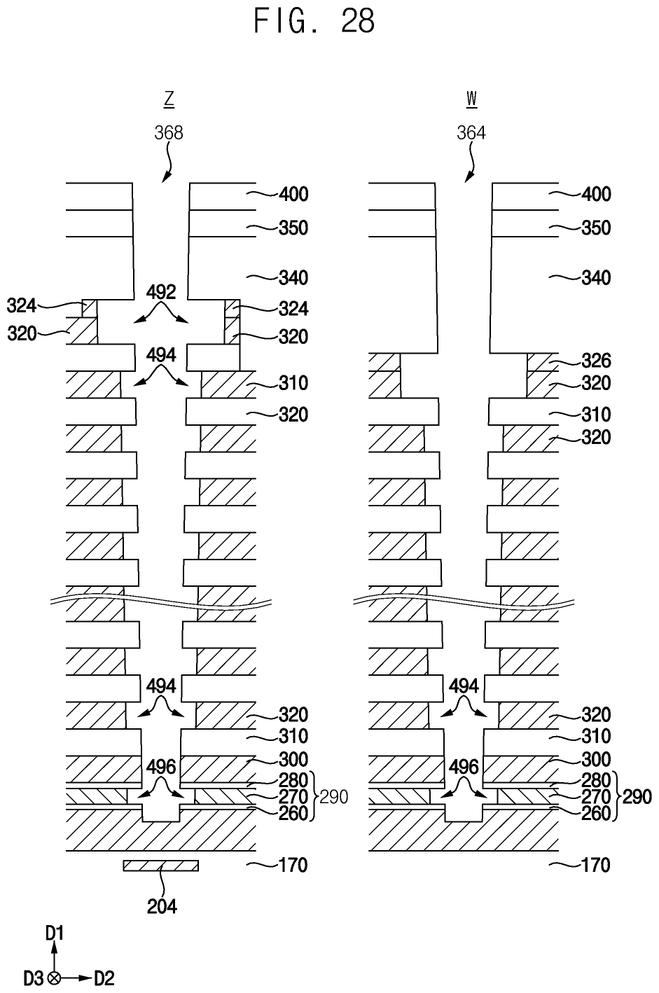

FIGS. 10, 11, 13, 14, 16, 21, 26, 30, 34, 38, 42, 48, 53, 58, and 61 are cross-sectional views taken along lines A-A′ of corresponding plan views, respectively. FIGS. 17, 22, 43, 46, 47, 49, and 54 are cross-sectional views taken along lines B-B′ of corresponding plan views, respectively. FIGS. 18, 23, 27, 31, 35, 39, 44, 50, and 55 are cross-sectional views taken along lines C-C′ of corresponding plan views, respectively. FIGS. 19, 24, 36, 40, 45, 51, and 56 are cross-sectional views taken along lines E-E′ of corresponding plan views, respectively. Each of FIGS. 28, 32, 59, and 62 includes enlarged cross-sectional views of regions Y and Z of a corresponding cross-sectional view.

Referring to FIGS. 9 and 10, a lower circuit pattern may be formed on a substrate 100, and first and second insulating interlayers 150 and 170 may be sequentially stacked on the substrate 100 to cover at least a portion of the lower circuit pattern.

Referring to FIGS. 9 and 10 together with FIG. 4, for example, a first transistor including a first lower gate structure 142 and first impurity regions 102 may be formed on a first region I of the substrate 100, a second transistor including a second lower gate structure 144 and second impurity regions 104 may be formed on a second region II of the substrate 100, and a third transistor including a third lower gate structure 148 and third impurity regions 108 may be formed on a third region III of the substrate 100.

The first insulating interlayer 150 may be formed on the substrate 100 to cover at least a portion of the first to third transistors. Alternatively or additionally, first to third lower contact plugs 162 to 168 may be formed through the first insulating interlayer 150 to contact the first to third impurity regions 102 to 108, respectively.

First to sixth lower wirings 182 to 208 and first to third lower vias 192 to 198 may be formed on the first insulating interlayer 150. Alternatively or additionally, the second insulating interlayer 170 may be formed on the first insulating interlayer 150 to cover at least a portion of the first insulating interlayer 150, the first to sixth lower wirings 182 to 208, and the first to third lower vias 192 to 198.

Each element of the lower circuit pattern may be formed by a patterning process and/or a damascene process.

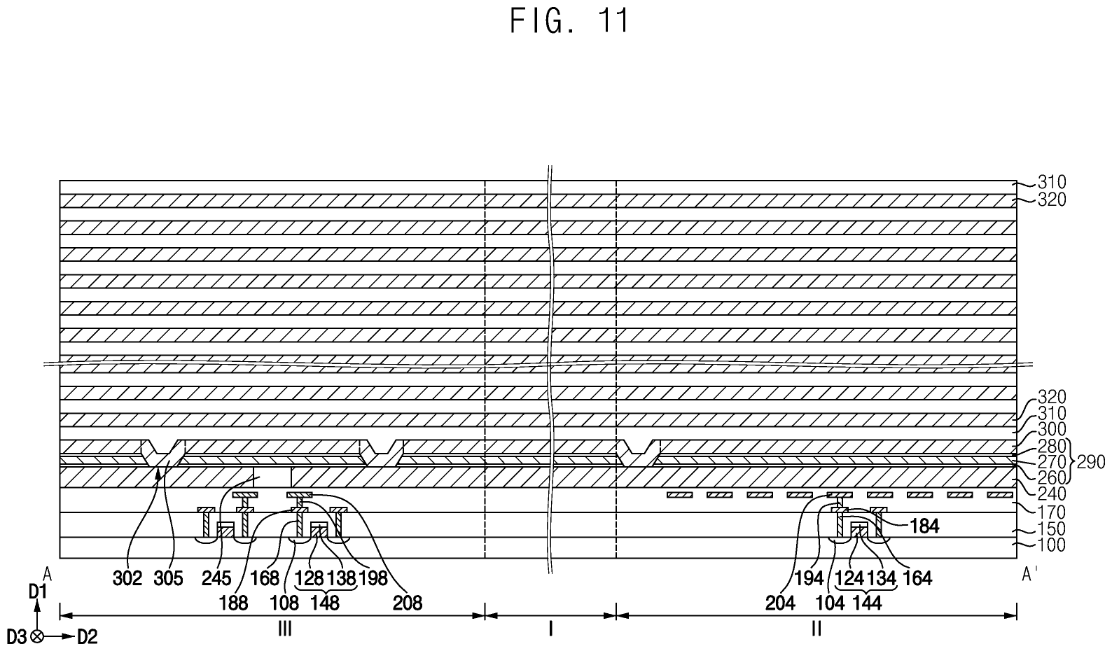

Referring to FIG. 11, a common source plate (CSP) 240 and a CSP division layer 245 may be formed on the second insulating interlayer 170, and a sacrificial layer structure 290 may be formed on the CSP 240 and the CSP division layer 245.

In example embodiments, the CSP division layer 245 may extend in the third direction D3 on a central portion in the second direction D2 of the third region III of the substrate 100.

The sacrificial layer structure 290 may be partially removed to form a first opening 302 exposing an upper surface of the CSP 240. Alternatively or additionally, a support layer 300 may be formed on an upper surface of the sacrificial layer structure 290 and the exposed upper surface of the CSP 240.

The sacrificial layer structure 290 may include first to third sacrificial layers 260 to 280 sequentially stacked. Each of the first and third sacrificial layers 260 and 280 may include, but not limited to, an oxide (e.g., silicon oxide), and the second sacrificial layer 270 may include, but not limited to, a nitride (e.g., silicon nitride).

The first opening 302 may be formed in various layouts in a plan view. For example, a plurality of first openings 302 may be spaced apart from each other in the second and third directions D2 and D3 on the first region I of the substrate 100. Alternatively or additionally, the first opening 302 may extend in the third direction D3 on a portion of the second region II adjacent to the first region I of the substrate 100, and a plurality of first openings 302, each of which may extend in the second direction D2, and may be spaced apart from each other in the third direction D3 on the second region II of the substrate 100. In an embodiment, a plurality of first openings 302, each of which may extend in the third direction D3, may be spaced apart from each other in the second direction D2 on the third region III of the substrate 100.

The support layer 300 may include a material having an etching selectivity with respect to the first to third sacrificial layers 260 to 280, such as, but not limited to, polysilicon doped with n-type impurities. The support layer 300 may be conformally formed, and thus a first recess may be formed on a portion of the support layer 300 in the first opening 302. Hereinafter, the portion of the support layer 300 in the first opening 302 that may contact the upper surface of the CSP 240 may be referred to as a support pattern 305.

A first insulation layer 310 and a fourth sacrificial layer 320 may be alternately and repeatedly stacked in a first direction D1 on the support layer 300 and the support pattern 305, and thus a mold layer including the first insulation layers 310 and the fourth sacrificial layers 320 may be formed. The first insulation layer 310 may include, but not be limited to, an oxide (e.g., silicon oxide), and the fourth sacrificial layer 320 may include a material having an etching selectivity with respect to the first insulation layer 310, such as, but not limited to, a nitride (e.g., silicon nitride).

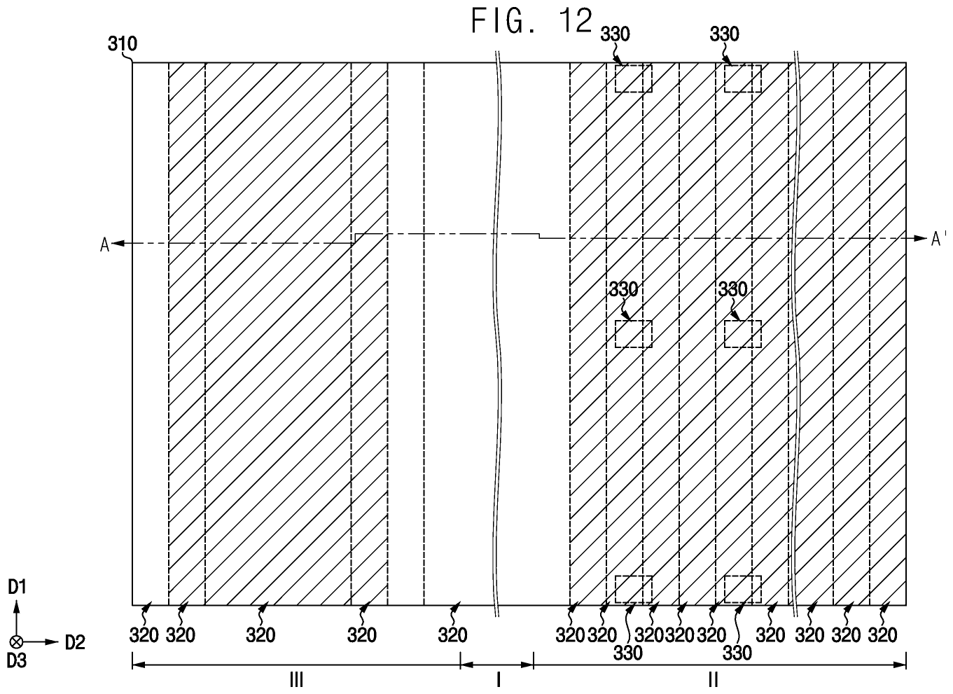

Referring to FIG. 11 together with FIG. 12, a first division pattern 330 may be further formed to extend through a portion of a lowermost one of the fourth sacrificial layers 320. In example embodiments, a plurality of first division patterns 330 may be spaced apart from each other in the second and third directions D2 and D3 on the second region II of the substrate 100.

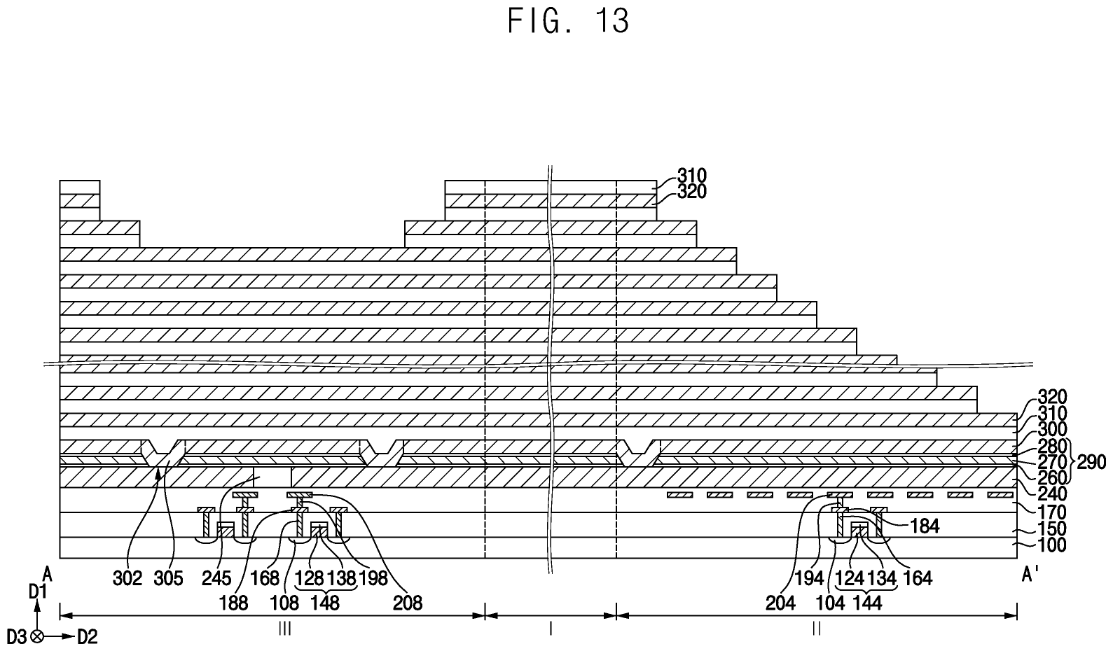

Referring to FIGS. 12 and 13, a first photoresist pattern partially covering an uppermost one of the first insulation layers 310 may be formed, and the uppermost one of the first insulation layers 310 and an uppermost one of the fourth sacrificial layers 320 may be etched using the photoresist pattern as an etching mask. As a result, a portion of one of the first insulation layers 310 directly under the uppermost one of the fourth sacrificial layers 320 may be exposed.

Referring to FIGS. 12 and 13 together with FIG. 1, the first photoresist pattern may cover the first region I at opposite sides of the third region III of the substrate 100 in the second direction D2 and edge portions of each of the second and third regions I and II neighboring the first region I in the second direction D2.

In an embodiment, after performing a trimming process for reducing an area of the first photoresist pattern, the uppermost one of the first insulation layers 310, the uppermost one of the fourth sacrificial layers 320, the exposed one of the first insulation layers 310, and one of the fourth sacrificial layer 320 directly under the exposed one of the first insulation layers 310 may be etched by an etching process using the reduced first photoresist pattern as an etching mask.

Thus, a plurality of steps each of which may include one first insulation layer 310 and one fourth sacrificial layer 320 sequentially stacked may be formed on each of the second and third regions II and III of the substrate 100. In example embodiments, the plurality of steps may be disposed in the second direction D2.

FIG. 13 shows that the steps are formed at an uppermost level and a second level from above, however the present disclosure may not be limited thereto. For example, the step may be formed only at the uppermost level. As another example, the steps may be formed from the uppermost level to the third level and/or to lower levels. Hereinafter, only a case where the steps are formed at the uppermost level and the second level is described for convenience of description.

In an embodiment, the first photoresist pattern may be removed, a second photoresist pattern may be formed on and partially cover one of the first insulation layers 310 at a third level from above. Referring to FIG. 13 together with FIG. 1, the second photoresist pattern may cover at least a portion of the third region III of the substrate 100, the first regions I at the opposite sides of the third region III of the substrate 100 in the second direction D2, and a portion of the second region II neighboring each of the first region I in the second direction D2.

An etching process using the second photoresist pattern as an etch mask and a trimming process for the second photomask pattern may be repeatedly performed to form steps, each of which may include the first insulation layer 310 and the fourth sacrificial layer 320 sequentially stacked, on the second region II of the substrate 100. In an example embodiment, the steps may be disposed in the second direction D2. In another example embodiment, the steps may also be disposed in the third direction D3.

Hereinafter, a structure including the first insulation layers 310 and the fourth sacrificial layers 320 alternately and repeatedly stacked in the first direction D1 on the sacrificial layer structure 290 may be referred to as a mold. The mold may have a staircase shape as a whole on the second region II of the substrate 100, and may have a staircase shape at several upper levels on the third region III of the substrate 100.

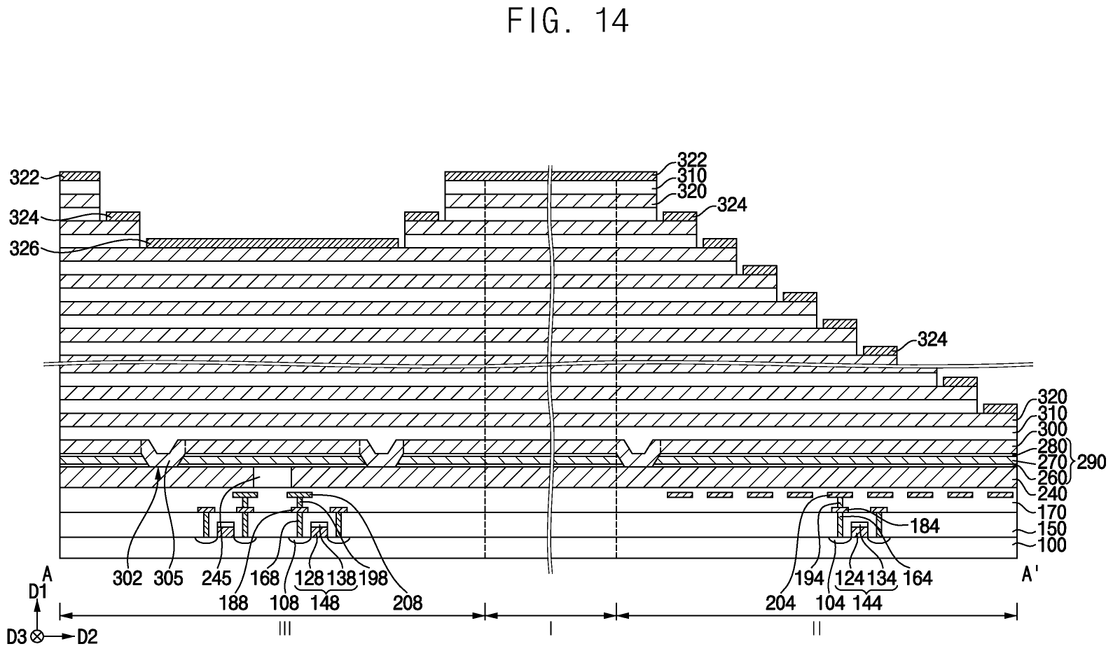

Referring to FIG. 14, an insulation pad layer may be formed on the mold, and may be partially removed to form first to third insulation pads 322 to 326.

In an example embodiment, the insulation pad layer may include the same material as the fourth sacrificial layer 320. However, the insulation pad layer may have an etching rate different from an etching rate of the fourth sacrificial layer 320.

Portions of the insulation pad layer adjacent to sidewalls of the steps, respectively, of the mold may be removed to form the first insulation pad 322 on an upper surface of the uppermost one of first insulation layers 310 and to form the second insulation pad 324 on an upper surface of each of the fourth sacrificial layers 320 that may form the steps of the mold. The third insulation pad 326 may be formed on a portion of the fourth sacrificial layer 320 on a central portion in the second direction D2 of the third region III of the substrate 100. In example embodiments, each of the first to third insulation pads 322 to 326 may extend in the third direction D3.

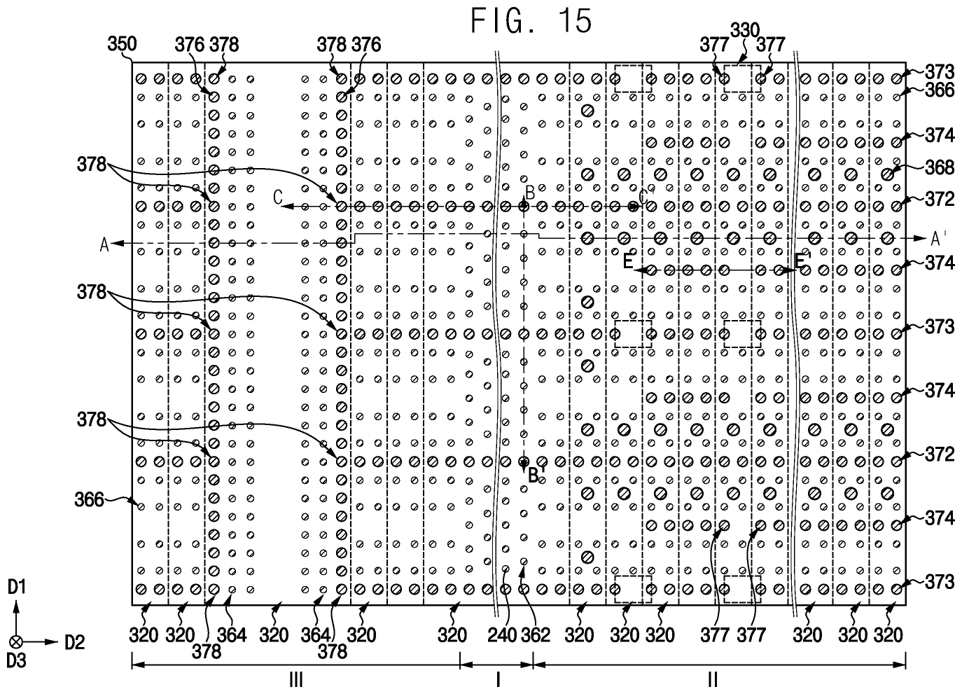

Referring to FIGS. 15 to 19, a third insulating interlayer 340 may be formed on the CSP 240 to cover the mold and the first to third insulation pads 322 to 326, and may be planarized until an upper surface of the uppermost one of the first insulation layers 310 is at least partially exposed.

During the planarization, the first insulation pad 322 may be removed, and a sidewall of the mold may be covered by the third insulating interlayer 340.

A fourth insulating interlayer 350 may be formed on upper surfaces of the mold and the third insulating interlayer 340. For example, a dry etching process may be performed to form holes (e.g., first hole 362, second hole 364, third hole 366, fourth hole 368, fifth hole 372, sixth hole 373, seventh hole 374, eighth hole 376, ninth hole 377, and tenth hole 378).

The first hole 362 may extend in the first direction D1 through the fourth insulating interlayer 350, the mold, the support layer 300 and the sacrificial layer structure 290 to expose the upper surface of the CSP 240 on the first region I of the substrate 100. The second hole 364 may extend in the first direction D1 through the third and fourth insulating interlayers 340 and 350, the third insulation pad 326, the mold, the support layer 300 and the sacrificial layer structure 290 to expose the upper surface of the CSP 240 on the third region III of the substrate 100. The third hole 366 may extend in the first direction D1 through the third and fourth insulating interlayers 340 and 350, the second insulation pad 324, a portion of the mold, the support layer 300 and the sacrificial layer structure 290 to expose the upper surface of the CSP 240 on the second region II of the substrate 100.

In example embodiments, a plurality of first holes 362 may be spaced apart from each other in the second and third directions D2 and D3 on the first region I of the substrate 100, a plurality of second holes 364 may be spaced apart from each other in the second and third directions D2 and D3 on the third region III of the substrate 100, and a plurality of third holes 366 may be spaced apart from each other in the second and third directions D2 and D3 on the second region II of the substrate 100.

In FIG. 15, the second holes 364 are formed in two columns in the second direction D2 on each of opposite edge portions of the third region III of the substrate 100 in the second direction D2, however the present disclosure may not be limited thereto.

The fourth hole 368 may extend in the first direction D1 through the third and fourth insulating interlayers 340 and 350, the second insulation pad 324, the mold, the support layer 300 and the sacrificial layer structure 290 to expose the upper surface of the CSP 240 on the second region II of the substrate 100. In example embodiments, each of the fourth holes 368 may be formed in an area surrounded by the third holes 366 in a plan view. For example, the third holes 366 may be disposed at respective vertices of a rectangle, and each of the fourth holes 368 may be formed in an inside the rectangle in a plan view.

Each of the fifth to tenth holes 372 to 378 may extend in the first direction D1 on the first to third regions I, II and III of the substrate 100, and may extend through the third and fourth insulating interlayers 340 and 350, the second and third insulation pads 324 and 326, the mold, the support layer 300 and the sacrificial layer structure 290, and/or through the third and fourth insulating interlayers 340 and 350, the second and third insulation pads 324 and 326, the mold and the support pattern 305 to expose the upper surface of the CSP 240.

In example embodiments, the fifth holes 372 may be formed to be spaced apart from each other by a first distance in the second direction D2 on the first and second regions I and II of the substrate 100 and a portion of the third region III of the substrate 100 neighboring the first region I of the substrate 100 in the second direction D2, and may be disposed to opposite end portions in the second direction D2 of the mold having a stair case shape. Alternatively or additionally, a plurality of fifth holes 372 may be spaced apart from each other in the third direction D3.

In an example embodiment, the fifth holes 372 on the first and third regions I and III of the substrate 100 may extend through the support layer 300 and the sacrificial layer structure 290 to expose the upper surface of the CSP 240, and the fifth holes 372 on the second region II of the substrate 100 may extend through the support pattern 305 to expose the upper surface of the CSP 240.

In example embodiments, the sixth holes 373 may be spaced apart from each other in the second direction D2 between ones of the fifth holes 372 neighboring in the third direction D3. The sixth holes 373 may be spaced apart from each other by the first distance in the second direction D2 on the first and third regions I and III of the substrate 100, while a plurality of sixth hole groups, each of which may include a plurality of sixth holes 373 spaced apart from each other by the first distance, may be spaced apart from each other by a second distance greater than the first distance in the second direction D2 on the second region II of the substrate 100.

In an example embodiment, the sixth holes 373 on the first and third regions I and III of the substrate 100 may extend through the support layer 300 and the sacrificial layer structure 290 to expose the upper surface of the CSP 240, and the sixth holes 373 on the second region II of the substrate 100 may extend through the support pattern 305 to expose the upper surface of the CSP 240.

In example embodiments, the seventh holes 374 may be spaced apart from each other in the second direction D2 between ones of the fifth and sixth holes 372 and 373 neighboring in the third direction D3. In some embodiments, the seventh holes 374 may not be formed on the first and third regions I and III of the substrate 100, but may be formed only on the second region II of the substrate 100. In example embodiments, a plurality of seventh hole groups, each of which may include a plurality of seventh holes 374 spaced apart from each other by the first distance, may be spaced apart from each other by a third distance greater than the first distance in the second direction D2. The third distance may be substantially the same as and/or different from the second distance. In an example embodiment, the seventh holes 374 may extend through the support pattern 305 to expose the upper surface of the CSP 240. Alternatively or additionally, the seventh holes 374 may extend through the sacrificial layer structure 290 and the support layer 300 to expose the upper surface of the CSP 240.

Ones of the sixth holes 373 that may be included in the sixth hole groups, respectively, neighboring in the second direction D2 and face each other in the second direction D2, and ones of the seventh holes 374 that may be included in the seventh hole groups, respectively, neighboring in the second direction D2 and face each other in the second direction D2 and may be referred to as ninth holes 377. In example embodiments, each of the ninth holes 377 adjacent to the sixth hole 373 in the second direction D2 may extend through at least a portion of the first division pattern 330.

In example embodiments, the eighth holes 376 may be spaced apart from each other in the third direction D3 on each of opposite edge portions of the third region III of the substrate 100 in the second direction D2. The eighth holes 376 may be spaced apart from the second holes 364 in the second direction D2. In an example embodiment, the eighth holes 376 may extend through the support pattern 305 to expose the upper surface of the CSP 240.

Hereinafter, ones of the eighth hole 376 adjacent to the fifth hole 372 or the sixth hole 373 in the second direction D2 may be referred to as a tenth hole 378.

The first to tenth holes 362 to 378 may be simultaneously (e.g., at substantially the same time) formed through a single etching process and/or may be sequentially formed through separate processes. Due to characteristics of the etching process, each of the first to tenth holes 362 to 378 may have a width that gradually decreases from a top toward a bottom thereof.

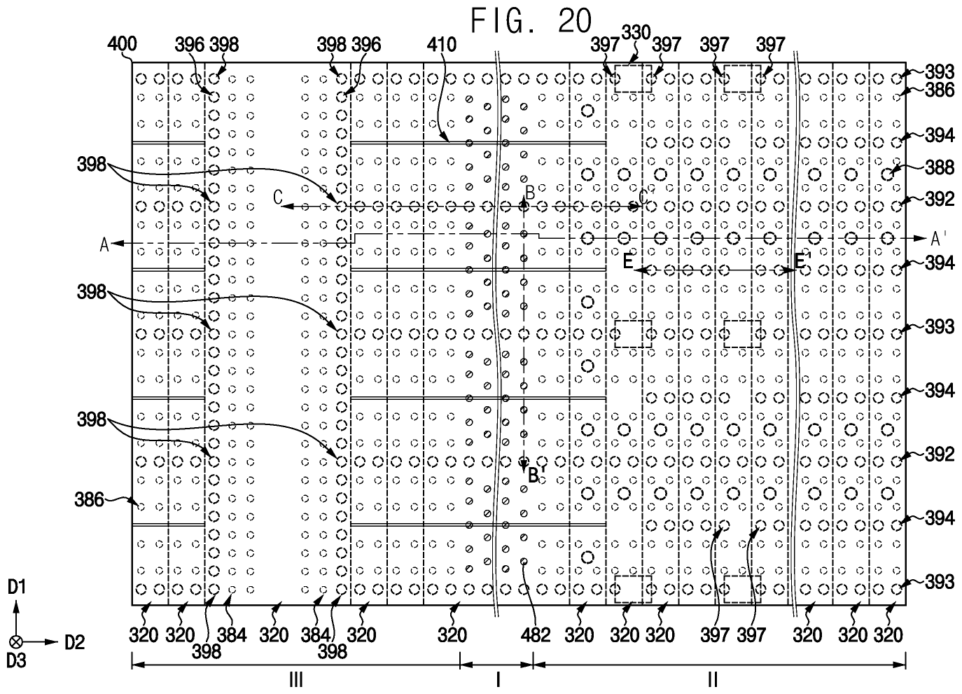

Referring to FIGS. 20 to 24, a fifth sacrificial pattern may be formed in the first hole 362, and sacrificial patterns (e.g., sixth sacrificial pattern 384, seventh sacrificial pattern 386, eighth sacrificial pattern 388, ninth sacrificial pattern 392, tenth sacrificial pattern 393, eleventh sacrificial pattern 394, twelfth sacrificial pattern 396, thirteenth sacrificial pattern 397, and fourteenth sacrificial pattern 398) may be formed in the second to tenth holes 364 to 378, respectively.

The fifth sacrificial pattern and the sixth to fourteenth sacrificial patterns 384 and 386 to 398 may be formed by forming a fifth sacrificial layer on the CSP 240 and the fourth insulating interlayer 350 to fill the first to tenth holes 362 to 378, and planarizing the fifth sacrificial layer until an upper surface of the fourth insulating interlayer 350 is exposed.

In example embodiments, each of the thirteenth sacrificial patterns 397 adjacent to the tenth sacrificial pattern 393 in the second direction D2 may extend through at least a portion of the first division pattern 330, and contact the first division pattern 330.

In an example embodiment, the fifth sacrificial layer may include a first layer including an insulating material (e.g., carbon), and a second layer on the first layer including, but not limited to, polysilicon.

According to shapes of the first to tenth holes 362 to 378, each of the fifth sacrificial pattern and the sixth to fourteenth sacrificial patterns 384 and 386 to 398 may also have a width that gradually decreases from a top toward a bottom thereof.

A fifth insulating interlayer 400 may be formed on the fourth insulating interlayer 350, the fifth sacrificial pattern and the sixth to fourteenth sacrificial patterns 384 to 398, and may be partially removed to expose an upper surface of the fifth sacrificial pattern. The exposed fifth sacrificial pattern may be removed by, for example, a dry etching process and/or a wet etching process, to form the first hole 362 exposing the upper surface of the CSP 240.

Referring to FIGS. 20 to 24 together with FIG. 7, a memory channel structure 482 may be formed in the first hole 362. The memory channel structure 482 may include a charge storage structure 442 on a sidewall and a bottom of the first hole 362, a channel 452 on the charge storage structure 442, a filling pattern 462 on the channel 452, and a capping pattern 472 on the channel 452 and the filling pattern 462 and contacting an upper inner sidewall of the charge storage structure 442. The charge storage structure 442 may include a first blocking pattern 412, a charge storage pattern 422 and a tunnel insulation pattern 432 sequentially stacked from the sidewall and the bottom of the first hole 362.

In example embodiments, the memory channel structure 482 may have a pillar shape extending in the first direction D1. A plurality of memory channel structures 482 may be spaced apart from each other in the second and third directions D2 and D3 on the first region I of the substrate 100.

The fourth and fifth insulating interlayers 350 and 400, and ones of the first insulation layers 310 and the fourth sacrificial layers 320 may be etched to form a second opening extending through the fourth and fifth insulating interlayers 350 and 400, and the ones of the first insulation layers 310 and the fourth sacrificial layers 320 in the second direction D2, and a second division pattern 410 may be formed to fill the second opening.

In example embodiments, the second division pattern 410 may extend through an upper portion of the memory channel structure 482. Alternatively or additionally, the second division pattern 410 may extend through not only the upper portion the memory channel structure 482, but also the fourth and fifth insulating interlayers 350 and 400, ones of the fourth sacrificial layers 320 at upper two levels, and ones of the first insulation layers 310 at upper two levels, and may also partially extend through one of the first insulation layers 310 directly under the ones of the first insulation layers 310 at the upper two levels. The second division pattern 410 may extend in the second direction D2 on the first region I of the substrate 100 and edge portions of the second and third regions II and III of the substrate 100 adjacent to the first region I in the second direction D2, and may extend through upper two step layers included in the mold. Accordingly, each of the ones of the fourth sacrificial layers 320 at the upper two levels may be divided in the third direction D3 by the second division pattern 410.

In an example embodiment, the second division pattern 410 may be aligned with the eleventh sacrificial patterns 394 in the seventh holes 374 along the second direction D2.

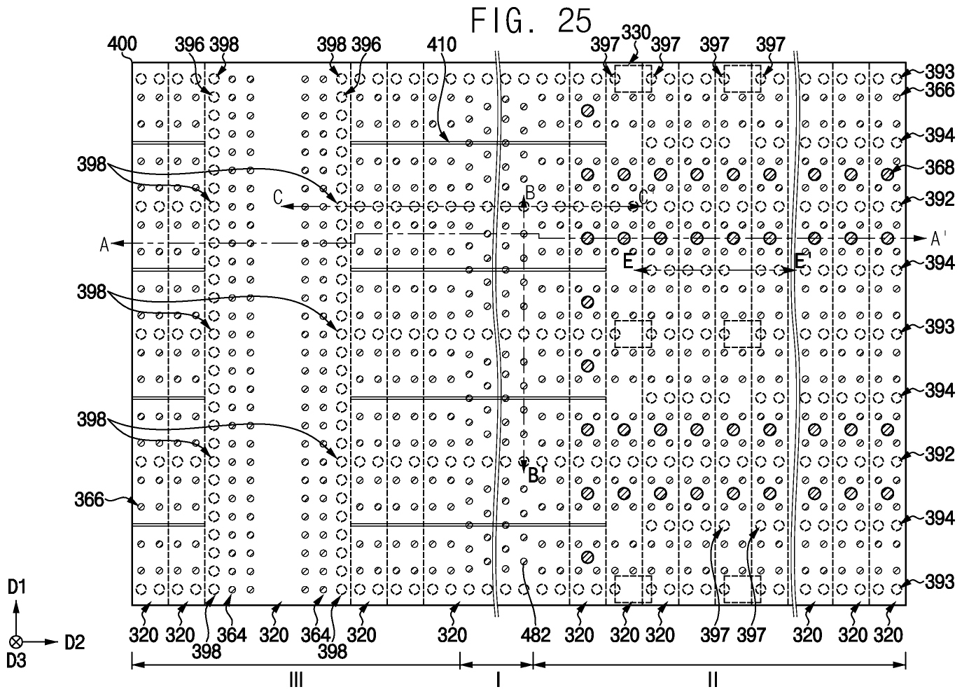

Referring to FIGS. 25 to 28, the fifth insulating interlayer 400 may be partially removed to expose the sixth to eighth sacrificial patterns 384 to 388. For example, a dry etching process and/or a wet etching process may be performed to remove the sixth to eighth sacrificial patterns 384 to 388 to form the second to fourth holes 364 to 368 exposing the upper surface of the CSP 240.

An additional etching process may be performed to remove portions of the fourth sacrificial layer 320 adjacent to the second to fourth holes 364 to 368 to form second and third recesses 492 and 494, and a portion of the second sacrificial layer 270 adjacent to each of the second to fourth holes 364 to 368 may also be removed to form a fourth recess 496.

In example embodiments, during the formation of the second recess 492, not only the fourth sacrificial layer 320 but also the second and third insulation pads 324 and 326 that may be formed on the fourth sacrificial layer 320 and include substantially the same material as the fourth sacrificial layer 320 may also be removed, and thus a width of the second recess 492 in the horizontal direction may be greater than a width of each of the third and fourth recesses 494 and 496 in the horizontal direction.

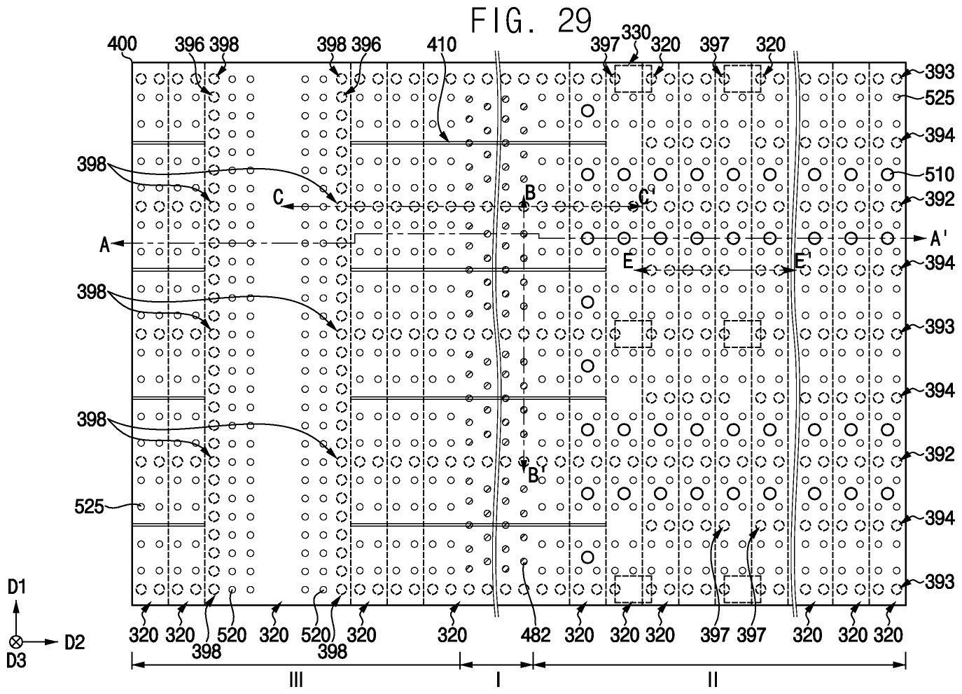

Referring to FIGS. 29 to 32, a second insulation layer may be formed on inner walls of the second to fourth holes 364 to 368 and the second to fourth recesses 492 to 496, and an upper surface of the fifth insulating interlayer 400 to fill the third and fourth recesses 494 and 496, a sacrificial liner layer may be formed on the second insulation layer, a sixth sacrificial layer may be formed on the sacrificial liner layer to fill remaining portions of the second to fourth holes 364 to 368, and the sixth sacrificial layer, the sacrificial liner layer and the second insulation layer may be planarized until the upper surface of the fifth insulating interlayer 400 is exposed.

In example embodiments, the second insulation layer may include, but not be limited to, an oxide (e.g., silicon oxide), the sacrificial liner layer may include, but not be limited to, an insulating nitride (e.g., silicon nitride), and the sixth sacrificial layer may include, but not be limited to, a polysilicon.

As the planarization process is performed, a sacrificial pillar 510 including a second insulation pattern 502, a sacrificial liner 504 and a fifteenth sacrificial pattern 506 may be formed in each of the second to fourth holes 364 to 368 and the second to fourth recesses 492 to 496 connected to a corresponding one of the second to fourth holes 364 to 368.

For example, a wet etching process may be performed to remove the sacrificial pillars 510 in the second and third holes 364 and 366, and a third insulation pattern may be formed to fill the second and third holes 364 and 366. During the wet etching process, portions of the second insulation pattern 502 in the third and fourth recesses 494 and 496 may remain. In example embodiments, the third insulation pattern may include a material substantially the same as that of the second insulation pattern 502, that is, an oxide such as, but not limited to, silicon oxide. Consequently, the third insulation pattern may be merged with the portions of the second insulation pattern 502 remaining in the third and fourth recesses 494 and 496.

Hereinafter, the third insulation pattern and the second insulation pattern 502 in the second hole 364 and the third and fourth recesses 494 and 496 may be collectively referred to as a first support structure 520, and the third insulation pattern and the second insulation pattern 502 in the third hole 366 may be collectively referred to as a second support structure 525.

Alternatively or additionally, the third insulation pattern may include a material different from that of the second insulation pattern 502, e.g., a conductive material, and thus may be referred as a conductive pattern. In such an embodiment, the conductive pattern may not be merged with the portions of the second insulation pattern 502 remaining in the third and fourth recesses 494 and 496. Each of the first and second support structures 520 and 525 may include the conductive pattern having a pillar shape extending in the first direction D1 and including a conductive material and the second insulation patterns 502 on a sidewall of the conductive pattern spaced apart from each other in the first direction D1 and protruding in the horizontal direction. In each of the first and second support structures 520 and 525, the conductive pattern may also be referred to as a vertical extension portion, and the second insulation pattern 502 may be referred to as a protrusion portion 502.

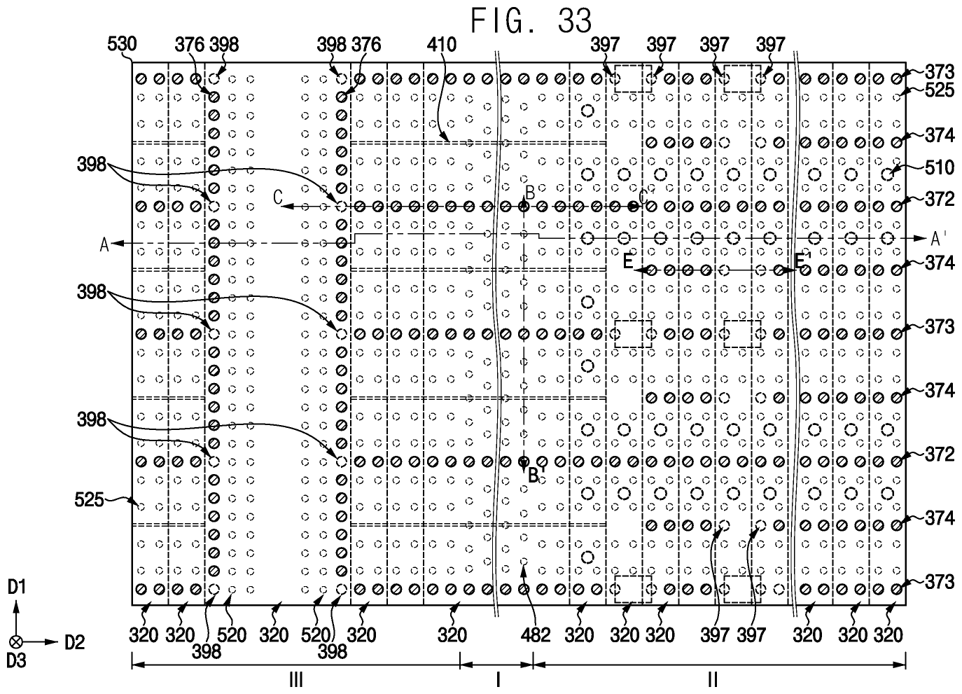

Referring to FIGS. 33 to 36, a sixth insulating interlayer 530 may be formed on the fifth insulating interlayer 400, the memory channel structure 482, the second division pattern 410, a sacrificial pillar 510 and the first and second support structures 520 and 525, the fifth and sixth insulating interlayers 400 and 530 may be partially removed to expose the ninth to twelfth sacrificial patterns 392 to 396, and the ninth to twelfth sacrificial patterns 392 to 396 may be removed by a dry etching process and/or a wet etching process to form the fifth to eighth holes 372 to 376 exposing the upper surface of the CSP 240.

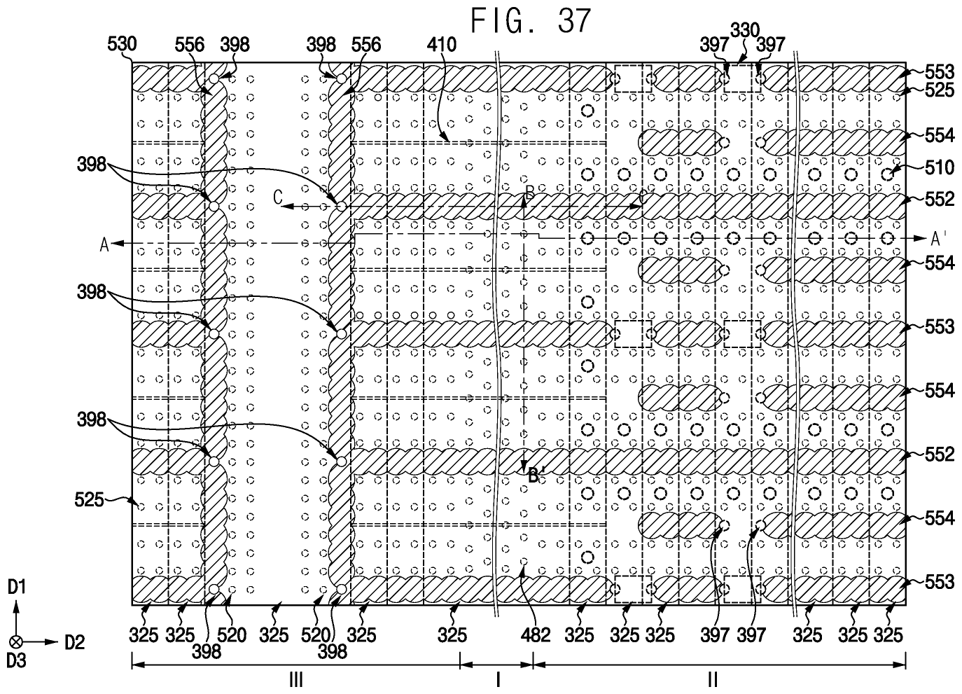

Referring to FIGS. 37 to 40, for example, a wet etching process may be performed to increase widths of the fifth to eighth holes 372 to 376 in the horizontal direction.

Thus, the fifth holes 372 adjacent to each other in the direction D2 may be connected to each other to form a third opening 552, the sixth holes 373 adjacent to each other in the second direction D2 may be connected to each other to form a fourth opening 553, seventh holes 374 adjacent to each other in the second direction D2 may be connected to each other to form a fifth opening 554, and the eighth holes 376 adjacent to each other in the third direction D3 may be connected to each other to form a sixth opening 556.

In example embodiments, the third opening 552 may extend to each of opposite end portions in the second direction D2 of a portion of the mold at each of opposite sides in the second direction D2 on the first and second region I and II and a portion of the third region III of the substrate 100 neighboring the first region I in the second direction D2, and a plurality of third openings 552 may be formed to be spaced apart from each other in the third direction D3. Thus, the portion of the mold at each of opposite sides in the second direction D2 may be divided in the third direction D3 by the third openings 552. As the third opening 552 is formed, the first insulation layers 310 and the fourth sacrificial layers 320 included in each of the portion of the mold may be divided into first insulation patterns 315 and fourth sacrificial patterns 325, respectively, each of which may extend in the second direction D2.

In example embodiments, the fourth opening 553 may extend continuously in the second direction D2 on the first region I of the substrate 100 and portions of the second and third regions II and III adjacent to the first region I in the second direction D2. However, a plurality of fourth openings, each of which may be formed from ones of the sixth holes 373 in each of the sixth hole groups, may be spaced apart from each other in the second direction D2 on the remaining portion of the second region II of the substrate 100. The fourth openings 553 arranged in the second direction D2 may be formed between ones of the third openings 552 adjacent to each other in the third direction D3.

Unlike the third opening 552 extending to an end portion in the second direction D2 of each of the portion of the mold, the fourth openings 553 may be spaced apart from each other in the second direction D2 on the second region II of the substrate 100, and thus the portion of the mold may not be completely divided by the fourth opening 553.

In example embodiments, the fifth opening 554 may be formed on the second region II of the substrate 100, and similarly to the fourth opening 553, a plurality of fifth openings, which may be formed from ones of the seventh holes 374 in each of the seventh hole groups, may be spaced apart from each other in the second direction D2. The fifth openings 554 arranged in the second direction D2 may be formed between ones of the third and fourth openings 552 and 553 adjacent to each other in the third direction D3.

As each of the fifth to seventh holes 372 to 374 may have a width that gradually decreases from a top toward a bottom thereof, each of the third to fifth openings 552 to 554 that may be formed by enlarging a corresponding one of the fifth to seventh holes 372 to 374 in the horizontal direction may also have a width in the third direction D3 gradually decreasing from a top toward a bottom thereof.

In example embodiments, ones of the thirteenth sacrificial patterns 397 in respective ones of the sixth holes 373 that may be respectively included in the sixth hole groups spaced apart from each other in the second direction D2 and face each other in the second direction D2 (e.g., in the respective ninth holes 377) may not be removed by the wet etching process, and ones of the thirteenth sacrificial patterns 397 in respectively ones of the seventh holes 374 that may be respectively included in the seventh hole groups spaced apart from each other in the second direction D2 and face each other in the second direction D2 (e.g., in the respective ninth holes 377) may also not be removed by the wet etching process.

Thus, each of the fourth and fifth openings 553 and 554 may extend only to a sidewall of the thirteenth sacrificial pattern 397 in the second direction D2.

In example embodiments, the sixth opening 556 may extend in the third direction D3 on the third region III of the substrate 100.

As the eighth hole 376 has a width that may gradually decrease from a top toward a bottom thereof, the sixth opening 556 that may be formed by enlarging the eighth hole in the horizontal direction may also have a width in the second direction D2 gradually decreasing from a top toward a bottom thereof.

In example embodiments, the fourteenth sacrificial patterns 398 adjacent to the ninth to eleventh sacrificial patterns 392 to 394 in the second direction D2 may not be removed during the wet etching process. Thus, the sixth opening 556 may not continuously extend in the third direction D3, and a plurality of sixth openings 556 may be spaced apart from each other in the third direction D3 by the fourteenth sacrificial patterns 398. In such an embodiment, each of the sixth openings 556 may extend only to a sidewall of the fourteenth sacrificial pattern 398 in the third direction D3.

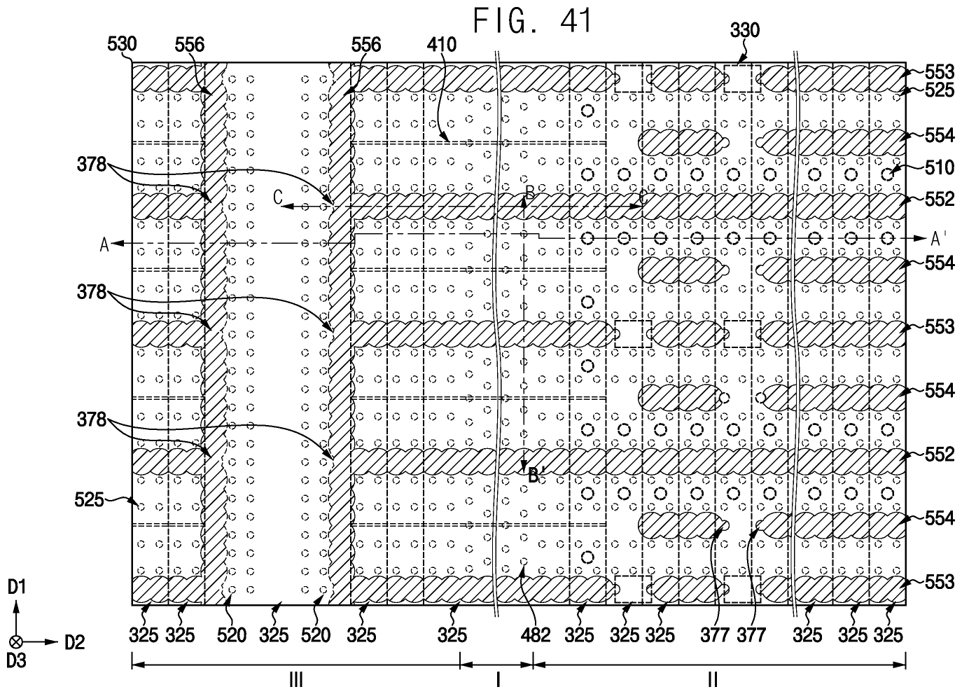

Referring to FIGS. 41 to 45, the fifth and sixth insulating interlayers 400 and 530 may be partially removed to expose the thirteenth and fourteenth sacrificial patterns 397 and 398, the thirteenth and fourteenth sacrificial patterns 397 and 398 may be removed by an etching process and/or a wet etching process, and thus ninth and tenth holes 377 and 378 may be formed again.

The ninth hole 377 may be connected to the fourth opening 553 and/or the fifth opening 554, and the tenth hole 378 may be connected to the third opening 552 and the sixth opening 556 and/or the fourth opening 553 and the sixth opening 556. Accordingly, the third opening 552 and/or the fourth opening 553 extending in the second direction D2 may be connected to the sixth opening 556 extending in the third direction D3 through the tenth hole 378.

In example embodiments, when the ninth to twelfth sacrificial patterns 392 to 396 are removed, the fourteenth sacrificial pattern 398 between the ninth sacrificial pattern 392 and/or the tenth sacrificial pattern 393 and the twelfth sacrificial pattern 396 may not be removed together with the ninth to twelfth sacrificial patterns 392 to 396, and thus when forming the third, fourth, and sixth openings 552 to 556 by performing a wet etching process on the fifth, sixth and eighth holes 372 to 376, which may be formed by removing the ninth, tenth and twelfth sacrificial patterns 392 to 396, respectively, to increase widths in the horizontal direction of the fifth, sixth and eighth holes 372 to 376, the fourteenth sacrificial pattern 398 may define a location where the wet etching process ends.

If the fourteenth sacrificial pattern 398 is removed together with the ninth, tenth, and twelfth sacrificial patterns 392 to 396 to form the tenth hole 378, and a wet etching process is performed on the tenth hole 378 together with the fifth, sixth and eighth holes 372 to 376 to form the third, fourth and sixth openings 552 to 556, a portion of the sixth opening 556 connected to the third opening 552 or the fourth opening 553 may have a width in the horizontal direction greater than widths of other portions of the sixth opening 556 due to the over-etching of the fourteenth sacrificial pattern 398.

However, in example embodiments, the fourteenth sacrificial pattern 398 may be removed by a separate etching process to form the tenth hole 378, after forming the third, fourth and sixth openings 552 to 556, and the wet etching process is not additionally performed on the tenth hole 378 so that the width in the horizontal direction may not increase. Thus, the portion of the sixth opening 556 connected to the third opening 552 or the fourth opening 553 may not have a greater width in the horizontal direction than other portions of the fourth opening 553.

Thus, an area in the horizontal direction of the portion of the sixth opening 556 connected to the third opening 552 or the fourth opening 553 may not be increased. For example, due to the characteristics of an etching process, each of the fifth to eighth holes 372 to 376 may have a width that gradually decreases from a top toward a bottom thereof, and each of the third to sixth openings 552 to 556 may also have widths that gradually decrease from a top toward a bottom thereof, and thus upper portions of each of the fifth to eighth holes 372 to 376 may have a relatively large width in order to achieve a desired depth.

In accordance with example embodiments, even if a vertical depth of each of the fifth to eighth holes 372 to 376 is large, the areas in the horizontal direction of the third to sixth openings 552 to 556, which may be formed by increasing the areas in the horizontal direction of the fifth to eighth holes 372 to 376, may be limited, so that the degree of integration of the semiconductor device may be improved.

The thirteenth sacrificial pattern 397 may not be removed, either, together with the tenth and eleventh sacrificial patterns 393 and 394, and thus when forming the fourth and fifth openings 553 and 554 by performing a wet etching process on the sixth and seventh holes 373 and 374, which may be formed by removing the tenth and eleventh sacrificial patterns 393 and 394, respectively, to increase widths in the horizontal direction of the sixth and seventh holes 373 and 374, the thirteenth sacrificial pattern 397 may define a location where the wet etching process ends.

The thirteenth sacrificial pattern 397 may be removed by a separate etching process to form the ninth hole 377, after forming the fourth and fifth openings 553 and 554, and the wet etching process may not be additionally performed on the ninth hole 377 so that the width in the horizontal direction may not be increased. Thus, an increase of a length of each of the fourth and fifth openings 553 and 554 in the second direction D2 may be limited, and the degree of integration of the semiconductor device including the fourth and fifth openings 553 and 554 may be improved, when compared to related semiconductor devices.

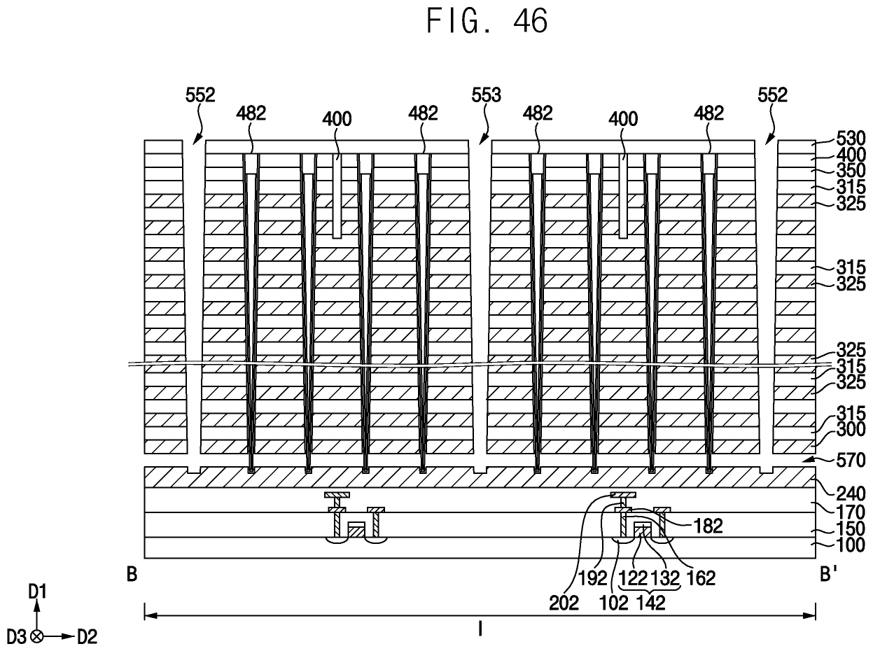

Referring to FIG. 46, the sacrificial film structure 290 may be removed by, for example, a wet etching process through the third to sixth openings 552 to 556, and thus a first gap 570 may be formed between the CSP 240 and the support layer 300 on the first region I of the substrate 100.

The wet etching process may be performed using an etchant, such as, but not limited to, hydrofluoric acid (HF) and/or phosphoric acid (H₃PO₄). In example embodiments, the third to fifth openings 552 to 554 may extend through the support pattern 305, instead of the support layer 300 and the sacrificial layer structure 290, to expose the upper surface of the CSP 240 on the second region II of the substrate 100. Thus, even though the wet etching process is performed, the sacrificial layer structure 290 may not be removed on the second region II of the substrate 100.

The sixth opening 556 may extend through the support pattern 305, instead of the support layer 300 and the sacrificial layer structure 290, to expose the upper surface of the CSP 240 on other portions of the third region III of the substrate 100 except for a portion of the third region III adjacent to the first region I of the substrate 100. Thus, even though the wet etching process is performed, the sacrificial layer structure 290 may not be removed on the other portions of the third region III of the substrate 100.

As the first gap 570 is formed, a portion of a sidewall of the charge storage structure 442 may be exposed, and the exposed sidewall of the charge storage structure 442 may also be removed during the wet etching process to expose an outer sidewall of the channel 452. Thus, the charge storage structure 442 may be divided into an upper portion covering most of the outer sidewall of the channel 452 through the mold and a lower portion covering a bottom surface of the channel 452 on the CSP 240.

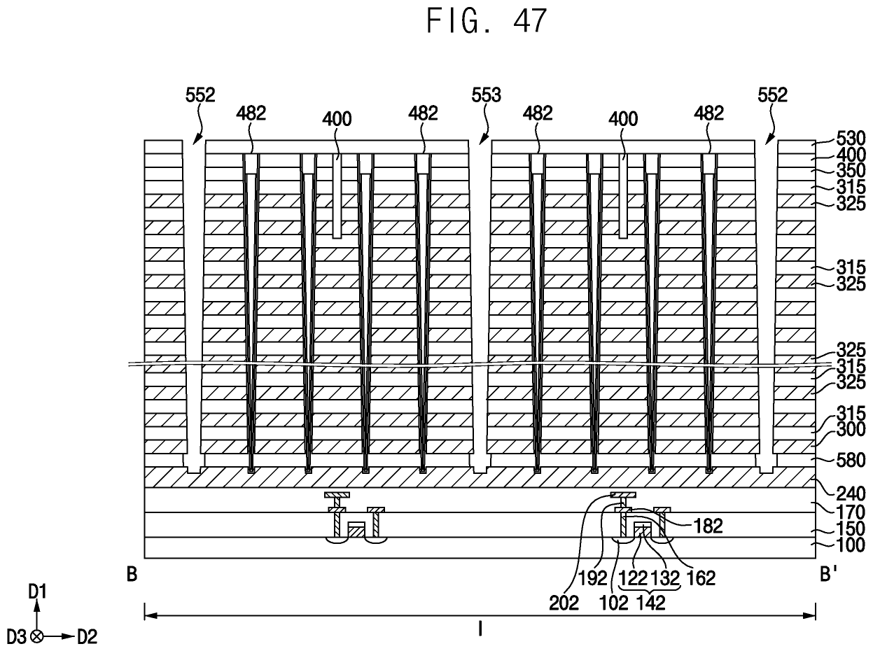

Referring to FIG. 47, a channel connection layer may be formed on sidewalls of the third to sixth openings 552 to 556 and in the first gap 570, and, for example, an etch-back process may be performed to remove a portion of the channel connection layer in the third to sixth openings 552 to 556 to form a channel connection pattern 580 in the first gap 570.

As the channel connection pattern 580 is formed, the channels 452 between the third and fourth openings 552 and 553 adjacent to each other in the third direction D3 may be connected to each other on the first region I of the substrate 100.

In example embodiments, an air gap may be formed in the channel connection pattern 580.

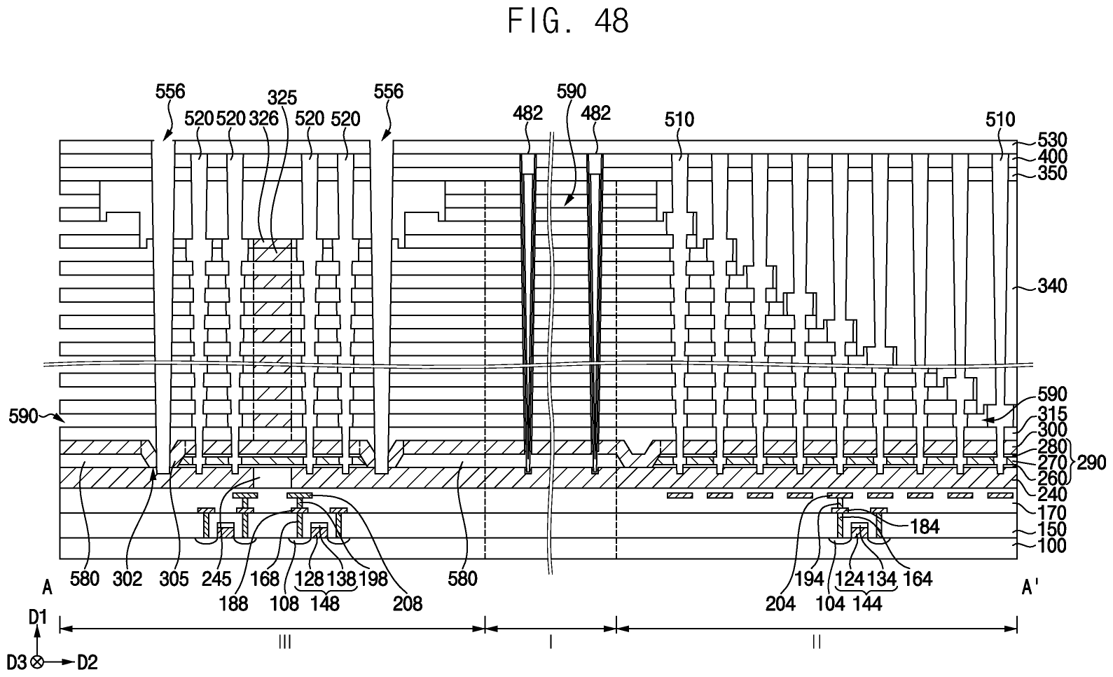

Referring to FIGS. 48 to 51, the fourth sacrificial patterns 325 and the second and third insulation pads 324 and 326 exposed by the third to sixth openings 552 to 556 may be removed to form a second gap 590 between the first insulation patterns 315 at respective levels, and a portion of the outer sidewall of the charge storage structure 442 in the memory channel structure 482, a portion of a sidewall of the sacrificial pillar 510, portions of sidewalls of the first and second support structures 520 and 525, and a portion of a sidewall of the second division pattern 410 may be exposed by the second gap 590.

According to example embodiments, the fourth sacrificial patterns 325 may be removed by a wet etching process using an etchant including, but not limited to, phosphoric acid (H₃PO₄) and/or sulfuric acid (H₂SO₄).

The wet etching process may be performed through the third to sixth openings 552 to 556, and an entire portion of the fourth sacrificial pattern 325 between the third to sixth openings 552 to 556 may be removed by the etchant flowing through the third to sixth openings 552 to 556 in opposite directions, respectively.

However, the etchant flowing from the sixth openings 556 spaced apart from each other in the second direction D2 may not reach portions of the fourth sacrificial pattern 325 and the third insulation pad 326 on a central portion of the third region III of the substrate 100 in the second direction D2, so that the portions of the fourth sacrificial pattern 325 and the third insulation pad 326 on the central portion of the third region III may remain without being removed.

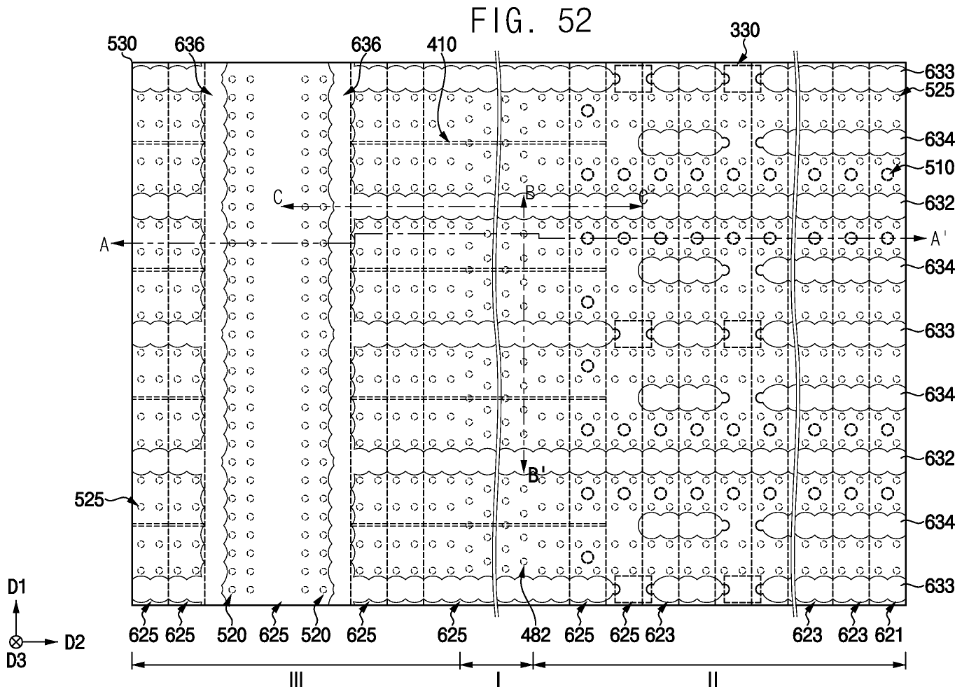

Referring to FIGS. 52 to 55, a second blocking layer may be formed on the portion of the outer sidewall of the charge storage structure 442, the portion of the sidewall of the sacrificial pillar 510, the portions of the sidewalls of the first and second support structures 520 and 525 and the portion of the sidewall of the second division pattern 410 exposed by the second gaps 590, inner walls of the second gaps 590, surfaces of the first insulation patterns 315, sidewalls of the fourth to sixth insulating interlayers 350 to 530, and an upper surface of the sixth insulating interlayer 530, and a gate electrode layer may be formed on the second blocking layer.

The gate electrode layer may partially be removed to form a gate electrode in each of the second gaps 590. In example embodiments, the gate electrode layer may be partially removed by a wet etching process. As a result, in the mold, which may include the first insulation pattern 315 and the fourth sacrificial pattern 325 sequentially stacked as step layers, the fourth sacrificial pattern 325 may be replaced with the gate electrode and the second blocking layer covering upper and lower surfaces of the gate electrode.

In example embodiments, the gate electrode may extend in the second direction D2, and a plurality of gate electrodes may be formed at a plurality of levels, respectively, to be spaced apart from each other in the first direction D1 to form a gate electrode structure. The gate electrode structure may have a staircase shape, in which each of the gate electrodes is a step layer. An end portion in the second direction D2 of each of the gate electrodes that is not overlapped by upper ones of the gate electrode, that is, a portion of the gate electrode structure corresponding to the steps of the step layers and having a relatively large thickness may be referred to as a pad.

In example embodiments, a plurality of gate electrode structures may be spaced apart from each other in the third direction D3 by the third openings 552. As described above, the fourth openings 553 may not continuously extend in the second direction D2 on the second region II of the substrate 100, and a plurality of fourth openings 553 may be spaced apart from each other in the second direction D2, so that the gate electrode structures may not be completely separated from each other in the third direction D3 by the fourth openings 553. However, a lowermost one of the gate electrodes of the gate electrode structure may be separated from each other in the third direction D3 by the fourth openings 553 and the first division pattern 330.

The gate electrode structure may include first to third gate electrodes 621 to 625 sequentially stacked in the first direction D1.

A third division layer may be formed on the second blocking layer to fill the third to sixth openings 552 to 556, and may be planarized until the upper surface of the sixth insulating interlayer 530 is exposed.

Thus, the second blocking layer may be transformed into a second blocking pattern 615, and third to sixth division patterns 632 to 636 may be formed in the third to sixth openings 552 to 556, respectively.

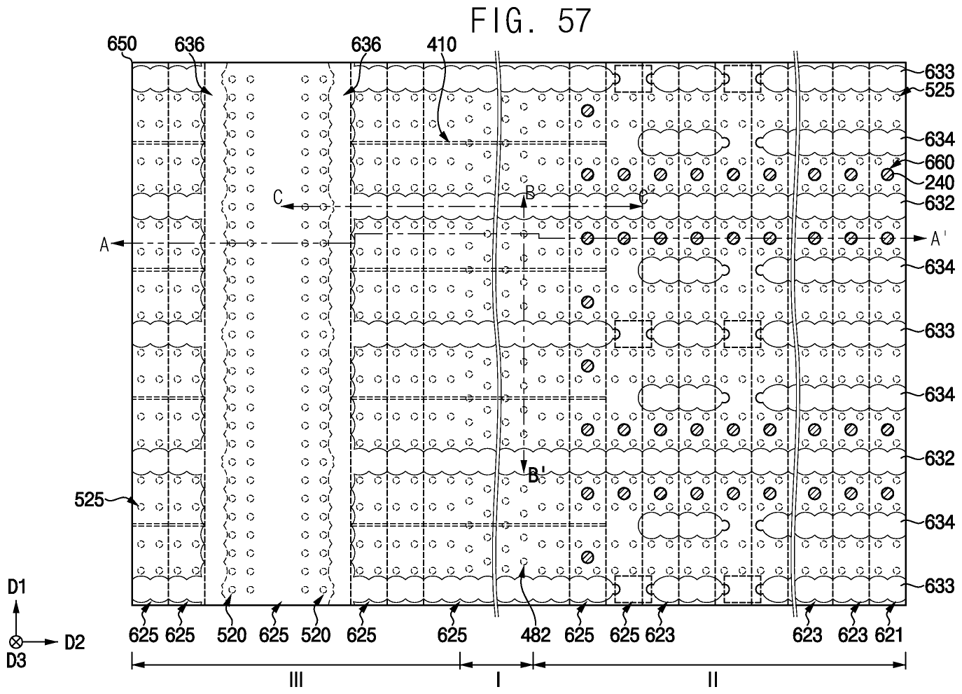

Referring to FIGS. 57 to 59, a seventh insulating interlayer 650 may be formed on the sixth insulating interlayer 530 and the third to sixth division patterns 632 to 636 to expose the sacrificial pillar 510. The exposed sacrificial pillar 510 may be partially removed to form an eleventh hole 660 exposing the upper surface of the CSP 240.

In an embodiment, the fifteenth sacrificial pattern 506 and the sacrificial liner 504 included in the sacrificial pillar 510 may be removed. The second insulation pattern 502 may be partially removed, and an entire portion of the second insulation pattern 502 in the third recess 492 having a relatively large width in the first direction D1 may be removed, while the fourth and fifth insulation patterns 674 and 676 may remain in the fourth and fifth recesses 494 and 496, respectively, having relatively small widths.

A portion of a sidewall of the second blocking pattern 615 exposed by the third recess 492 may be additionally removed, and thus a sidewall of an uppermost one of the gate electrodes in the eleventh hole 660 may be exposed.

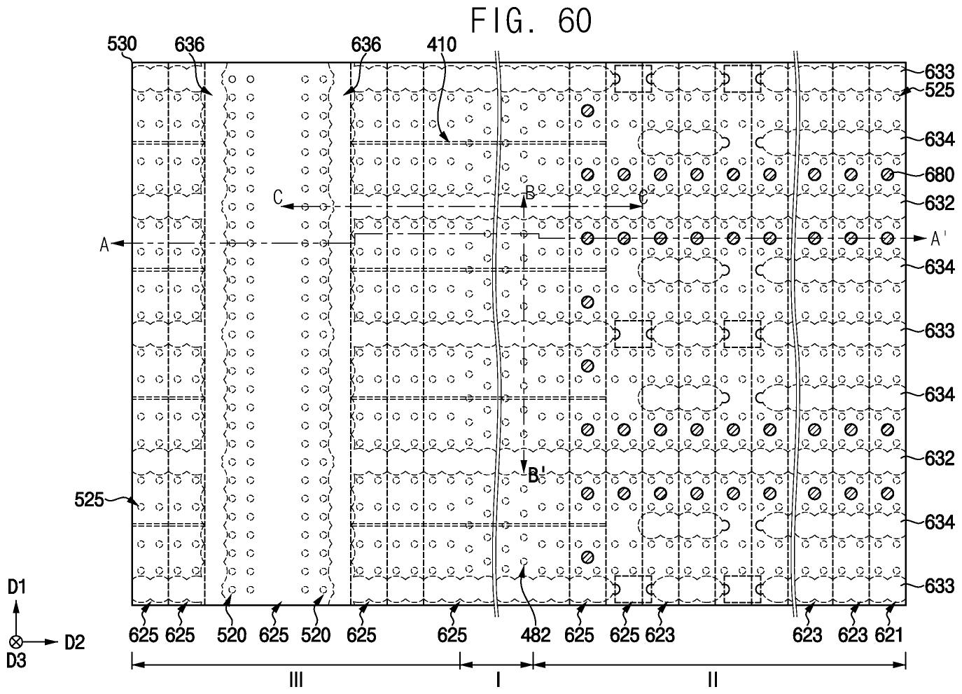

Referring to FIGS. 60 to 62, a portion of the CSP 240 exposed by the eleventh hole 660 and an upper portion of the second insulating interlayer 170 thereunder may be removed to enlarge the eleventh hole 660 downwardly, and thus, an upper surface of the fifth lower wiring 204 may be exposed.

A first upper contact plug 680 may be formed in the eleventh hole 660 to contact the upper surface of the fifth lower wiring 204.

Referring back to FIGS. 1 to 8, an eighth insulating interlayer 700 may be formed on the seventh insulating interlayer 650 and the first upper contact plug 680, and a second upper contact plug 710 extending through the fourth to eighth insulating interlayers 350 to 700, the first insulation pattern 315 and the second blocking pattern 615 to contact an upper surface of an uppermost one of the third gate electrodes 625 and/or an upper surface of one of the third gate electrodes 625 at a second level from above on the third region III of the substrate 100, a third upper contact plug 720 extending through the sixth to eighth insulating interlayers 530 to 700 to contact an upper surface of the capping pattern 472 included in the memory channel structure 482, and an upper via 730 extending through the eighth insulating interlayer 700 to contact an upper surface of the first upper contact plug 680 may be formed.

A ninth insulating interlayer may be formed on the eighth insulating interlayer 700, the second and third upper contact plugs 710 and 720 and the upper via 730, and upper wirings electrically connected to the second and third upper contact plugs 710 and 720 and the upper via 730 may be additionally formed through the ninth insulating interlayer, so that the manufacture of the semiconductor device may be completed.

As described above, the third and fourth openings 552 and 553 extending in the second direction D2 may be formed by performing an additional etching process on the fifth and sixth holes 372 and 373, which may be formed by removing the ninth and tenth sacrificial patterns 392 and 393, respectively, to increase the widths of the fifth and sixth holes 372 and 373 in the horizontal direction, and the sixth opening 556 extending in the third direction D3 may be formed by performing an additional etching process on the eighth hole 376, which may be formed by removing the twelfth sacrificial pattern 396, to increase the width of the eight hole 376 in the horizontal direction. However, the fourteenth sacrificial pattern 398 between the third and sixth openings 552 and 556 and/or the fourth and sixth openings 553 and 556 may not be removed together with the ninth, tenth, and twelfth sacrificial patterns 392 to 396, but may be removed separately so that an additional etching process for increasing the width of the tenth hole 378 may not be performed after the tenth hole 378 is formed.

Thus, the portion of the sixth opening 556 connected to the third opening 552 or the fourth opening 553 may have the width in the horizontal direction that is not larger than those of other portions of the sixth opening 556.

The fourth and fifth openings 553 and 554 extending in the second direction D2 may be formed by performing an additional etching process on the fifth and sixth holes 372 and 373, respectively, which may be formed by removing the ninth and tenth sacrificial patterns 392 and 393, respectively, to increase the widths of the fifth and sixth holes 372 and 373 in the horizontal direction. However, the thirteenth sacrificial pattern 397 between the fourth openings 553 or between the fifth openings 554 may not be removed together with the tenth and eleventh sacrificial patterns 393 and 394. The thirteenth sacrificial pattern 397 may be removed separately so that an additional etching process for increasing the width of the ninth hole 377 may not be performed after the ninth hole 377 is formed. Thus, the increase of the length in the second direction D2 of each of the fourth and fifth openings 553 and 554 may be limited, so that the fourth openings 553 and/or the fifth openings 554, which may be spaced apart from each other in the second direction D2, may not be undesirably connected to each other.

For example, when the third to sixth openings 552 to 556 are formed by an etching process, the width of the upper portion of each of the third to sixth openings 552 to 556 may be greater than a width of a lower portion thereof due to the characteristics of the etching process. In example embodiments, a margin of the etching process may be improved by limiting the increase of the width of the sixth opening 556 connected to each of the third and fourth openings 552 and 553 and/or the increase of the widths of the end portions of the fourth and fifth openings 553 and 554 during the etching process, and thus the semiconductor device including the third to sixth division patterns 632 to 636 respectively formed therein may have improved degree of integration.

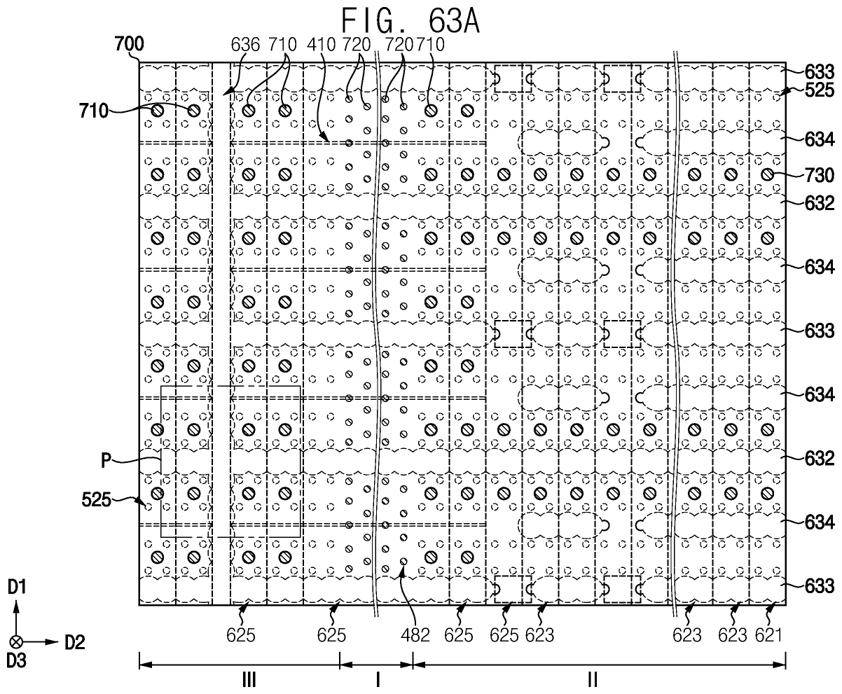

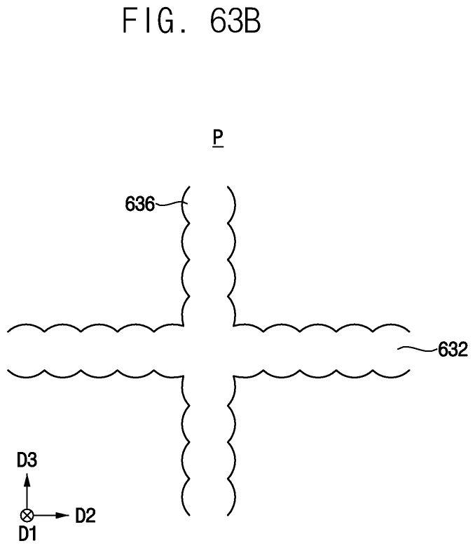

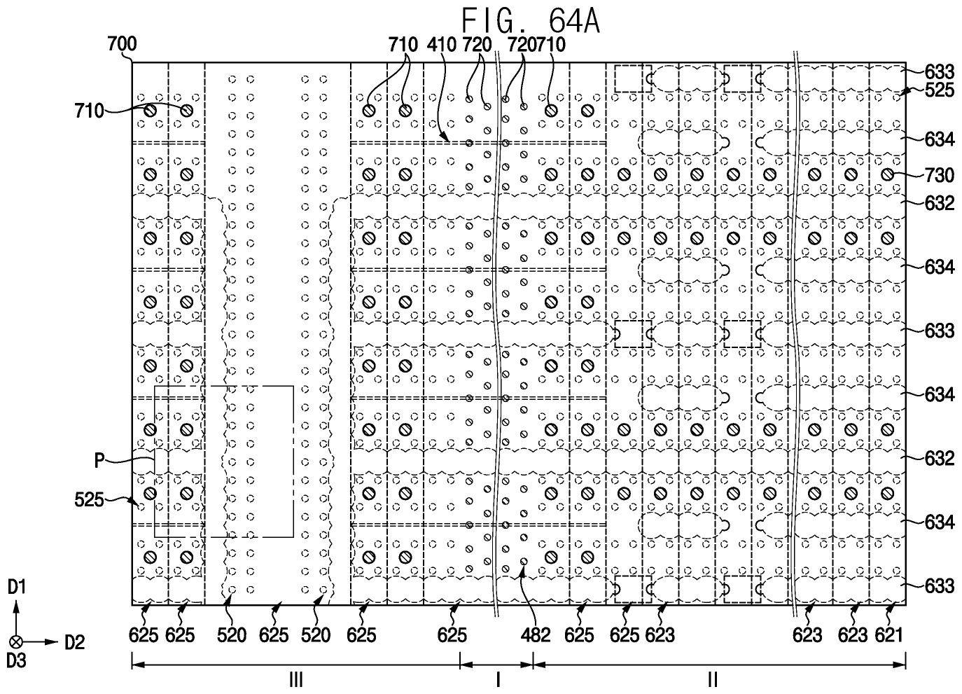

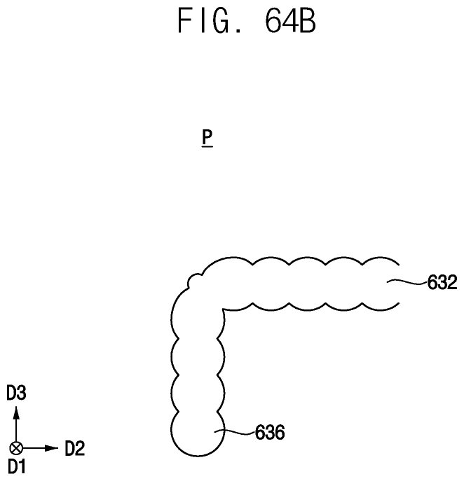

FIGS. 63A and 64A are plan views illustrating semiconductor devices in accordance with example embodiments, which may correspond to FIG. 2A. FIGS. 63B and 64B are enlarged cross-sectional views of region P of FIGS. 63A and 64A, respectively, which may correspond to FIG. 2B.

These semiconductor devices may be substantially the same as and/or similar to the semiconductor devices depicted in FIGS. 1 to 4, except for the shape of the sixth division pattern 636, and as such, a repeated explanation is omitted herein for the sake of brevity.

Referring to FIGS. 63A and 63B, the sixth division pattern 636 may be formed on a central portion, instead of the opposite edge portions, in the second direction D2 of the third region III of the substrate 100, and thus the third division patterns 632 (or the fourth division patterns 633) at opposite sides, respectively, in the second direction D2 may be commonly connected to the sixth division pattern 636.

A width of a portion of the sixth division pattern 636 connected to the third division pattern 632 and/or the fourth division pattern 633 may be smaller than widths of other portions of the sixth division pattern 636.

Referring to FIGS. 64A and 64B, an end portion of the sixth division pattern 636 in the third direction D3 may be connected to an end portion of the third division pattern 632 and/or the fourth division pattern 633 in the second direction D2 on each of opposite end portions of the third region III of the substrate 100 in the third direction D3.

A width of a portion of the sixth division pattern 636 connected to the third division pattern 632 and/or fourth division pattern 633 may be smaller than widths of other portions of the sixth division pattern 636.

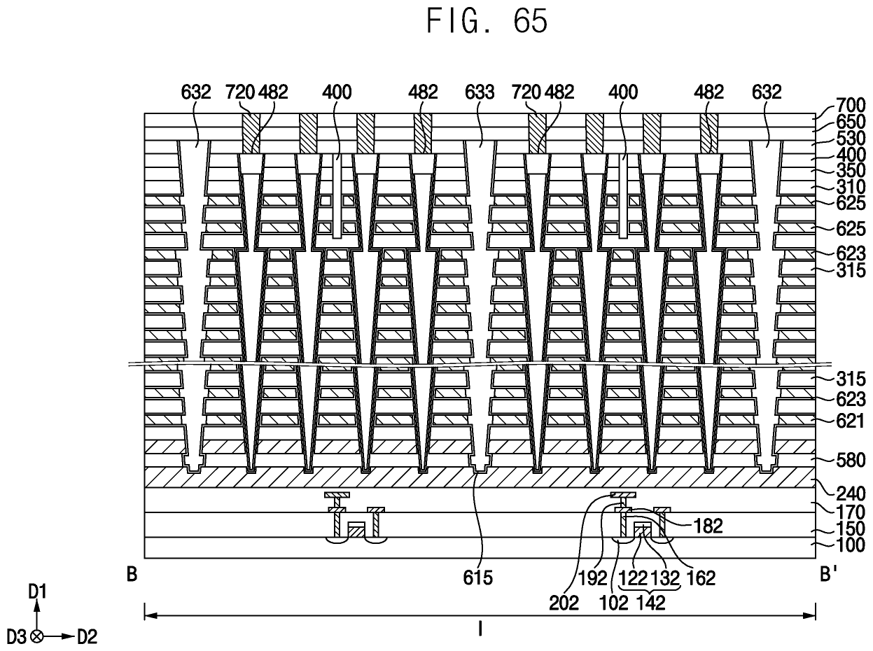

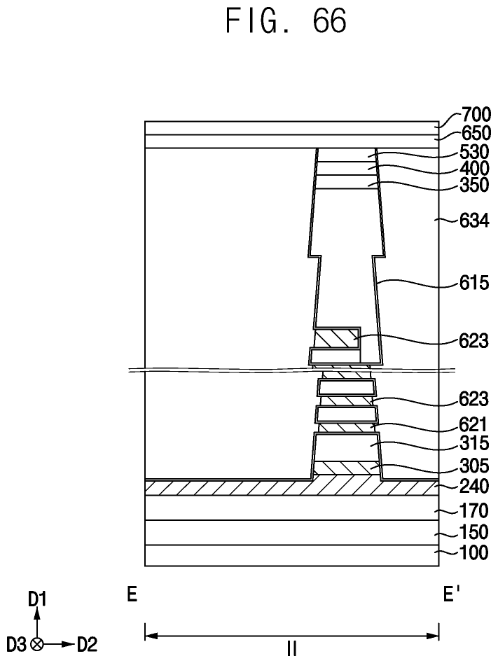

FIGS. 65 and 66 are cross-sectional views illustrating a semiconductor device in accordance with example embodiments, which may correspond to FIGS. 4 and 6, respectively.

This semiconductor device may be substantially the same as and/or similar to the semiconductor devices illustrated in FIGS. 1 to 8, except for the shape of the memory channel structure 482, the first and second support structures 520 and 525, the first upper contact plug 680 and the third to sixth division patterns 632 to 636, and as such, a repeated explanation is omitted herein for the sake of brevity.

Referring to FIGS. 65 and 66, each of the memory channel structure 482, the first and second support structures 520 and 525, the first upper contact plug 680, and the third to sixth division patterns 632 to 636 may include a lower portion, a central portion and an upper portion sequentially stacked.

In example embodiments, each of the lower portion, the central portion and the upper portion may have a width that gradually decreases from a top toward a bottom thereof in the first direction D1.

In example embodiments, in each of the memory channel structure 482, the first and second support structures 520 and 525, the first upper contact plug 680 and the third to sixth division patterns 632 to 636, an upper surface of the lower portion may have a greater width than a lower surface of the central portion, and an upper surface of the central portion may have a greater width than a lower surface of the upper portion.

As shown in FIGS. 65 and 66, each of the memory channel structure 482, the first and second support structures 520 and 525, the first upper contact plug 680 and the third to sixth division patterns 632 to 636 may include three portions of the lower portion, the central portion and the upper portion. However, the present disclosure may not be limited thereto, and may include two or four or more portions. Each of the portions may have a width that gradually decreases from a top toward a bottom thereof, and a width of an upper surface of an underlying portion may be greater than a width of a bottom surface of a directly overlying portion.

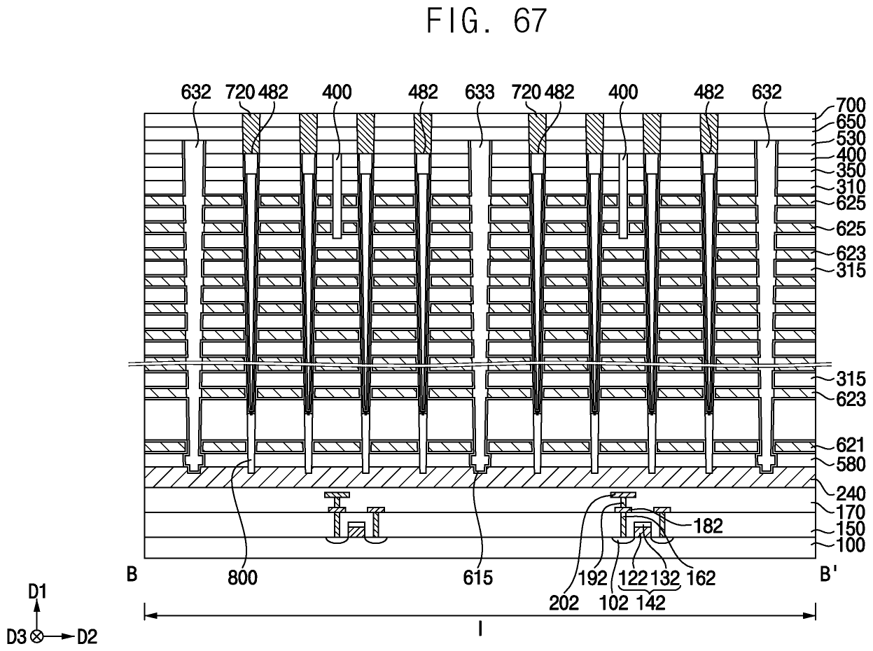

FIG. 67 is a cross-sectional view illustrating a semiconductor device in accordance with example embodiments, which may correspond to FIG. 4.

This semiconductor device may be substantially the same as and/or similar to the semiconductor devices depicted in FIGS. 1 to 8, except for the memory channel structure 482, the channel connection pattern 580, the support layer 300 and support pattern 305, and as such, a repeated explanation is omitted herein for the sake of brevity.

Referring to FIG. 67, the memory channel structure 482 may further include a semiconductor pattern 800 on the substrate 100, and the charge storage structure 442, the channel 452, the filling pattern 462 and the capping pattern 472 may be disposed on the semiconductor pattern 800.

The semiconductor pattern 800 may include, but not be limited to, single crystalline silicon and/or polysilicon. In an example embodiment, an upper surface of the semiconductor pattern 800 may be located at a height between a lower surface and an upper surface of one of the first insulation patterns 315 that may be disposed between the first and second gate electrodes 621 and 623. The charge storage structure 442 may have a cup shape with an open central bottom surface on the upper surface of the semiconductor pattern 800, and may contact an edge portion of the upper surface of the semiconductor pattern 800. The channel 452 may have a cup shape on the upper surface of the semiconductor pattern 800, and may contact a central portion of the upper surface of the semiconductor pattern 800. Thus, the channel 452 may be electrically connected to the CSP 240 through the semiconductor pattern 800.

The channel connection pattern 580, the support layer 300 and the support pattern 305 may not be disposed between the CSP 240 and the first gate electrode 621. In an example embodiment, the one of the first insulation patterns 315 between the first and second gate electrodes 621 and 623 may have a thickness greater than those of upper ones of the first insulation patterns 315.

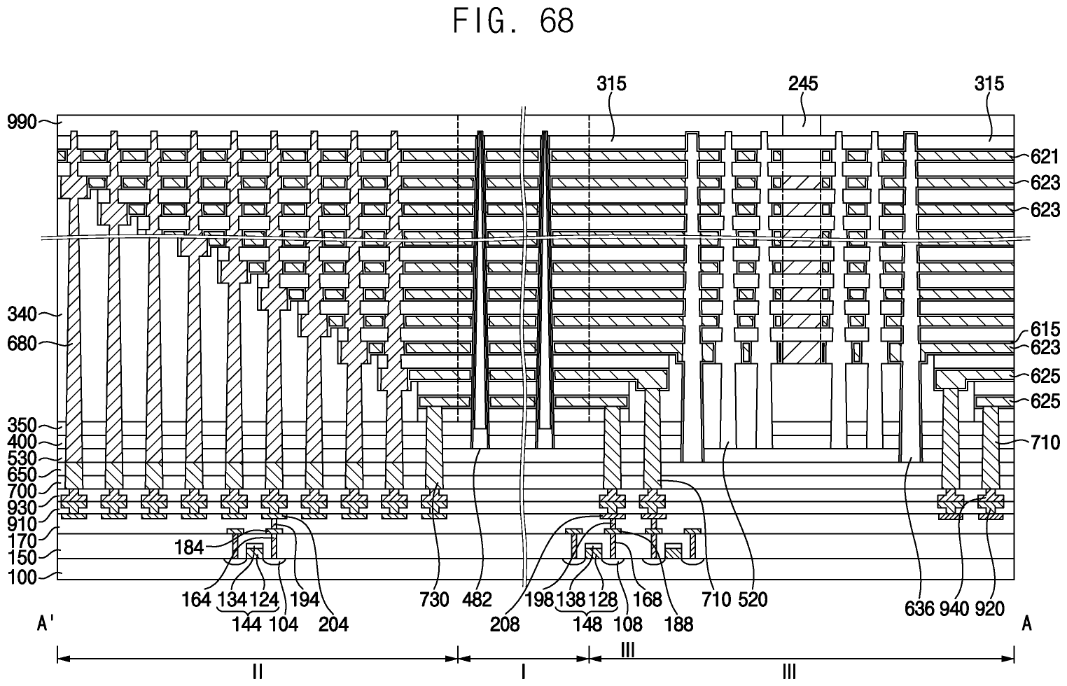

FIG. 68 is a cross-sectional view illustrating a semiconductor device in accordance with example embodiments, which may correspond to FIG. 3.

This semiconductor device may be substantially the same as and/or similar to the semiconductor devices illustrated in FIGS. 1 to 8, except that an upper structure is turned upside down, bonding structures are further included, and the channel connection pattern 580, the support layer 300 and the support pattern 305 are not formed. Thus, a repeated explanation is omitted herein for the sake of brevity.

Upper and lower portions of structures shown in FIGS. 1 to 8 may be referred to as lower and upper portions of the structures in FIG. 68, respectively.

In example embodiments, tenth and eleventh insulating interlayers 910 and 930 may be sequentially stacked on the fourth to sixth lower wirings 202 to 208 and the second insulating interlayer 170. First bonding patterns 920 may extend through the tenth insulating interlayer 910, and may contact the fourth to sixth lower wirings 202 to 208, respectively. Alternatively or additionally, second bonding patterns 940 may extend through the eleventh insulating interlayer 930, and may contact the first bonding patterns 920, respectively.

Each of the first and second bonding patterns 920 and 940 may include a metal, such as, but not limited to, copper.

An upper surface of each of the memory channel structure 482, the first and second support structures 520 and 525, the first upper contact plug 680 and the third to sixth division patterns 632 to 636 may extend through a lower portion of an upper substrate 990. The upper surface and an upper sidewall of the channel 452 may not be covered by the charge storage structure 442, and may contact the upper substrate 990. The upper substrate 990 may include a semiconductor material, such as, but not limited to, silicon, germanium, silicon-germanium, and the like, and may be doped with impurities (e.g., n-type or p-type impurities).

While example embodiments have been particularly shown and described, it may be understood by one of ordinary skill in the art that variations in form and detail may be made therein without departing from the spirit and scope of the claims.

What is claimed is:

1. A semiconductor device, comprising:
a plurality of gate electrode structures, each gate electrode structure of the plurality of gate electrode structures comprising a plurality of gate electrodes spaced apart from each other on a substrate in a first direction substantially perpendicular to an upper surface of the substrate, each gate electrode of the plurality of gate electrodes extending in a second direction substantially parallel to the upper surface of the substrate, and the plurality of gate electrode structures being spaced apart from each other in a third direction substantially parallel to the upper surface of the substrate and crossing the second direction;
a first division pattern extending in the second direction between the plurality of gate electrode structures on the substrate;
a second division pattern extending in the third direction on the substrate, the second division pattern being on sidewalls of end portions in the second direction of the plurality of gate electrode structures; and
a memory channel structure extending in the first direction through each gate electrode structure of the plurality of gate electrode structures,
wherein the first division pattern and the second division pattern contact each other,
wherein the first division pattern and the second division pattern are coupled to each other, and
wherein a first maximum width in the second direction of a first portion of the second division pattern contacting the first division pattern is narrower than a second maximum width in the second direction of other portions of the second division pattern.

2. The semiconductor device according to claim 1, wherein the first division pattern has a first width in the third direction that varies periodically, and
wherein the second division pattern has a second width in the second direction that varies periodically.

3. The semiconductor device according to claim 1, further comprising:
a plurality of third division patterns spaced apart from each other in the second direction on the substrate, the plurality of third division patterns extending partially through a corresponding gate electrode structure of the plurality of gate electrode structures.

4. The semiconductor device according to claim 3, wherein the second division pattern contacts a pattern of the plurality of third division patterns,
wherein the second division pattern and the pattern of the plurality of third division patterns are coupled to each other, and
wherein a third maximum width in the second direction of a second portion of the second division pattern contacting the pattern of the plurality of third division patterns is narrower than a fourth maximum width in the second direction of other portions of the second division pattern except for the first portion of the second division pattern.

5. The semiconductor device according to claim 4, wherein the third maximum width in the second direction of the second portion of the second division pattern is substantially equal to the first maximum width in the second direction of the first portion of the second division pattern.

6. The semiconductor device according to claim 3, wherein, for each pattern of the plurality of third division patterns, a third maximum width in the third direction of an end portion in the second direction of that pattern is narrower than a fourth maximum width in the third direction of other portions of that pattern.

7. The semiconductor device according to claim 3, further comprising:
a fourth division pattern extending through a lowermost gate electrode of the plurality of gate electrodes,
wherein an end portion in the second direction of each pattern of the plurality of third division patterns extends through a portion of the fourth division pattern.

8. The semiconductor device according to claim 3, further comprising:
a plurality of fourth division patterns spaced apart from each other in the second direction on the substrate between the first division pattern and a pattern of the plurality of third division patterns neighboring in the third direction, each pattern of the plurality of fourth division patterns partially extending through a corresponding gate electrode structure of the plurality of gate electrode structures.

9. The semiconductor device according to claim 8, wherein, for each pattern of the plurality of fourth division patterns, a third maximum width in the third direction of an end portion in the second direction of that pattern is narrower than a fourth maximum width in the third direction of other portions of that pattern.

10. The semiconductor device according to claim 8, further comprising:
a fifth division pattern extending through an uppermost gate electrode of the plurality of gate electrodes,
wherein the fifth division pattern is aligned with a pattern of the plurality of fourth division patterns in the second direction.

11. The semiconductor device of claim 1, wherein the substrate comprises a third region, a first region on each of opposite sides in the second direction of the third region, and a second region on a side in the first direction of the first region,
wherein the memory channel structure is on the first region of the substrate,
wherein the first division pattern is on the first region and the second region of the substrate, and the third region of the substrate adjacent to the first region of the substrate in the second direction, and
wherein the second division pattern is on the third region of the substrate.

12. The semiconductor device of claim 11, wherein the second division pattern is on each of opposite edge portions in the second direction of the third region of the substrate.

13. A semiconductor device, comprising:
a gate electrode structure comprising a plurality of gate electrodes spaced apart from each other on a substrate in a first direction substantially perpendicular to an upper surface of the substrate, each gate electrode of the plurality of gate electrodes extending in a second direction substantially parallel to the upper surface of the substrate;
a plurality of first division patterns on respective opposite sidewalls of the gate electrode structure in a third direction substantially parallel to the upper surface of the substrate and crossing the second direction, each pattern of the plurality of first division patterns extending in the second direction on the substrate;
a plurality of second division patterns spaced apart from each other in the second direction between the plurality of first division patterns on the substrate, each pattern of the plurality of second division patterns extending partially through the gate electrode structure; and
a memory channel structure extending in the first direction through the gate electrode structure,
wherein for each pattern of the plurality of second division patterns, a first maximum width in the third direction of an end portion in the second direction of that pattern is narrower than a second maximum width in the third direction of other portions of that pattern.

14. The semiconductor device according to claim 13, further comprising:
a third division pattern extending through a lowermost gate electrode of the plurality of gate electrodes,
wherein the end portion in the second direction of each pattern of the plurality of second division patterns extends through a portion of the third division pattern.

15. The semiconductor device according to claim 13, further comprising:
a plurality of third division patterns spaced apart from each other in the second direction between the plurality of first division patterns and the plurality of second division patterns neighboring in the third direction on the substrate, each pattern of the plurality of third division patterns extending partially through the gate electrode structure.

16. The semiconductor device according to claim 15, wherein for each pattern of the plurality of third division patterns, a third maximum width in the third direction of the end portion in the second direction of that pattern is narrower than a fourth maximum width in the third direction of other portions of that pattern.

17. A semiconductor device according to claim 15, further comprising:
a fourth division pattern extending through an uppermost gate electrode of the plurality of gate electrodes,
wherein the fourth division pattern is aligned with a pattern of the plurality of third division patterns in the second direction.

18. A semiconductor device, comprising:
a lower circuit pattern on a substrate;
a common electrode plate (CSP) on the lower circuit pattern;
a plurality of gate electrode structures, each gate electrode structure of the plurality of gate electrode structures comprising a plurality of gate electrodes spaced apart from each other on the CSP in a first direction substantially perpendicular to an upper surface of the substrate, each gate electrode of the plurality of gate electrodes extending in a second direction substantially parallel to the upper surface of the substrate, and the plurality of gate electrode structures being spaced apart from each other in a third direction substantially parallel to the upper surface of the substrate and crossing the second direction;
a first division pattern extending in the second direction between the plurality of gate electrode structures on the CSP;
a second division pattern extending in the third direction on the CSP, the second division pattern being on sidewalls of end portions in the second direction of the plurality of gate electrode structures;
a memory channel structure extending in the first direction through each gate electrode structure of the plurality of gate electrode structures on the CSP;
a support structure extending in the first direction through each gate electrode structure of the plurality of gate electrode structures on the CSP; and
a contact plug extending through each of the plurality of gate electrode structures, the contact plug being electrically coupled to the lower circuit pattern,
wherein the first division pattern and the second division pattern contact each other,
wherein the first division pattern and the second division pattern are coupled to each other, and
wherein a first maximum width in the second direction of a first portion of the second division pattern contacting the first division pattern is narrower than a second maximum width in the second direction of other portions of the second division pattern.

19. The semiconductor device according to claim 18, wherein the substrate comprises a third region, a first region on each of opposite sides in the second direction of the third region, and a second region on a side in the first direction of the first region,
wherein the memory channel structure is on the first region of the substrate, and the support structure and the contact plug are on the second region of the substrate,
wherein the first division pattern is on the first region and the second region of the substrate and a portion of the third region of the substrate adjacent to the first region of the substrate in the second direction, and
wherein the second division pattern is on the third region of the substrate.

20. The semiconductor device according to claim 18, further comprising:
a plurality of third division patterns spaced apart from each other in the second direction on the substrate, the plurality of third division patterns extending partially through a corresponding gate electrode structure of the plurality of gate electrode structures,
wherein the second division pattern contacts a pattern of the plurality of third division patterns,
wherein the second division pattern is coupled to the pattern of the plurality of third division patterns, and
wherein a third maximum width in the second direction of a second portion of the second division pattern contacting the pattern of the plurality of third division patterns is narrower than a fourth maximum width in the second direction of other portions of the second division pattern except for the first portion of the second division pattern.
